(19) United States
(12) Patent Application Publication
(10) Pub. No.: US 2025/0300119 A1
(43) Pub. Date: Sep. 25, 2025

(54) SEMICONDUCTOR DEVICE, METHOD FOR DESIGNING THE SAME, AND METHOD FOR MANUFACTURING THE SAME

(71) Applicant: Rohm Co., Ltd., Kyoto-shi (JP)

(72) Inventors: Junsuke SATAKE, Kyoto-shi (JP); Yoshizo OSUMI, Kyoto-shi (JP); Riku SAWAMURA, Kyoto-shi (JP)

(21) Appl. No.: 19/045,038

(22) Filed: Feb. 4, 2025

(30) Foreign Application Priority Data
Feb. 7, 2024 (JP) 2024-016763
Mar. 22, 2024 (JP) 2024-046351

(51) Int. Cl. H01L 23/00; H01L 23/29; H01L 23/31; H01L 23/495

(52) U.S. Cl. CPC H01L 24/49; H01L 23/293; H01L 23/3107; H01L 23/49575; H01L 24/48; H01L 2224/48137; H01L 2224/49051

(57) ABSTRACT

A semiconductor device is provided with a first lead and a second lead spaced apart from each other in a first direction, a first semiconductor element including a first functional part and supported by the first lead, and a second semiconductor element including a second functional part and supported by the second lead. Each of the first functional part and the second functional part transmits an electrical signal in an insulated state. The distance d1 between the first lead and the second lead in the first direction is greater than a predetermined distance d0.

### TECHNICAL FIELD

The present disclosure relates to semiconductor devices, methods for designing semiconductor devices, and methods for manufacturing semiconductor devices.

### BACKGROUND ART

Semiconductor devices are used in inverter devices configured for electric vehicles or hybrid vehicles, and home appliances. An inverter device is equipped with a semiconductor device and switching elements such as IGBTs (Insulated Gate Bipolar Transistors) or MOSFETs (Metal Oxide Semiconductor Field Effect Transistors), where the semiconductor device includes a control element and a drive element. In such an inverter device, control signals outputted from the ECU (Engine Control Unit) are inputted to the control element of the semiconductor device. The control element converts the control signals into PWM (Pulse Width Modulation) control signals and transmits them to the drive element. The drive element drives, for example, six switching elements at the desired timing based on the PWM control signals. With such arrangements, three-phase AC power for motor drive is generated from the DC power of the vehicle battery.

In the above-noted semiconductor device, the power voltage supplied to the control element may be low voltage (approximately 5 V), while the power voltage supplied to the drive element may be high voltage (approximately 600 V or more). Conventionally, insulating elements are used for transmitting signals between elements to which different power voltages are applied. For instance, JP-A-2009-49035 discloses a semiconductor device (intelligent power module) equipped with an insulating element. The intelligent power module disclosed in JP-A-2009-49035 includes a control circuit, arm circuits (upper arm circuit and lower arm circuit), and an insulating transformer. The control circuit may be made up of a CPU or logic IC or a system LSI equipped with a logic IC and a CPU. The arm circuits are equipped with a gate driver IC. The isolating transformer transmits signals between the control circuit and the arm circuits in an isolated state. The CPU of the control circuit generates PWM signals for gate drive, which instruct the switching elements to be electrically connected or disconnected, and transmits these gate drive PWM signals to the gate driver IC of the arm circuit in an isolated state via the isolation transformer. The gate driver IC generates gate signals based on the gate drive PWM signals for driving the control terminal of the switching element, causing the switching element to perform a switching operation.

Multiple elements whose power voltages are mutually different may be disposed in a single package. In this case, a relatively high voltage part and a relatively low voltage part are present within the single package. With this semiconductor device, there is a risk of dielectric breakdown, and dielectric breakdown tends to occur more easily when the potential difference of the power voltages is large. The occurrence of dielectric breakdown causes the semiconductor device to malfunction and impairs its reliability.

### SUMMARY

An objection of the present disclosure is to provide a semiconductor device that has been improved over conventional devices. In particular, in view of the above circumstances, an objective of the present disclosure is to provide a semiconductor device that is capable of suppressing the occurrence of dielectric breakdown.

According to the present disclosure, there is provided a semiconductor device comprising: a conductive support including a first lead and a second lead spaced apart from each other in a first direction perpendicular to a thickness direction; a first semiconductor element including a first functional part and supported by the first lead; a second semiconductor element including a second functional part and supported by the second lead; a sealing resin covering a part of the conductive support, the first semiconductor element, and the second semiconductor element. Each of the first functional part and the second functional part transmits an electrical signal in an insulated state. A distance d1 between the first lead and the second lead in the first direction is greater than a distance d0 determined by Formula (1),

$$d 0 = ( ( Y / A ) \hat{} ( 1 / B ) ) \times 0.15 \times ( X ) \qquad ( 1 )$$

where Y is an insulation life [years] required for the semiconductor device, A and B are constants depending on a material of the sealing resin, 0.15 is an offset value for calculating the distance d0 [mm], and X is a voltage [kVrms].

According to the present disclosure, there is provided a method for designing a semiconductor device that comprises: a conductive support including a first lead and a second lead spaced apart from each other in a first direction; a first semiconductor element including a first functional part and supported by the first lead; a second semiconductor element including a second functional part and supported by the second lead; a sealing resin covering a part of the conductive support, the first semiconductor element, and the second semiconductor element, where each of the first functional part and the second functional part transmits an electrical signal in an insulated state. The method comprises a first design step configured to design that a distance d1 between the first lead and the second lead in the first direction is greater than a distance d0 determined by Formula (1),

$$d 0 = ( ( Y / A ) \hat{} ( 1 / B ) ) \times 0.15 \times ( X ) \qquad ( 1 )$$

where Y is an insulation life [years] required for the semiconductor device, A and B are constants depending on a material of the sealing resin, 0.15 is an offset value for calculating the distance d0 [mm], and X is a voltage [kVrms].

According to the present disclosure, there is provided a method for manufacturing a semiconductor device, where the manufacturing method comprises the design method noted above.

### BRIEF DESCRIPTION OF DRAWINGS

FIG. 1 is a plan view showing a semiconductor device according to a first embodiment of the first aspect.

FIG. 2 is a view showing the sealing resin indicated by imaginary lines in the plan view of FIG. 1.

FIG. 3 is a front view showing the semiconductor device according to the first embodiment of the first aspect.

FIG. 4 is a left side view showing the semiconductor device according to the first embodiment of the first aspect.

FIG. 5 is a right side view of the semiconductor device according to the first embodiment of the first aspect.

FIG. 6 is a cross-sectional view along the line VI-VI in FIG. 2.

FIG. 7 is an enlarged cross-sectional view of a part of FIG. 6.

FIG. 8 is a cross-sectional view along the line VIII-VIII in FIG. 2.

FIG. 9 is a sectional view of the internal structures of a first semiconductor element and a second semiconductor element of the semiconductor device according to the first embodiment of the first aspect.

FIG. 10 is a flowchart showing an example of a method for manufacturing the semiconductor device according to the first embodiment of the first aspect.

FIG. 11 is a plan view showing a process of the manufacturing method shown in FIG. 10.

FIG. 12 is a plan view showing a process of the manufacturing method shown in FIG. 10.

FIG. 13 is a plan view showing a process of the manufacturing method shown in FIG. 10.

FIG. 14 is a plan view showing a process of the manufacturing method shown in FIG. 10.

FIG. 15 is a plan view showing a process of the manufacturing method shown in FIG. 10.

FIG. 16 is a sectional view showing a process of the manufacturing method shown in FIG. 10.

FIG. 17 is a plan view showing a process of the manufacturing method shown in FIG. 10.

FIG. 18 is a sectional view showing a semiconductor device according to a first variation of the first embodiment of the first aspect, corresponding to the sectional view of FIG. 7.

FIG. 19 is a sectional view showing a semiconductor device according to a second variation of the first embodiment of the first aspect, corresponding to the sectional view of FIG. 7.

FIG. 20 is a plan view showing a semiconductor device according to a second embodiment of the first aspect, with the sealing resin indicated by imaginary lines.

FIG. 21 is an enlarged sectional view of main parts along the line XXI-XXI in FIG. 20, corresponding to the sectional view of FIG. 7.

FIG. 22 is a plan view of a semiconductor device according to a third embodiment of the first aspect, with the sealing resin indicated by imaginary lines.

FIG. 23 is an enlarged sectional view of main parts along line XXIII-XXIII in FIG. 22, corresponding to the sectional view of FIG. 7.

FIG. 24 is a plan view of a semiconductor device according to a first embodiment of the second aspect.

FIG. 25 is a plan view of the sealing resin indicated by imaginary lines, corresponding to FIG. 24.

FIG. 26 is a front view of the semiconductor device according to the first embodiment of the second aspect.

FIG. 27 is a left side view of the semiconductor device according to the first embodiment of the second aspect.

FIG. 28 is a right side view of the semiconductor device according to the first embodiment of the second aspect.

FIG. 29 is a cross-sectional view along the line XXIX-XXIX in FIG. 25.

FIG. 30 is an enlarged cross-sectional view of a part of FIG. 29.

FIG. 31 is a cross-sectional view along the line XXXI-XXXI in FIG. 25.

FIG. 32 is a sectional view of the internal structure of one (insulating element) of the semiconductor elements in the semiconductor device according to the first embodiment of the second aspect.

FIG. 33 is a flowchart showing an example of a method for manufacturing the semiconductor device according to the first embodiment of the second aspect.

FIG. 34 is a plan view showing a process of the manufacturing method shown in FIG. 33.

FIG. 35 is a plan view showing a process of the manufacturing method shown in FIG. 33.

FIG. 36 is a plan view showing a process of the manufacturing method shown in FIG. 33.

FIG. 37 is a plan view showing a process of the manufacturing method shown in FIG. 33.

FIG. 38 is a plan view showing a process of the manufacturing method shown in FIG. 33.

FIG. 39 is a sectional view showing a process of the manufacturing method shown in FIG. 33.

FIG. 40 is a plan view showing a process of the manufacturing method shown in FIG. 33.

FIG. 41 is a plan view showing a semiconductor device according to a first variation of the first embodiment of the second aspect, with the sealing resin indicated by imaginary lines.

FIG. 42 is a cross-sectional view along the line XLII-XLII in FIG. 41.

FIG. 43 is an enlarged cross-sectional view of a part of FIG. 42.

FIG. 44 is an enlarged cross-sectional view of a semiconductor device according to a second variation of the first embodiment of the second aspect.

FIG. 45 is a plan view of a semiconductor device according to a second embodiment of the second aspect, with the sealing resin indicated by imaginary lines.

FIG. 46 is an enlarged sectional view of a part of the section along the line XLVI-XLVI in FIG. 45.

FIG. 47 is a sectional view of the internal structure of two (two insulating elements) of the semiconductor elements of the semiconductor device according to the second embodiment of the second aspect.

FIG. 48 is a flowchart showing an example of a method for manufacturing the semiconductor device according to the second embodiment of the second aspect.

FIG. 49 is a plan view showing a process of the manufacturing method shown in FIG. 48.

FIG. 50 is a cross-sectional view showing a process of the manufacturing method shown in FIG. 48.

FIG. 51 is an enlarged cross-sectional view showing a semiconductor device according to a variation of the second embodiment of the second aspect.

FIG. 52 is a plan view showing a semiconductor device according to a third embodiment of the second aspect, with the sealing resin indicated by imaginary lines.

FIG. 53 is an enlarged sectional view of a part of the cross section along line LIII-LIII in FIG. 52.

FIG. 54 is an enlarged sectional view of a semiconductor device according to a variation of the third embodiment of the second aspect.

FIG. 55 is a plan view of a semiconductor device according to a fourth embodiment of the second aspect, with the sealing resin indicated by imaginary lines.

FIG. 56 is an enlarged sectional view of a part of the section along the line LVI-LVI in FIG. 55.

### DETAILED DESCRIPTION OF EMBODIMENTS

The following specifically describes various embodiments of the present disclosure, such as semiconductor devices, methods for designing semiconductor devices and methods for manufacturing semiconductor devices, with reference to the drawings. In the following description, the same or similar elements are indicated by the same reference numerals, and redundant descriptions are omitted.

In the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, the expression “An object A contains (or the material of an object A includes) a material C” implies the situation where, unless otherwise specifically noted, “the object A is made of (or the material of the object A is) the material C” or “the object A is mainly made of (or the material of the object A is) the material C”. Still further, “A surface A faces in a direction B (or toward a first side or an opposite second side in the direction B) is not limited, unless otherwise specifically noted, to the situation where the surface A forms an angle of 90° with the direction B but includes the situation where the surface A is inclined relative to the direction B.

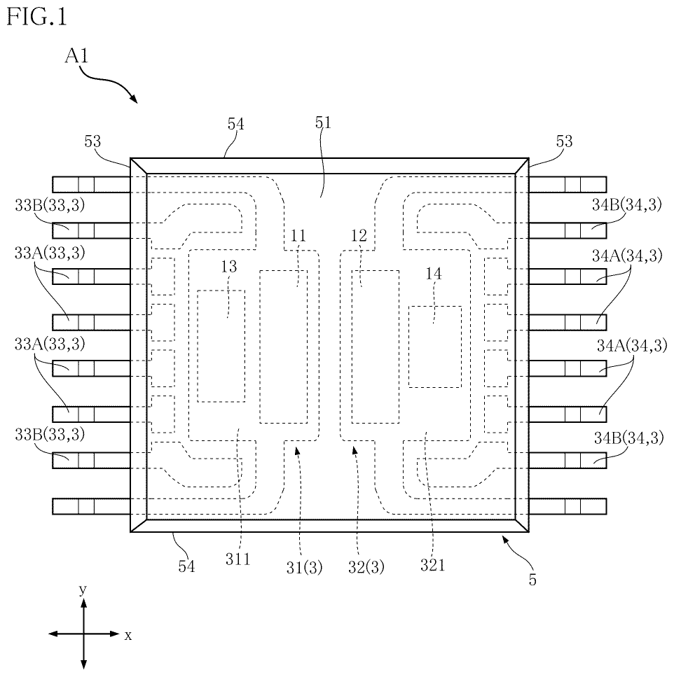

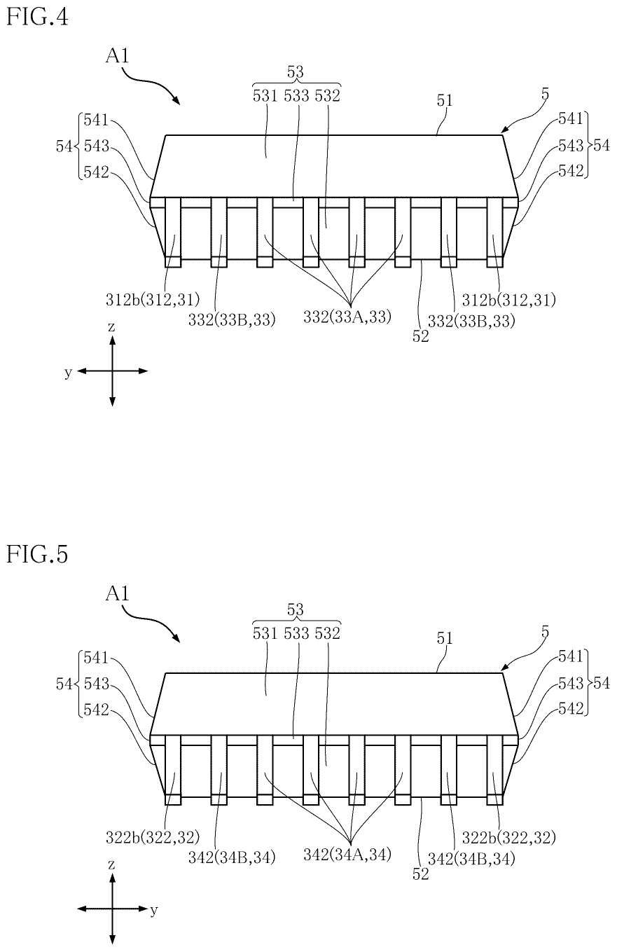

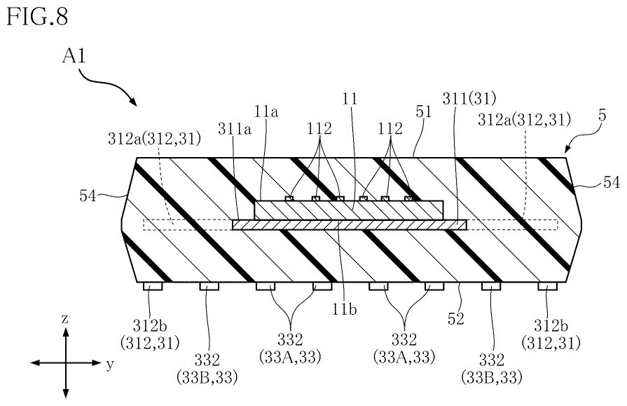

FIGS. 1-23 illustrate embodiments according to a first aspect of the present disclosure, such as semiconductor devices, methods for designing semiconductor devices, and methods for manufacturing semiconductor devices. Each of the semiconductor devices described below with reference to FIGS. 1 to 23 has two semiconductor elements (semiconductor element 11 and semiconductor element 12 to be described below), and in the respective semiconductor devices, each of the two semiconductor elements equally has a functional part configured to transmit electrical signals while ensuring a desired insulated state.

### <First Aspect>

FIGS. 1 to 9 illustrate a semiconductor device A1 according to a first embodiment of the first aspect. As shown in these figures, the semiconductor device A1 has a semiconductor element 11, a semiconductor element 12, a semiconductor element 13, a semiconductor element 14, a conductive support 3, a plurality of connection members 4, and a sealing resin 5. The conductive support 3 includes a lead 31, a lead 32, a plurality of leads 33, a plurality of leads 34. The connection members 4 include a plurality of wires 41, a plurality of wires 42, a plurality of wires 43, a plurality of wires 44, a plurality of wires 45, a wire 46, and a wire 47.

The present disclosure is described with reference to a thickness direction z, a first direction x, and a second direction y, which are orthogonal to each other. The thickness direction z may correspond to the thickness direction of the semiconductor element 11, the semiconductor element 12, the semiconductor element 13, the semiconductor element 14, the conductive support 3, or the sealing resin 5. One side of the thickness direction z may be referred to as “up” and the other side as “down. The terms such as “above,” “below,” “upper,” “lower,” “upper surface,” and “lower surface” indicate relative positional relationships of the respective components in the thickness direction z, and do not necessarily define the relationship with the direction of gravity. In the following description, “plan view” means when the object in question is viewed along the thickness direction z.

The semiconductor device A1 may be surface-mounted on a circuit board of an inverter device in, for example, an electric vehicle or a hybrid vehicle. The semiconductor device A1 controls the switching operation of switching elements such as IGBTs or MOSFETs. The illustrated package of the semiconductor device A1 is an SOP (Small Outline Package), as understood from FIG. 1 and FIGS. 3 to 5, though the package type for the semiconductor device A1 may not be limited to the SOP according to the present disclosure.

The semiconductor element 11, the semiconductor element 12, the semiconductor element 13, and the semiconductor element 14 may be chief functional components of the semiconductor device A1. The semiconductor element 11, the semiconductor element 12, the semiconductor element 13 and the semiconductor element 14 are all individual elements separated from each other. In the first direction x, the semiconductor element 11 and the semiconductor element 12 are located between the semiconductor element 13 and the semiconductor element 14. In the first direction x, the semiconductor element 11 is located between the semiconductor element 12 and the semiconductor element 13, while the semiconductor element 12 is located between the semiconductor element 11 and the semiconductor element 14. In plan view, the semiconductor element 11, the semiconductor element 12, the semiconductor element 13, and the semiconductor element 14 are each rectangular with their long sides or edges extending along the second direction y. According to the present disclosure, the shape of the semiconductor elements 11, 12, 13 and 14 in plan view is not limited to the illustrated one.

The semiconductor element 13 is a controller (control element) of a gate driver for driving switching elements such as IGBTs and MOSFETs. The semiconductor element 13 has a circuit for converting control signals inputted from an ECU or the like into PWM control signals, a transmitting circuit for transmitting the PWM control signals to the semiconductor element 11, and a receiving circuit for receiving electrical signals from the semiconductor element 11.

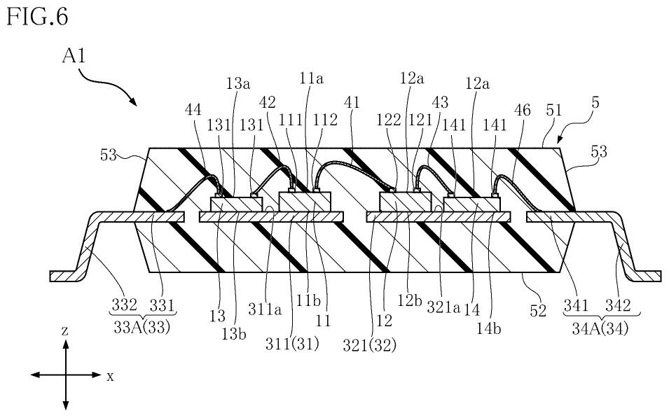

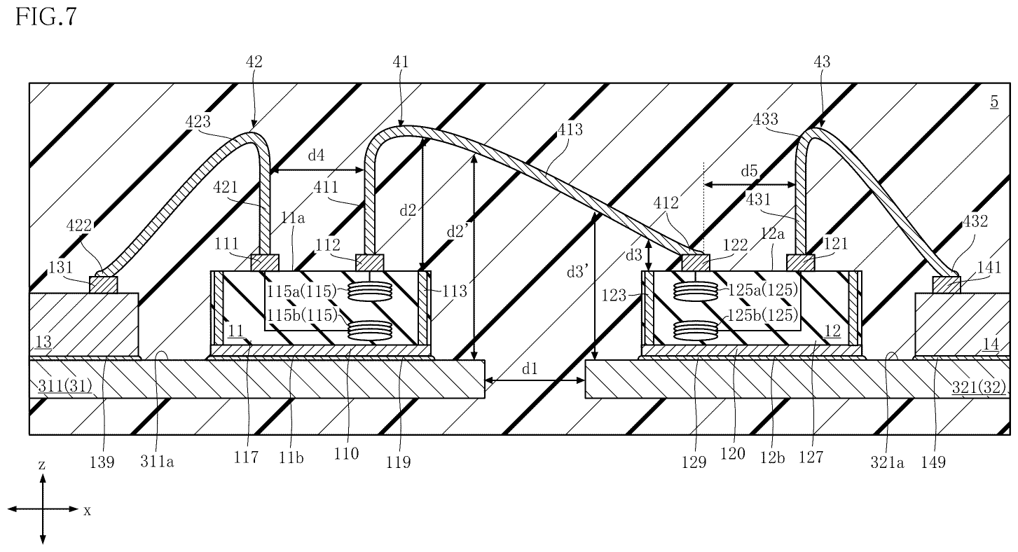

The semiconductor element 13 has an obverse surface 13a and a reverse surface 13b, as shown in FIG. 6. The obverse surface 13a and the reverse surface 13b are spaced apart from each other in the thickness direction z. The obverse surface 13a is the upper surface of the semiconductor element 13 and the reverse surface 13b is the lower surface of the semiconductor element 13. The reverse surface 13b faces the lead 31.

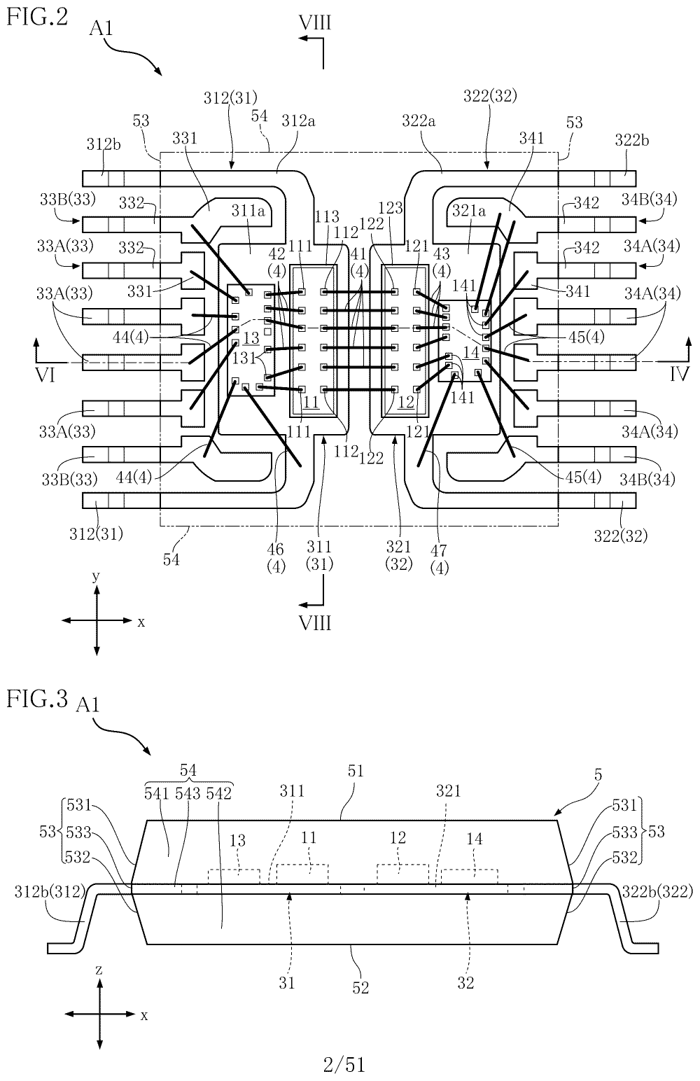

As shown in FIG. 2 and FIG. 6, the semiconductor element 13 has a plurality of pads 131. The plurality of pads 131 are provided on the obverse surface 13a (the surface facing the same direction as the mount surface 311a of the island portion 311 of the lead 31 to be described below). The pads 131 may be made of a material including aluminum (A1), for example.

The semiconductor element 14 is a gate driver (drive element) for driving switching elements. The semiconductor element 14 has a receiving circuit for receiving a PWM control signal, a circuit for driving the switching elements based on the PWM control signal, and a transmitting circuit for transmitting electrical signals to the semiconductor element 13. The electrical signals may include an output signal from a temperature sensor located near a motor.

The semiconductor element 14 has an obverse surface 14a and a reverse surface 14b, as shown in FIG. 6. The obverse surface 14a and the reverse surface 14b are spaced apart from each other in the thickness direction z. The obverse surface 14a is the upper surface of the semiconductor element 14 and the reverse surface 14b is the lower surface of the semiconductor element 14. The reverse surface 14b faces the lead 32.

As shown in FIGS. 2 and 6, the semiconductor element 14 has a plurality of pads 141. The plurality of pads 141 are provided on the obverse surface 14a (the surface facing the same direction as the mount surface 321a of the island portion 321 of the lead 32 to be described below). The pads 141 may made made of a material including aluminum, for example.

The semiconductor element 11 and the semiconductor element 12 are components for transmitting PWM control signals and other electrical signals while ensuring a desired insulated state (thus, insulating components as well). The semiconductor element 11 and the semiconductor element 12 may be of an inductive type. An example of the inductive type semiconductor elements 11 and 12 is an isolation transformer. Alternatively, the semiconductor element 11 and the semiconductor element 12 may be of a capacitive type. An example of the capacitive type semiconductor elements 11 and 12 may be a capacitor. Further, the semiconductor elements 11 and 12 may be a photocoupler, for example.

The semiconductor element 11 has an obverse surface 11a and a reverse surface 11b, as shown in FIGS. 6-9. The obverse surface 11a and the reverse surface 11b are spaced apart from each other in the thickness direction z. The obverse surface 11a is the upper surface of the semiconductor element 11 and the reverse surface 11b is the lower surface of the semiconductor element 11. The reverse surface 11b faces the lead 31.

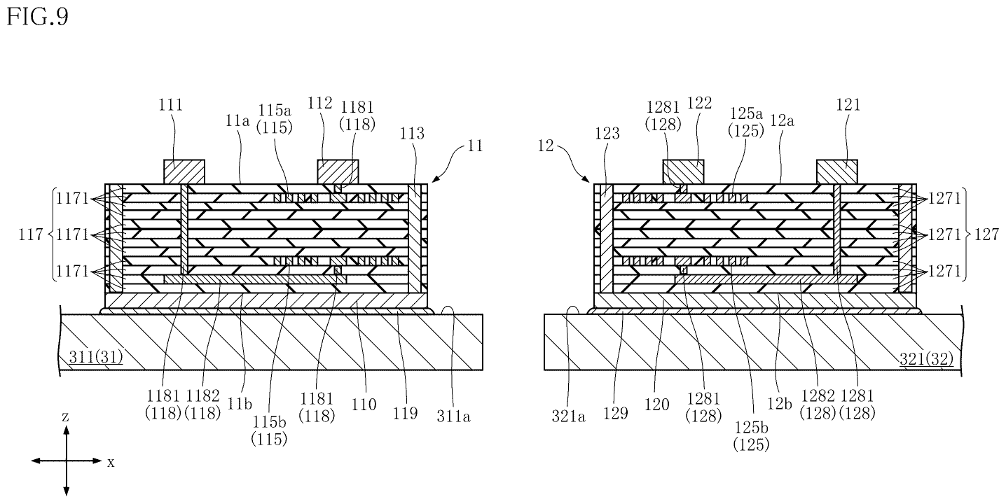

The semiconductor element 11 is provided with a functional part 115. The functional part 115 includes a number of sets of upper windings 115a and lower windings 115b, with each upper winding 115a and a corresponding lower winding 115b serving as one set. Thus, the semiconductor element 11 is provided with multiple upper windings 115a and multiple lower windings 115b. FIGS. 7 and 9 show one of the sets of upper and lower windings 115a, 115b. In the illustrated example, the sets of upper and lower windings 115a and 115b are arranged along the longitudinal direction (second direction y) of the semiconductor element 11. In each set, the upper and the lower windings 115a, 115b are spaced apart from each other in the thickness direction z and are opposite each other in the thickness direction z. In this embodiment, in each set, the upper and the lower windings 115a and 115b are each planarly wound in a spiral shape. The paired upper and lower windings 115a and 115b are magnetically coupled to each other. Thus, the semiconductor element 11 is configured such that the upper and lower windings 115a, 115b of each pair inductively couple with each other, thereby transmitting electrical signals while ensuring a desired insulated state.

As shown in FIGS. 2, 6 and 7, the semiconductor element 11 has a plurality of pads 111, 112. The plurality of pads 111, 112 are provided on the obverse surface 11a. As shown in FIG. 7, each pad 111 is electrically connected to one of the plurality of lower windings 115b, and each pad 112 is electrically connected to one of the plurality of upper windings 115a. The pads 111, 112 may be made of a material including aluminum, for example. As shown in FIGS. 2, 6, and 7, each pad 111 is bonded to one of the wires 42, and each pad 112 is bonded to one of the wires 41. As shown in FIGS. 2 and 7, the semiconductor element 11 includes a seal ring portion 113. The seal ring portion 113 extends along the respective four outer edges of the semiconductor element 11 in plan view, thereby surrounding the periphery of a circuit forming region. The seal ring portion 113 may be made of copper (Cu), aluminum (A1), or the like.

As shown in FIGS. 7 and 9, the semiconductor element 11 includes a semiconductor substrate 110, a stacking structure 117, and a distributing conductor 118 for desired wiring.

For making the semiconductor substrate 110, use may be made of a Si (silicon) substrate, a SiC (silicon carbide) substrate, and the like. Instead of the semiconductor substrate 110, use may be made of an insulating substrate such as a ceramic substrate or a resin substrate, for example. The seal ring portion 113 is erected on the semiconductor substrate 110 so as to penetrate the stacking structure 117 in the thickness direction z. In this embodiment, the potential of the seal ring portion 113 is approximately the same as that of the semiconductor substrate 110.

The stacking structure 117 is provided on the semiconductor substrate 110. As shown in FIG. 9, the stacking structure 117 includes a plurality of insulation layers 1171. The insulation layers 1171 as a whole are stacked on the upper surface of the semiconductor substrate 110. Each insulation layer 1171 comprises a stacking configuration made up of an etching stopper film as the lower layer and an interlayer insulating film on the upper layer, except for the bottom-most insulation layer 1171 that is in contact with the upper surface of the semiconductor substrate 110. The bottom-most insulation layer 1171 comprises only an interlayer insulation layer. For the etching stopper film, use may be made of a SiN film (silicon nitride film), a SiC film (silicon carbide film), a SiCN film (silicon carbonitride film). For the interlayer insulating film, use may be made of a SiO₂ film (silicon oxide film), for example. Without limitation, the dimension of the plurality of insulation layers 1171 in the thickness direction z may be 2.4 μm, for example. The thicknesses of the respective insulation layers 1171 may be equal to or different from each other.

The upper and lower windings 115a and 115b are formed on different insulation layers 1171 in the stacking structure 117 in a manner such that they face each other across one or more insulation layers 1171. In the illustrated example, the lower windings 115b are formed on the fourth insulation layer 1171 from the semiconductor substrate 110, while the upper windings 115a are formed on the eleventh insulation layer 1171 with six insulation layers 1171 intervening between the upper and lower windings 115a, 115b. The number of the insulation layers 1171 is not limited to the example shown in the figure and can be changed according to, for example, the magnitude of the voltage applied to the pads 111 and the pads 112. A greater number of insulation layers 1171 between the upper windings 115a and the lower windings 115b may ensure a greater dielectric strength or insulation resistance voltage of the semiconductor element 11, while leading to a greater thickness (dimension in the thickness direction z) of the semiconductor element 11. On the other hand, a smaller number of insulation layers 1171 between the upper windings 115a and the lower windings 115b may lower the insulation resistance voltage in the semiconductor element 11, while leading to a smaller thickness (dimension in the thickness direction z) of the semiconductor element 11. In this embodiment, the number of insulation layers 1171 between the upper windings 115a and the lower windings 115b may preferably be 4 at least and 6 at most, considering the relationship between the insulation resistance voltage of the semiconductor element 11 and the thickness of the semiconductor element 11 (desirably small increase in thickness). The dimension in the thickness direction z of the insulation layers 1171 between the upper windings 115a and the lower windings 115b (i.e., the separation distance in the thickness direction z between the upper windings 115a and the lower windings 115b) is not limitative, but may preferably be 9.6 μm at least and 14.4 μm at most. This exemplary dimensional (between 9.6 μm and 14.4 μm) corresponds, for example, to a case where the dimension in the thickness direction z of each insulation layer 1171 between the upper windings 115a and the lower windings 115b is 2.4 μm and the number of insulation layers 1171 between the upper windings 115a and the lower windings 115b is 4 at least and 6 at most.

The distributing conductor 118 electrically connects the plurality of pads 111, 112 to the upper winding 115a and the lower winding 115b. The distributing conductor 118 may include a plurality of penetration wirings 1181 and a lead-out wiring 1182. As shown in FIG. 9, the plurality of penetration wirings 1181 each penetrate one or more insulation layers 1171 in the thickness direction z. In the example shown in FIG. 9, the plurality of penetration wirings 1181 include a wiring that connects a pad 111 to the lead-out wiring 1182, a wiring that connects the lead-out wiring 1182 to the lower winding 115b, and a wiring that connects a pad 112 to the upper winding 115a. The lead-out wiring 1182 is formed on the bottom-most insulation layer 1171. The lead-out wiring 1182 forms part of the conduction path between the pad 111 and the lower winding 115b.

The structure of the semiconductor element 11 is not limited to the example described above. For example, the semiconductor element 11 may include other non-illustrated members such as: a protection film (e.g., SiO₂ film) and a passivation film (e.g., SiN film) that are formed on the obverse surface 11a in a manner such that the pads 111, 112 are exposed to the outside; and a coil protection film selectively covering portions of the area located directly above the upper winding 115a. The upper and lower windings 115a, 115b are not limited to the ones being planarly wound on a single insulation layer 1171, but may be three-dimensionally wound on a desired number of insulation layers 1171. In order to reduce the thickness of the semiconductor element 11, it is preferable that the upper winding 115a and the lower winding 115b are each planarly wound on one insulation layer 1171.

The semiconductor element 12 has an obverse surface 12a and a reverse surface 12b, as shown in FIGS. 6, 7 and 9. The obverse surface 12a and the reverse surface 12b are spaced apart from each other in the thickness direction z. The obverse surface 12a is the upper surface of the semiconductor element 12 and the reverse surface 12b is the lower surface of the semiconductor element 12. The reverse surface 12b faces the lead 32.

The semiconductor element 12 is provided with a functional part 125. The functional part 125 has plural sets of upper windings 125a and lower windings 125b inside, with each upper winding 125a and a corresponding lower winding 125b serving as one set. In other words, the semiconductor element 12 is provided with multiple upper windings 125a and multiple lower windings 125b. In the example shown in FIGS. 7 and 9, the plurality of sets of upper and lower windings 125a and 125b are arranged along the longitudinal direction (second direction y) of the semiconductor element 12. In each set, the upper and the lower windings 125a, 125b are spaced apart from each other in the thickness direction z and are opposite each other in the thickness direction z. By this embodiment, in each set, the upper and the lower windings 125a and 125b are each planarly wound in a spiral shape. The paired upper and lower windings 125a and 125b are magnetically coupled to each other. Thus, the semiconductor element 12 is configured such that the upper and lower windings 125a, 125b of each pair inductively couple with each other, thereby transmitting electrical signals while ensuring a desired insulated state.

As shown in FIGS. 2, 6 and 7, the semiconductor element 12 has a plurality of pads 121, 122. The plurality of pads 121, 122 are provided on the obverse surface 12a. As shown in FIG. 7, each pad 121 is electrically connected to one of the plurality of lower windings 125b, and each pad 122 is electrically connected to one of the plurality of upper windings 125a. The pads 121, 122 may be made of a material including aluminum, for example. As shown in FIGS. 2, 6, and 7, each of the plurality of pads 121 is bonded to one of the plurality of wires 43, and each of the plurality of pads 122 is bonded to one of the plurality of wires 41. As shown in FIGS. 2 and 7, the semiconductor element 12 includes a seal ring portion 123. The seal ring portion 123 extends along the respective four outer edges of the semiconductor element 12 in plan view and surrounds the periphery of a circuit forming region. The seal ring portion 123 may be made of copper (Cu), aluminum (A1), or the like.

As shown in FIGS. 7 and 9, the semiconductor element 12 includes a semiconductor substrate 120, a stacking structure 127, and a distributing conductor 128.

For the semiconductor substrate 120, use may be made of a Si (silicon) substrate, a SiC (silicon carbide) substrate, and the like. Instead of the semiconductor substrate 120, use may be made of an insulating substrate such as a ceramic substrate or a resin substrate, for example. The seal ring portion 123 is erected on the semiconductor substrate 120 so as to penetrate the stacking structure 127 in the thickness direction z. In this embodiment, the potential of the seal ring portion 123 is approximately the same as that of the semiconductor substrate 120.

The stacking structure 127 is formed on the semiconductor substrate 120. As shown in FIG. 9, the stacking structure 127 includes a plurality of insulation layers 1271. The insulation layers 1271 are stacked on the upper surface of the semiconductor substrate 120. Each of the insulation layers 1271 comprises a stacking configuration made up of an etching stopper film as the lower layer and an interlayer insulating film on the upper layer, except for the bottom-most insulation layer 1271 that is in contact with the upper surface of the semiconductor substrate 120. The bottom-most insulation layer 1271 comprises only an interlayer insulation layer. For the etching stopper film, use may be made of a SiN film (silicon nitride film), a SiC film (silicon carbide film), a SiCN film (silicon carbonitride film). For the interlayer insulating film, use may be made of a SiO₂ film (silicon oxide film), for example. Without limitation, the dimension of the plurality of insulation layers 1271 in the thickness direction z may be 2.4 μm, for example. The thicknesses of the respective insulation layers 1271 may be equal to or different from each other.

The upper and lower windings 125a and 125b are formed on different insulation layers 1271 in the stacking structure 127 in a manner such that they face each other across one or more insulation layers 1271. In the illustrated example, the lower windings 125b are formed on the fourth insulation layer 1271 from the semiconductor substrate 120, while the upper windings 125a are formed on the eleventh insulation layer 1271 with six insulation layers 1271 intervening between the upper and lower windings 125a, 125b. The number of the insulation layers 1271 is not limited to the example shown in the figure and can be changed according to, for example, the magnitude of the voltage applied to the pads 121 and the pads 122. A greater number of insulation layers 1271 between the upper windings 125a and the lower windings 125b may ensure a greater insulation resistance voltage in the semiconductor element 12, while leading to a greater thickness (dimension in the thickness direction z) of the semiconductor element 12. On the other hand, a smaller number of insulation layers 1271 between the upper windings 125a and the lower windings 125b may lower the insulation resistance voltage in the semiconductor element 12, while leading to a smaller thickness (dimension in the thickness direction z) of the semiconductor element 12. In this embodiment, the number of insulation layers 1271 between the upper windings 125a and the lower windings 125b may preferably be 4 at least and 6 at most, considering the relationship between the insulation resistance voltage of the semiconductor element 12 and the thickness of the semiconductor element 12 (inhibition of increase in thickness). The dimension in the thickness direction z of the insulation layers 1271 between the upper windings 125a and the lower windings 125b (i.e., the separation distance in the thickness direction z between the upper windings 125a and the lower windings 125b) is not limitative, but may preferably be 9.6 μm at least and 14.4 μm at most. This exemplary dimensional (i.e., between 9.6 μm and 14.4 μm) corresponds, for example, to a case where the dimension in the thickness direction z of each insulation layer 1271 between the upper windings 125a and the lower windings 125b is 2.4 μm and the number of insulation layers 1271 between the upper windings 125a and the lower windings 125b is 4 at least and 6 at most.

The distributing conductor 128 may electrically connect the plurality of pads 121, 122 to the upper winding 125a and the lower winding 125b. The distributing conductor 128 includes a plurality of penetration wirings 1281 and a lead-out wiring 1282. As shown in FIG. 9, the plurality of penetration wirings 1281 each penetrate one or more insulation layers 1271 in the thickness direction z. In the example shown in FIG. 9, the plurality of penetration wirings 1281 include a wiring that connects a pad 121 to the lead-out wiring 1282, a wiring that connects the lead-out wiring 1282 to the lower winding 125b, and a wiring that connects a pad 122 to the upper winding 125a. The lead-out wiring 1282 is formed on the bottom-most insulation layer 1271. The lead-out wiring 1282 forms part of the conduction path between the pad 121 and the lower winding 125b.

The structure of the semiconductor element 12 is not limited to the example described above. For example, the semiconductor element 12 may include non-illustrated members such as: a protection film (e.g., SiO₂ film) and a passivation film (e.g., SiN film) that are formed on the obverse surface 12a in a manner such that the pads 121, 122 are exposed to the outside; and a coil protection film selectively covering portions of the area located directly above the upper winding 125a. The upper and lower windings 125a, 125b are not limited to the ones being planarly wound on a single insulation layer 1271, but may be three-dimensionally wound on a desired number of insulation layers 1271. In order to reduce the thickness of the semiconductor element 12, it is preferable that the upper winding 125a and the lower winding 125b are each planarly wound on one insulation layer 1271.

In the semiconductor device A1, the semiconductor element 14 requires a higher supply of voltage than that required for the semiconductor element 13. Thus, a potential difference is generated between the semiconductor element 13 and the semiconductor element 14. In light of this, a first circuit including the semiconductor element 13 as a constituting component and a second circuit including the semiconductor element 14 as a constituting component are insulated from each other by the semiconductor elements 11 and 12. The components of the first circuit include, a third semiconductor element 13, a lead 31 and a plurality of leads 33, a plurality of wires 42, a plurality of wires 44 and a wire 46, and a portion of the semiconductor element 11 (such as the pads 111 and the lower windings 115b). The second circuit includes a fourth semiconductor element 14, a lead 32, a plurality of leads 34, a plurality of wires 43, a plurality of wires 45 and a wire 47, and a portion of the semiconductor element 12 (such as the pads 121 and the lower windings 125b). The first circuit and the second circuit have different potentials relative to each other. In the semiconductor device A1, the potential of the second circuit is higher than that of the first circuit. The semiconductor elements 11 and 12 relay mutual signals between the first circuit and the second circuit. For example, in inverter devices used in electric or hybrid vehicles, the voltage applied to the ground of the semiconductor element 13 is about 0 V, while the voltage applied to the ground of the semiconductor element 14 may be 600 V or higher transiently. Depending on the specifications of the inverter device, the voltage applied to the ground of semiconductor element 14 may be 3750 V or higher.

In the semiconductor device A1, it can be considered that a third circuit is provided between the first circuit and the second circuit by electrically insulating them with the semiconductor elements 11, 12 (i.e., two insulating elements), where the third circuit has an intermediate potential between the potential of the first circuit and that of the second circuit. As such, the semiconductor device A1 includes a third circuit in addition to the first and second circuits. In this embodiment, the third circuit includes a portion of the semiconductor element 11 (such as the upper windings 115a and the pads 112), a portion of the second semiconductor element 12 (such as the upper windings 125a and the pads 122), and a plurality of wires 41. When the potential of the second circuit is higher than the potential of the first circuit, the potential of the third circuit is higher than the potential of the first circuit and lower than the potential of the second circuit. In the present embodiment, the semiconductor element 11 and the semiconductor element 12 are equally configured, thereby equally sharing the voltage difference between the first and second circuits for insulating. Thus, the potential of the third circuit corresponds to the half of the potential difference between the first and the second circuits. Alternatively, the potential of the third circuit may be shifted toward the potential of the first circuit or toward the potential of the second circuit, thereby deviating from the middle potential between those of the first and second circuits.

The conductive support 3 constitutes a conductive path for connecting the semiconductor element 11, the semiconductor element 12, the semiconductor element 13 and the semiconductor element 14 to the circuit board on which the semiconductor device A1 is mounted. The conductive support 3 may be obtained, for example, from the same lead frame, as will be described in detail later. The lead frame may be made of copper or a copper alloy, but may also be made of other metallic materials. The conductive support 3 includes a lead 31, a lead 32, a plurality of leads 33 and a plurality of leads 34, as noted above.

The leads 31 and 32 are spaced apart from each other in the first direction x, as shown in FIGS. 1 and 2. In the semiconductor device A1, the semiconductor element 11 and the semiconductor element 13 are mounted on the lead 31, while the semiconductor element 12 and the semiconductor element 14 are mounted on the other lead 32.

The lead 31 includes an island portion 311 and two terminal portions 312, as shown in FIG. 2.

The island portion 311 has a mount surface 311a facing one side of the thickness directions z (upward), as shown in FIGS. 6 and 7. As shown in FIG. 7, the semiconductor element 11 is bonded to the mount surface 311a via a conductive bonding material 119, and the semiconductor element 13 is bonded to the mount surface 311a via a conductive bonding material 139. The semiconductor substrate 110 of the semiconductor element 11 is substantially at the same potential as the island portion 311 via the conductive bonding material 119. The conductive bonding material 119, 139 is, for example, solder, metal paste or sintered metal. The island portion 311 is covered by the sealing resin 5. In the illustrated example, the island portion 311 is rectangular in plan view. The thickness of the island portion 311 is, for example, 100 μm at least and 300 μm at most. Differing from the illustrated example, the island portion 311 may be formed with a through-hole extending through the island portion 311 in the thickness direction z. The through-hole may be formed, for example, between the semiconductor element 11 and the semiconductor element 13.

As shown in FIG. 2, two terminal portions 312 extend from the respective sides of the island portion 311 in the second direction y. The two terminal portions 312 are spaced apart from each other in the second direction y. At least one of the two terminal portions 312 is electrically connected to the ground of the semiconductor element 13 via the wire 46. Each of the two terminal portions 312 has a covered portion 312a and an exposed portion 312b. The covered portion 312a is connected to the island portion 311 and covered by the sealing resin 5. The exposed portion 312b is connected to the covered portion 312a and is exposed from the sealing resin 5. In plan view, the exposed portion 312b extends along the first direction x. As shown in FIG. 3, as viewed in the second direction y, the exposed portion 312b is bent in a gull wing shape. The surface of the exposed portion 312b may be plated with tin (Sn), for example.

The lead 32 has an island portion 321 and two terminal portions 322, as shown in FIG. 2.

The island portion 321 has a mount surface 321a facing one side of the thickness directions z (upward), as shown in FIGS. 6 and 7. As shown in FIG. 7, the semiconductor element 12 is bonded to the mount surface 321a via a conductive bonding material 129 and the semiconductor element 14 is bonded to the mount surface 321a via a conductive bonding material 149. The semiconductor substrate 120 of the semiconductor element 12 is substantially at the same potential as the island portion 321 via the conductive bonding material 129. The conductive bonding material 129, 149 is, for example, solder, metal paste or sintered metal. The island portion 321 is covered by the sealing resin 5. In the illustrated example, the island portion 321 is rectangular in plan view. The thickness of the island portion 321, like the island portion 311, is, for example, 100 μm at least and 300 μm at most. Differing from the illustrated example, the island portion 321 may be formed with a through-hole extending through it in the thickness direction z. The through-hole may be formed, for example, between the semiconductor element 12 and the semiconductor element 14.

As shown in FIG. 2, two terminal portions 322 extend from the respective sides of the island portion 321 in the second direction y. The two terminal portions 322 are spaced apart from each other in the second direction y. At least one of the two terminal portions 322 is electrically connected to the ground of the semiconductor element 14 via the wire 47. Each of the two terminal portions 322 has a covered portion 322a and an exposed portion 322b. The covered portion 322a is connected to the island portion 321 and is covered by the sealing resin 5. The exposed portion 322b is connected to the covered portion 322a and is exposed from the sealing resin 5. In plan view, the exposed portion 322b extends along the first direction x. As shown in FIG. 3, as viewed in the second direction y, the exposed portion 322b is bent in a gull wing shape. The surface of the exposed portion 322b may be plated with tin, for example.

As shown in FIGS. 1 and 2, the plurality of leads 33 are located opposite from the island portion 321 of the lead 32 with respect to the island portion 311 of the lead 31 in the first direction x. The plurality of leads 33 are arranged along the second direction y. At least one of the plurality of leads 33 is electrically connected to the semiconductor element 13 via the wire 44. The plurality of leads 33 include a plurality (four in the illustrated example) of intermediate leads 33A and two lateral leads 33B. The two lateral leads 33B are located on the respective sides of the group of the intermediate leads 33A in the second direction y. In the second direction y, each of the two lateral leads 33B is located between a corresponding one of the two first terminal portions 312 of the lead 31 and the intermediate lead 33A which is closest to the corresponding first terminal portion 312.

As shown in FIG. 2 and FIG. 6, the plurality of leads 33 (intermediate leads 33A and two lateral leads 33B) each have a covered portion 331 and an exposed portion 332. The covered portion 331 is covered by the sealing resin 5. In the illustrate example, the dimension in the first direction x of each covered portion 331 of the two lateral leads 33B is greater than the dimension in the first direction x of each covered portion 331 of the plurality of intermediate leads 33A. As shown in FIGS. 2 and 6, the exposed portion 332 is connected to the covered portion 331 and exposed from the sealing resin 5. In plan view, the exposed portion 332 extends along the first direction x. As understood from FIGS. 2 to 4, as viewed in the second direction y, the exposed portion 332 is bent in a gull wing shape. The shape of the exposed portion 332 is equal to the shape of the exposed portion 312b of each terminal portion 312 of the first lead 31. The surface of the exposed portion 332 may be tin plated, for example.

The shape, arrangement and number of the leads 33 are not limited to the example shown in the figure. For example, the leads 33 may be fewer or more than the illustrated example (six leads). Some of the leads 33 may be located outside of either of the two terminal portions 312 of lead 31.

The leads 34 are located opposite the leads 33 with respect to the island portion 321 of the lead 32 in the first direction x, as shown in FIGS. 1 and 2. The leads 34 are arranged along the second direction y. At least one of the leads 34 is electrically connected to the semiconductor element 14 via the wire 45. The leads 34 include a plurality of intermediate leads 34A (four in the illustrated example) and two lateral leads 34B. The two lateral leads 34B are located one on each side of the intermediate leads 34A in the second direction y. In the second direction y, each lateral lead 34B is located between the terminal portion 322 of one of the two leads 32 and and the intermediate lead 34A closest to the terminal portion 322.

As shown in FIG. 2 and FIG. 6, the leads 34 (the intermediate leads 34A, two lateral leads 34B) each have a covered portion 341 and an exposed portion 342. The covered portions 341 are covered by the sealing resin 5. In the illustrated example, the dimension of each covered portion 341 of the two lateral leads 34B in the first direction x is greater than the dimension of each covered portion 341 of the intermediate leads 34A in the first direction x. As shown in FIGS. 2 and 6, the exposed portions 342 are connected to the covered portions 341 and exposed from the sealing resin 5. In plan view, each exposed portion 342 extends along the first direction x. As understood from FIGS. 2, 3 and 5, as viewed in the second direction y, the exposed portion 342 is bent in a gull wing shape. The shape of the exposed portion 342 is equal to the shape of the exposed portion 322b of the terminal portion 322 of each second lead 32. The surface of the exposed portion 342 may be tin plated, for example.

The shape, arrangement and number of the leads 34 are not limited to those of the illustrated examples. For example, the leads 34 may be provided fewer or more than the illustrated example (i.e., six leads). Some of the leads 34 may be located outside of either of the second terminal portions 322 of the two lead 32.

The connection members 4 each electrically connect two points or locations spaced apart from each other. As noted above, the connection members 4 include a plurality of wires 41, a plurality of wires 42, a plurality of wires 43, a plurality of wires 44, a plurality of wires 45, a wire 46 and a wire 47.

The wires 41, the wires 42, the wires 43, the wires 44, the wires 45, the wire 46 and the wire 47 are each made of a metallic material which may include gold, copper or aluminum, for example. The connection members 4 may be bonding ribbons or metallic sheets or strips, instead of the wires 41, the wires 42, the wires 43, the wires 44, the wires 45, the wire 46 and the wire 47.

The wires 41 are each bonded to one of the pads 112 of the semiconductor element 11 and one of the pads 122 of the semiconductor element 12, as shown in FIG. 2 and FIG. 7. Each wire 41 electrically connects the semiconductor element 11 and the semiconductor element 12. The wires 41 are arranged along the second direction y. In plan view, each wire 41 bridges between the island portion 311 of the lead 31 and the island portion 321 of the lead 32.

As shown in FIG. 7, each wire 41 includes a neck portion 411, a joint portion 412, and a loop portion 413. In each wire 41, the neck portion 411 is a portion that is bonded to one of the pads 112 and extends in the thickness direction z. The joint portion 412 is a portion bonded to one of the pads 122. The loop portion 413 is connected to the neck portion 411 and the joint portion 412. The loop portion 413 extends from the neck portion 411 to the joint portion 412 while curving. Each wire 41 may be formed by a ball bonding process, and is first-bonded to one of the pads 112 and second-bonded to one of the pads 122. Alternatively, each wire 41 may be formed by other techniques such as wedge bonding. When such a wire 41 is formed by wedge bonding, a joint portion having a generally same shape as that of the joint portion 412 may be bonded to a pad 112 instead of the neck portion 411.

Each of the wires 42 is bonded to one of the pads 111 of the semiconductor element 11 and one of the pads 131 of the semiconductor element 13, as shown in FIGS. 2 and 7. Each wire 42 electrically connects the semiconductor element 11 and the semiconductor element 13. The wires 42 are arranged along the second direction y.

As shown in FIG. 7, each wire 42 includes a neck portion 421, a joint portion 422, and a loop portion 423. In each second wire 42, the neck portion 421 is a portion that is bonded to one of the pads 111 and extends in the thickness direction z. The joint portion 422 is a portion bonded to one of the pads 131. The loop portion 423 is connected to the neck portion 421 and the joint portion 422. The loop portion 423 extends from the neck portion 421 to the joint portion 422 while curving. Each wire 42 may be formed by a ball bonding process, and is first-bonded to one of the pads 111 and second-bonded to one of the pads 131. Alternatively, each wire 42 may be formed by other techniques such as wedge bonding. When such a wire 42 is formed by wedge bonding, a joint portion having a generally same shape as that of the joint portion 422 may be bonded to a pad 111 instead of the neck portion 421.

Each of the wires 43 is bonded to one of the pads 121 of the semiconductor element 12 and one of the pads 141 of the semiconductor element 14, as shown in FIG. 2 and FIG. 7. Each wire 43 electrically connects the semiconductor element 12 and the semiconductor element 14. The wires 43 are arranged along the second direction y.

As shown in FIG. 7, each wire 43 includes a neck portion 431, a joint portion 432, and a loop portion 433. In each wire 43, the neck portion 431 is a portion that is bonded to one of the pads 121 and extends in the thickness direction z. The junction 432 is a portion bonded to one of the pads 141. The loop portion 433 is connected to the neck portion 431 and the joint portion 432. The loop portion 433 extends from the neck portion 431 toward the joint portion 432 while curving. Each wire 43 may be formed by a ball bonding process, and is first-bonded to one of the pads 121 and second-bonded to one of the pads 141. Alternatively, each wire 43 may be formed by other techniques such as wedge bonding. When a wire 43 is formed by wedge bonding, a joint portion having a generally same shape as that of the joint portion 432 is bonded to a pad 121 instead of the neck portion 431.

Each wire 44 is bonded to one of the pads 131 of the semiconductor element 13 and to the covered portion 331 of one of the leads 33, as shown in FIG. 2. Each wire 44 electrically connects the semiconductor element 13 and one of the leads 33.

Each wire 45 is bonded to one of the pads 141 of the semiconductor element 14 and to the covered portion 341 of one of the leads 34, as shown in FIG. 2. Each wire 45 electrically connects the semiconductor element 14 and one of the leads 34.

The wire 46 is bonded to one of the pads 131 of the semiconductor element 13 and to the covered portion 312a of one of the two first terminal portions 312, as shown in FIG. 2. The wire 46 electrically connects the semiconductor element 13 and the lead 31. The number of wires 46 is not limited to one, and more than one wire 46 may be used.

The wire 47 is bonded to one of the pads 141 of the semiconductor element 14 and to the covered portion 322a of one of the two terminal portions 322, as shown in FIG. 2. The wire 47 electrically connects the semiconductor element 14 and the lead 32. The number of wires 47 is not limited to one, and more than one wire 47 may be used.

The sealing resin 5 covers the semiconductor element 11, the semiconductor element 12, the semiconductor element 13, the semiconductor element 14, a part of the conductive support 3, and the connection members 4, as shown in FIG. 1. The sealing resin 5 has electrical insulation properties. The sealing resin 5 insulates the components of the first circuit (e.g., the leads 31) and the components of the second circuit (e.g., the leads 32) from each other. The sealing resin 5 may be made of a material including, for example, a black epoxy resin. In the illustrated example, the sealing resin 5 is rectangular in plan view.

As shown in FIGS. 2-5, the sealing resin 5 has a top face 51, a bottom face 52, a pair of side faces 53, and a pair of side faces 54.

As shown in FIGS. 3 to 5, the top face 51 and bottom face 52 are spaced apart from each other in the thickness direction z. The top face 51 and the bottom face 52 face away from each other in the thickness direction z. Each of the top face 51 and the bottom face 52 is flat.

As shown in FIGS. 3-5, the pair of side faces 53 connect to the top face 51 and the bottom face 52 and are spaced apart from each other in the first direction x. The exposed portion 312b of each of the two terminal portions 312 (leads 31) and the exposed portion 332 of each of the leads 33 are exposed from the side face 53 located on the first side of the first direction x. Likewise, the exposed portion 322b of each of the two terminal portions 322 (leads 32) and the exposed portion 342 of each of the leads 34 are exposed from the side face 53 located on the second or the other side of the first direction x.

As shown in FIGS. 3-5, each side face 53 includes an upper portion 531, a lower portion 532, and a middle portion 533. The upper portion 531 has one edge, on one side of the thickness direction, which is connected to the top face 51 and an another edge, on the other side of the thickness direction, which is connected to the middle portion 533 z. The upper portion 531 is inclined with respect to the top face 51. The lower portion 532 has one edge, on one side of the thickness direction, which is connected to the bottom face 52 and another edge, on the other side of the thickness direction, which is connected to the middle portion 533. The lower portion 532 is inclined with respect to the bottom face 52. The middle portion 533 has one edge, on one side of the thickness direction, which is connected to the upper portion 531 and an another edge, on the other side of the thickness direction z, which is connected to the lower portion 532. The middle portion 533 has the thickness direction z and the second direction y as examples of its in-plane directions. In plan view, the middle portion 533 is located outwardly relative to the top face 51 and the bottom face 52. From the middle portions 533 of the two side faces 53 are exposed the following portions: the exposed portions 312b of the two terminal portions 312 (leads 31), the exposed portions 322b of the two terminal portions 322 (leads 32), the exposed portions 332 of the leads 33, and the exposed portions 342 of the leads 34.

As shown in FIGS. 3-5, the two side faces 54 connect to the top face 51 and the bottom face 52 and are spaced apart from each other in the second direction y. As shown in FIG. 1, the lead 31, the lead 32, the leads 33 and the leads 34 are spaced away from the two side faces 54.

As shown in FIGS. 3-5, each side face 54 includes an upper portion 541, a lower portion 542, and a middle portion 543. The upper portion 541 is connected, at one edge, to the top face 51 on one side of the thickness direction z and connected, at the other edge, to the middle portion 543 on the other side of the thickness direction z. The upper portion 541 is inclined with respect to the top face 51. The lower portion 542 is connected, at one edge, to the bottom face 52 on one side in the direction of thickness z and connected, at the other edge, to the middle portion 543 on the other side in the direction of thickness z. The lower portion 542 is inclined with respect to the bottom face 52. The middle portion 543 is connected, at one edge, to the upper portion 541 on one side of the thickness direction and connected, at the other edge, to the lower portion 542 on the other side of the thickness direction. The middle portion 543 contains the thickness direction z and the second direction y as examples of its in-plane directions. In plan view, the middle portion 543 is located outwardly relative to the top face 51 and the bottom face 52.

Generally, in a motor driver circuit in an inverter device, it is common to configure a half-bridge circuit that includes a low-side (low potential side) switching element and a high-side (high potential side) switching element. In the following description, without limitation, these switching elements are MOSFETs. In the low-side switching element, the reference potentials for the source of the switching element and for the gate driver to drive the switching element are the potential of the ground. On the other hand, in the high-side switching element, the reference potentials for the source of the switching element and the gate driver to drive the switching element correspond to the potential at the output node of the half-bridge circuit. Since the potential at the output node changes according to the driving of the high-side and low-side switching elements, the reference potential of the gate driver to drive the high-side switching element changes. When the high-side switching element is on, the reference potential is equivalent to the voltage applied to the drain of the high-side switching element (e.g., 600 V or more). In the semiconductor device A1, the ground of the semiconductor element 13 and the ground of the semiconductor element 14 are separated from each other. Thus, when the semiconductor device A1 is used as a gate driver to drive the high-side switching element, a voltage equivalent to the voltage applied to the drain of the high-side switching element is applied transiently to the ground of the semiconductor element 14.

In the semiconductor device A1, it is configured that the distance between any two constituents selected from a constituent of the first circuit, a constituent of the second circuit and a constituent of the third circuit is greater than the distance d0 [mm] determined by the following formula (1). In Formula (1), the term “Y” is the required length of insulation life [years] for the semiconductor device A1, the terms “A” and “B” are constants depending on the material of the sealing resin 5, and the term “X” is the voltage (effective value) [kVrms] used in the semiconductor device A1. The voltage X is, for example, the difference of voltage applied between two target points or sites. In the semiconductor device A1, AC voltage is generated by the switching elements in operation, and the effective value is used for the voltage X. In an example where the sealing resin 5 is made of an epoxy resin, the constant A is 1000×416 and the constant B is 16. In the formula, the number “0.15” is an offset value for calculating the distance d0 [mm]. The unit of the offset value may be [mm]/(([year]\hat{ }(1/B))×[kVrms]) so that the dimension of the right side of Formula (1) corresponds to the dimension of the left side (i.e., distance d0) of Formula (1). As understood from Formula (1), the distance d0 becomes greater as the voltage is greater, and/or the insulation life year is greater, and it also depends on the material of the sealing resin 5. For instance, the distance d0 calculated by Formula (1) is about 0.0294 [mm] (=29.4 [μm]) when the insulation life year Y is 20 [years], the voltage X is 1 [kVrms], and the constant A is 1000×416 for epoxy resin. Note that “(Y/A)\hat{ }(1/B)” is the B-squared root (positive real number) of (Y/A).

$$d 0 = ( ( Y / A ) \hat{} ( 1 / B ) ) \times 0.15 \times ( X ) \qquad ( 1 )$$

Specifically, the distance d1 (see FIG. 7) in the first direction X between the lead 31 and the lead 32 is greater than the distance d0 noted above. In setting the distance d1, the voltage X is, for example, the difference between the voltage applied to the first circuit (lead 31) and the voltage applied to the second circuit (lead 32). In the example shown in FIG. 7, the distance d1 is the shortest distance between the island portions 311 and 321 where they are closest to each other. The distance d1 may be 10 mm or less, for example. This serves to prevent the semiconductor device A1 from becoming unduly large. In the semiconductor device A1, the distance d1 may be about 300 μm, which is greater than the distance d0 (29.4 μm) in the above example.

The distance d2 between each wire 41 and the semiconductor element 11 (see FIG. 7) is greater than the distance d0. In the example shown in FIG. 7, the distance d2 is the distance in the thickness direction z where the loop portion 413 and the seal ring portion 113 of the semiconductor element 11 are closest to each other. In this embodiment, each wire 41 is a component of the third circuit, which is at an intermediate potential between the first and second circuits. Hence, in setting the distance d2, the voltage X may be the difference between the voltage applied to the third circuit (each wire 41) and the voltage applied to the first circuit (seal ring portion 113 of the semiconductor element 11). As seen from this, the voltage X in setting the distance d2 may be lower than the voltage X in setting the distance d1. Alternatively, the voltage X in setting the distance d2 may be higher than the voltage difference between the third circuit and the first circuit. For example, it may be the same as the voltage X in setting the distance d1. The distance d2 may be 10 mm or less, for example. This serves to prevent the semiconductor device A1 from becoming unduly large. In the semiconductor device A1, the distance d2 may be about 170 μm, which is greater than the distance d0 (29.4 μm) in the example above.

The distance d2′ (see FIG. 7) between each wire 41 and the lead 31 is greater than the distance d0. In the example shown in FIG. 7, the distance d2′ is the distance in the thickness direction z where each loop portion 413 and the mount surface 311a of the island portion 311 are closest to each other. For setting the distance d2′, the difference between the voltage applied to the third circuit (each wire 41) and the voltage applied to the first circuit (lead 31) may be used for the voltage X, as in setting the distance d2. Alternatively, the voltage X in setting the distance d2′ may be greater than the voltage difference between the third circuit and the first circuit. For example, it may be the same as the voltage X in setting the distance d1. The distance d2′ may be 10 mm or less, for example. This prevents the semiconductor device A1 from becoming unduly large. In the semiconductor device A1, the distance d2′ may be about 470 μm, which is greater than the distance d0 (29.4 μm) in the above example.

The distance d3 (see FIG. 7) between each wire 41 and the semiconductor element 12 is greater than the distance d. In the example shown in FIG. 7, the distance d3 is the shortest distance in the thickness direction z where each loop portion 413 and the seal ring portion 123 of the semiconductor element 12 are closest to each other. In this embodiment, since each wire 41 is a component of the third circuit, which is at an intermediate potential between the first and the second circuits, in setting the distance d3, the voltage X is, for example, the difference between the voltage applied to the third circuit (each wire 41) and the voltage applied to the second circuit (seal ring portion 123 of semiconductor element 12). As such, the voltage X in setting the distance d3 may be lower than the voltage X in setting the distance d1. Alternatively, the voltage X in setting the distance d3 may be higher than the voltage difference between the third circuit and the second circuit. For example, it may be the same as the voltage X in setting the distance d1. The distance d3 may be 10 mm or less, for example. This prevents the semiconductor device A1 from becoming unduly large. In the semiconductor device A1, the distance d3 may be about 170 μm, which is greater than the distance d0 (29.4 μm) in the above example.

The distance d3′ (see FIG. 7) between each wire 41 and the lead 32 is greater than the distance d0. In the example shown in FIG. 7, the distance d3′ is the shortest distance in the thickness direction z where each loop portion 413 and the mount surface 321a of the island portion 321 are closest to each other. The difference between the voltage applied to the third circuit (each wire 41) and the voltage applied to the second circuit (lead 32) may be used for the voltage X in setting the distance d3′, as in setting the distance d3. Alternatively, the voltage X in setting the distance d3′ may be greater than the voltage difference between the third and the second circuits. For example, it may be the same as the voltage X in setting the distance d1. The distance d3′ may be 10 mm or less, for example. This prevents the semiconductor device A1 from becoming unduly large. In the semiconductor device A1, the distance d3′ may be about 470 μm, which is greater than the distance d0 (29.4 μm) in the above example.

The distance d4 between the wire(s) 41 and the wire(s) 42 (see FIG. 7) is greater than the distance d0. In the example shown in FIG. 7, the distance d4 is the shortest distance in the direction orthogonal to the thickness direction z (the first direction x in FIG. 7) at the points where the neck portion 411 and the neck portion 421 are closest to each other. In this embodiment, the wires 41 are a component of the third circuit, which is at an intermediate potential between the first and the second circuits. Thus, in setting the distance d4, the difference between the voltage applied to the third circuit (each wire 41) and the voltage applied to the first circuit (each wire 42) may be used for the voltage X, for example. As such, the voltage X in setting the distance d4 may be lower than the voltage X in setting the distance d1. Alternatively, the voltage X in setting the distance d4 may be greater than the voltage difference between the third circuit and the first circuit. For example, it may be the same as the voltage X in setting the distance d1. In the semiconductor device A1, the distance d4 may be about 300 μm, which is greater than the distance d0 (29.4 μm) in the above example.

The distance d5 between the wire(s) 41 and the wire(s) 43 (see FIG. 7) is greater than the distance d0. In the example shown in FIG. 7, the distance d5 is the shortest distance in the direction orthogonal to the thickness direction z (the first direction x in FIG. 7) where the joint portion 412 and the neck portion 431 are closest to each other. In this embodiment, the wires 41 are a component of the third circuit, which is at an intermediate potential between the first and the second circuits. Thus, in setting the distance d5, the difference between the voltage applied to the third circuit (each wire 41) and the voltage applied to the second circuit (each wire 43) may be used for the voltage X, for example. As such, the voltage X in setting the distance d5 may be lower than the voltage X in setting the distance d1. Alternatively, the voltage X in setting the distance d5 may be higher than the voltage difference between the third and the second circuits. For example, it may be the same as the voltage X in setting the distance d1. In the semiconductor device A1, the distance d5 may be about 300 μm, which is greater than the distance d0 (29.4 μm) in the above example.

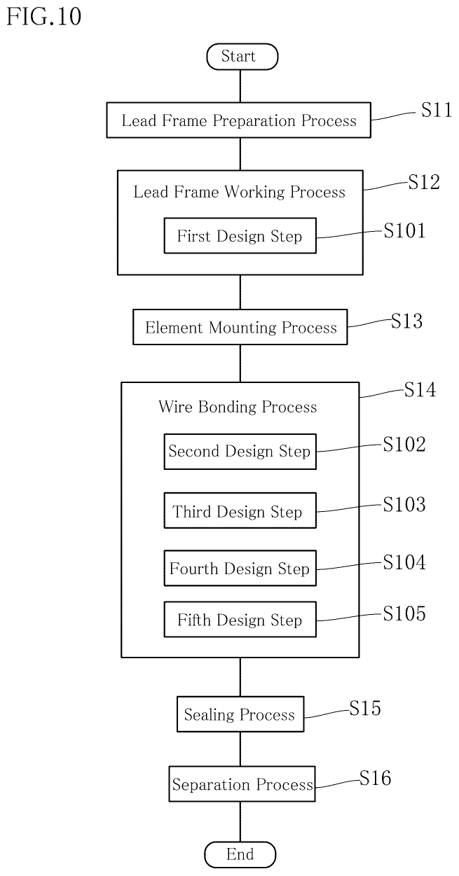

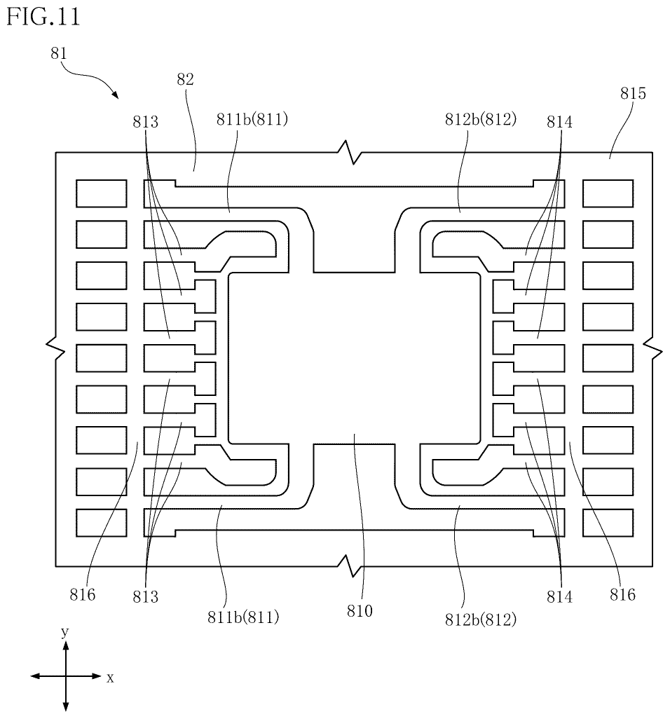

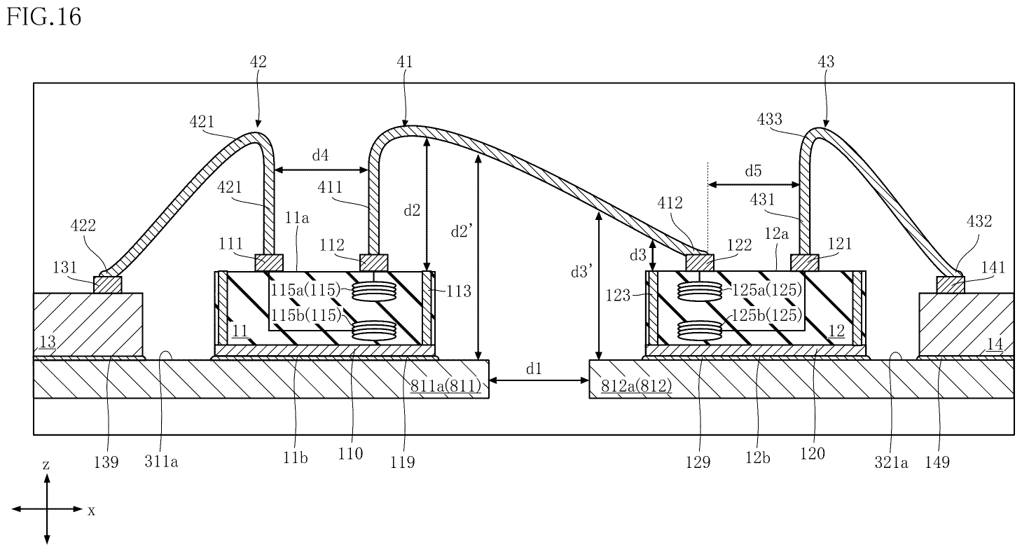

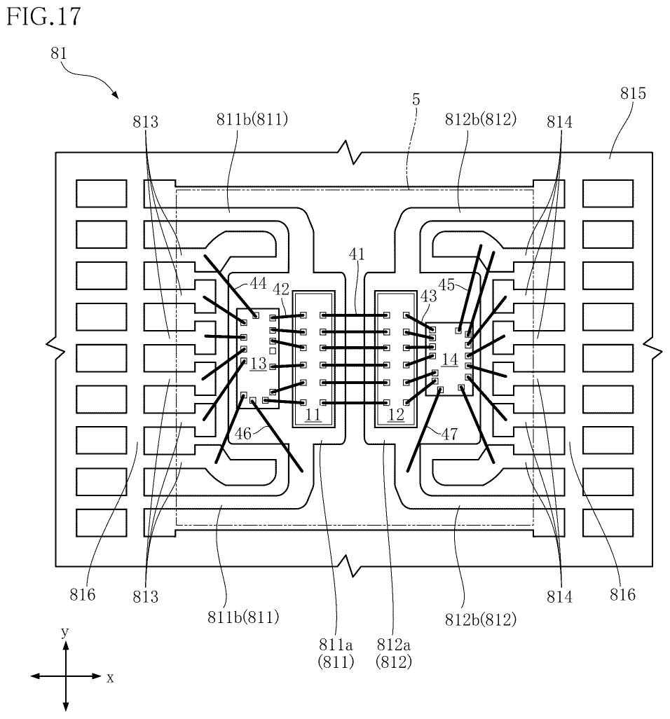

Next, an example of manufacturing method for the semiconductor device A1 will be described with reference to FIGS. 10-17. FIG. 10 is a flowchart illustrating an example of the manufacturing method of the semiconductor device A1. FIGS. 11-15 and 17 show a plan view illustrating some processes of the manufacturing method of the semiconductor device A1. FIG. 16 is a cross-sectional view showing a process of the manufacturing method of the semiconductor device A1. The cross-section of FIG. 16 corresponds in location to the cross-section of FIG. 7.

As shown in FIG. 10, the manufacturing method of the semiconductor device A1 of the present embodiment includes a lead frame preparation process S11, a lead frame working process S12, an element mounting process S13, a wire bonding process S14, a sealing process S15 and a separation process S16. Further, the manufacturing method for the semiconductor device A1 includes a design method made up of design steps. Specifically, the design steps may include a first design step S101, a second design step S102, a third design step S103, a fourth design step S104, and a fifth design step S105, which are described in detail below.

First, in the lead frame preparation process S11, a lead frame 81 as shown in FIG. 11 is prepared. The lead frame 81 includes a flat portion 810, a plurality of support leads 811b, 812b, a plurality of leads 813, 814, an outer frame 815, and a dam bar 816. The lead frame 81 is produced, for example, by punching out a copper sheet that is rectangular in plan view. As shown in FIG. 11, the support leads 811b, 812b are connected to the flat portion 810. The support leads 811b, 812b and the leads 813, 814 are connected via the outer frame 815 and/or the dam bar 816. The outer frame 815 and the dam bar 816 of the lead frame 81 do not constitute any part of the semiconductor device A1.

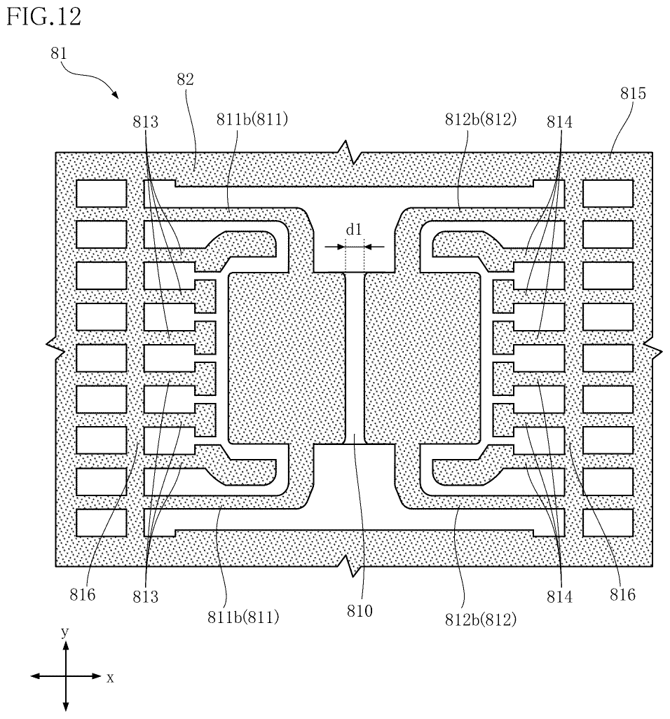

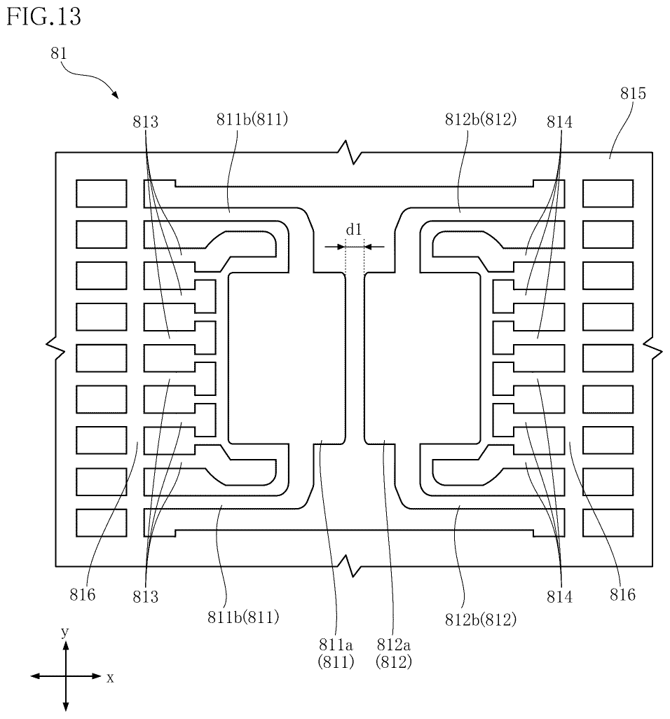

Next, in the lead frame working process S12, the flat portion 810 of the lead frame 81 is to be divided into an island 811a and another island 812a (see FIG. 13). To this end, in the lead frame working process S12, as shown in FIG. 12, a resist 82 is formed on the lead frame 81. In the illustrated example, the parts on which the resist 82 is formed are indicated by dots. Then, an etching process is performed on the lead frame 81 with the resist 82. As a result, the portion of the lead frame 81 exposed from the resist 82 is removed, whereby the flat portion 810 is divided into two islands 811a and 812a, as seen from FIG. 13. Then, the resist 82 is removed, and the lead frame 81 shown in FIG. 13 is obtained. In the lead frame 81 shown in FIG. 13, a first lead 811 is provided by the island 811a and the support leads 811b each connected to the island 811a. Likewise, in the lead frame 81 shown in FIG. 13, a second lead 812 is provided by the island 812a and the support leads 812b each connected to the island 812a.

In this embodiment, the first design step S101 is performed in the lead frame working process S12, as shown in FIG. 10.

In the first design step S101, it is designed that when the flat portion 810 is divided into the islands 811a and 812a, the distance d1 (see Figures. 12, 13 and 16) in the first direction x between the island 811a (lead 811) and the island 812a (lead 812) will be greater than the distance d0, which is determined by Formula (1) mentioned above. As understood from the configuration described in detail below, the island 811a (lead 811) becomes the island portion 311 (lead 31) and the island 812a (lead 812) becomes the island portion 321 (lead 32). In light of this, in designing the distance d1 in the first design step S101, it is designed that the distance d1 in the first direction x between the lead 31 and the lead 32 will be greater than the distance d0. In the first design step S101, it is preferable that the distance d1 is designed to be greater than the distance d0 but less than or equal to 10 mm, for example, which serves to prevent the semiconductor device A1 from becoming unduly large.

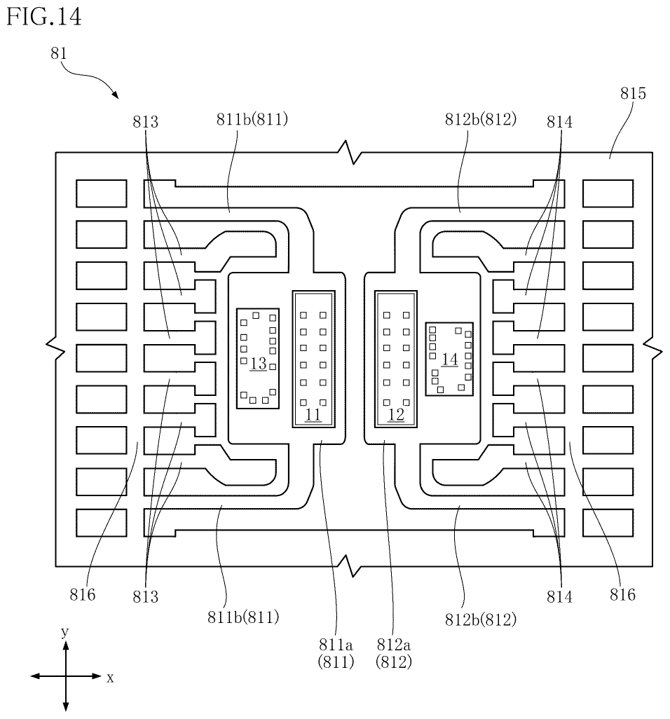

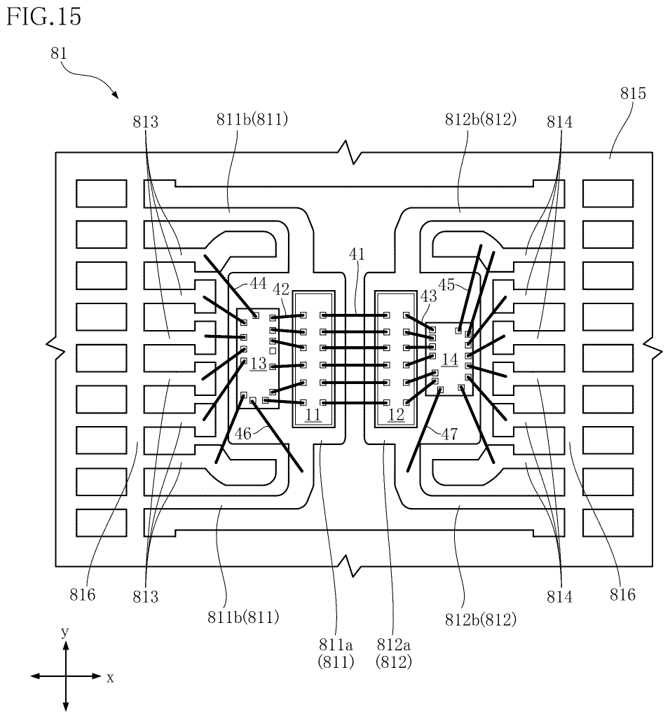

Next, in the element mounting process S13, the semiconductor element 11, the semiconductor element 12, the semiconductor element 13, and the semiconductor element 14 are mounted on the lead frame 81, as shown in FIG. 14. Specifically, the semiconductor element 11 and the semiconductor element 13 are bonded to the island 811a by a conductive bonding material not shown in the figure, while the semiconductor element 12 and the semiconductor element 14 are bonded to the island 812a also by a conductive bonding material.

Next, in the wire bonding process S14, wires 41, wires 42, wires 43, wires 44, wires 45, a wire 46, and a wire 47 are provided or formed, as shown in FIGS. 15 and 16. To form the wires 41-47, use may be made of a conventionally known wire bonder. The order of formation of the respective wires 41-47 is not limitative.

In the present embodiment, as shown in FIG. 10, the second design step S102, the third design step S103, the fourth design step S104 and the fifth design step S105 are performed during the wire bonding process S14.

In the second design step S102, when forming each wire 41, it is designed that the distance d2 in the thickness direction z between the wire 41 and the semiconductor element 11 will be greater than the distance d0, and also that the distance d2′ in the thickness direction z between the wire 41 and the lead 811 will be greater than the distance d0. To this end, the wire bonding of the wire 41 is performed such that the loop portion 413 of the wire 41 will be disposed apart from the seal ring portion 113 of the semiconductor element 11 by more than the distance d0, and also apart from the island portion 811a by more than the distance d0. As understood from the explanation below, the lead 811 will become the lead 31. Thus, in designing the distance d2′ in the second design step S102, the distance d2′ in the thickness direction z between the wire 41 and the lead 31 will be greater than the distance d0. In the second design step S102, it is preferable to design the distance d2 to be greater than the distance d0, but not greater than 10 mm, for example, which serves to prevent the resulting semiconductor device A1 from becoming unduly large. Likewise, it is preferable to design the distance d2′ to be greater than the distance d0, but not greater than 10 mm, for example, which serves to prevent the resulting semiconductor device A1 from becoming unduly large.

In the third design step S103, when forming each wire 41, it is designed that the distance d3 in the thickness direction z between the wire 41 and the semiconductor element 12 will be greater than the distance d0, and that the distance d3′ in the thickness direction z between the wire 41 and the lead 812 will be greater than the distance d0. To this end, the wire bonding of the wire 41 is performed such that the loop portion 413 of the wire 41 will be disposed apart from the seal ring portion 123 of the semiconductor element 12 by more than the distance d0 and also apart from the island portion 812a by more than the distance d0. As understood from the explanation below, the lead 812 will become the lead 32. Thus, in designing the distance d3′ in the third design step S103, the distance d3′ in the thickness direction z between the wire 41 and the lead 32 will be greater than the distance d0. In the third design step S103, it is preferable to design the distance d2 to be greater than the distance d0, but not greater than 10 mm, for example, which serves to prevent the resulting semiconductor device A1 from becoming unduly large. Likewise, it is preferable to design the distance d3′ to be greater than the distance d0, but not greater than 10 mm, for example, which serves to prevent the resulting semiconductor device A1 from becoming unduly large.

In the fourth design step S104, it is designed that when forming each wire 41 and 42, the distance d4 between the wire 41 and the wire 42 will be greater than the distance d0. To this end, supposing, without limitation, that the wire bonding of the wire 41 is performed before that of the wire 42, the wire bonding of the wire 42 is performed such that the neck portion 421 of the wire 42 is spaced apart from the neck portion 411 of the wire 41 by more than the distance d0. Conversely, when the wire 42 is wire-bonded before the wire 41, the wire 41 is wire-bonded so that the neck portion 411 of the wire 41 is spaced apart from the neck portion 421 of the wire 42 by more than the distance d0. In the fourth design step S104, it is preferable to design the distance d4 to be greater than the distance d0, but not greater than 10 mm for example, which serves to prevent the resulting semiconductor device A1 from becoming unduly large.

In the fifth design step S105, it is designed that when forming each wire 41 and each wire 43, the distance d5 between the wire 41 and the wire 43 will be greater than the distance d0. To this end, supposing, without limitation, that the wire bonding of the wire 41 is performed before that of the wire 43, the wire bonding of the wire 43 is performed such that the neck portion 431 of the wire 43 is spaced apart from the joint portion 412 of the wire 41 by more than the distance d0. Conversely, when the wire 43 is wire-bonded before the wire 41, the wire 41 is wire-bonded so that the joint portion 412 of the wire 41 is spaced apart from the neck portion 421 of the wire 42 by more than the distance d. In the fifth design step S105, it is preferable to design the distance d5 to be greater than the distance d0, but not greater than 10 mm for example, which serves to prevent the resulting semiconductor device A1 from becoming unduly large.

Next, in the sealing process S15, a sealing resin 5 is formed as shown in FIG. 17. In FIG. 17, the sealing resin 5 is indicated by imaginary lines (double-dotted lines). The sealing resin 5 may be formed by transfer molding. The material for making the sealing resin 5 may be an epoxy resin, for example.

Subsequently, in the separation process S16, dicing is performed to divide the product assembly into individual pieces, whereby the leads 811, 812, 813 and 814 connected to each other via the outer frame 815 and the dam bar 816 are separated. Thus, after the separation, the lead 811 provides the lead 31. Specifically, the island 811a provides the island portion 311, and the supporting leads 811b provide the respective terminal portions 312. Likewise, the lead 812 provides the lead 32. Specifically, the island 812a provides the island portion 321, and the supporting leads 812b provide the respective terminal portions 322. Further, the leads 813 provide the respective leads 33, and the leads 814 provide the respective leads 34. The leads 33 (or leads 813) and the leads 34 (or leads 814) may be subjected to the required bending during the separation process S16 or during the punching process in the lead frame preparation process S11.

Through the above-noted processes, the semiconductor device(s) A1 is manufactured. The manufacturing method of the semiconductor device A1 is not limited to the example explained above. For instance, the lead frame working process S12 may be omitted, and instead the islands 811a and 812a may be produced by punching the metal sheet in the lead frame preparation process S11. In this case, the first design step S101 may be performed during the lead frame preparation process S11. Formation of the islands 811a, 812a may be performed more accurately by the etching process in the lead frame working process S12 than by the punching process in the lead frame preparation process S11, and thus the former process may be preferable to reliably make the distance d1 greater than the distance d0. As another example of manufacturing method, a copper plate rectangular in plan view is prepared in the lead frame preparation process S11, and then the plate is subjected to the resist formation and subsequent etching in the lead frame working process S12. As such, it is possible to collectively provide the lead 811 (island 811a and support leads 811b), the lead 812 (island 812a and support leads 812b), the leads 813, 814, the outer frame 815 and the dam bar 816.

The semiconductor device A1, the design method of the semiconductor device A1 and the manufacturing method of the semiconductor device A1 may have the following effects and advantages.

In the semiconductor device A1, the distance d1 in the first direction x between the lead 31 and the lead 32 is greater than the distance d0 determined by Formula (1). As noted above, the distance d0 may be calculated based on the insulation life years Y of the semiconductor device A1, the voltage X used in the semiconductor device A1, and the constant A determined by the material of the sealing resin 5. Through the research by the inventor, it has been found that Formula (1) is preferably used for designing the insulation resistance voltage in light of actual usage conditions.

The design of such a practical insulation resistance voltage is implemented in the semiconductor device A1 by making the distance d1 greater than the distance d0. With the semiconductor device A1, it is possible to ensure a sufficient dielectric strength between the lead 31 and the lead 32 for example, thereby preventing the occurrence of dielectric breakdown. With the design method of the semiconductor device A1, the first design step S101 may ensure that the distance d1 is greater than the distance d0. This enables the design and manufacture of the semiconductor device A1 in which the occurrence of dielectric breakdown is suppressed.

In the semiconductor device A1, the semiconductor element 13 and the semiconductor element 14 are electrically insulated from each other by the semiconductor element 11 and the semiconductor element 12. Differing from this configuration, if the semiconductor elements 13 and 14 are mutually insulated by a single semiconductor element (that is, insulating element), the voltage difference between the first circuit and the above second circuit is incurred on the single insulating element. On the other hand, with the semiconductor device A1, the voltage difference between the first and the second circuits is shared by the two insulating elements (i.e., the semiconductor element 11 and the semiconductor element 12). Accordingly, a smaller voltage difference is generated in each semiconductor element 11 and 12. Thus, with the semiconductor device A1, it is possible to more reliably ensure the dielectric strength relating to the lead 31 (island portion 311) and the semiconductor element 11, compared to the configuration in which only one insulating element is used, while also ensuring the dielectric strength relating to the lead 32 (island portion 321) and the semiconductor element 12.

In the semiconductor element 11, since the voltage difference generated therein can be reduced, it is possible to reduce the number of the insulation layers 1171 located between the upper winding 115a and the lower winding 115b. Accordingly, the thickness (dimension in the thickness direction z) of the semiconductor element 11 can be reduced, thereby producing an advantageously thin semiconductor device A1. Likewise, in the semiconductor element 12, the number of insulation layers 1271 located between the upper winding 125a and the lower winding 125b can be reduced due to the smaller voltage difference generated in the semiconductor element 12, which also contributes to reducing the thickness (dimension in the thickness direction z) of the semiconductor element 12, thereby producing an advantageously thin semiconductor device A1. As seen from the above, the semiconductor device A1 of the present disclosure can be made thinner than a conventional semiconductor device with a single insulating element incorporated, while enjoying the same insulation resistance voltage as that of the conventional device. In certain applications, the thickness of the semiconductor device A1 may need to be smaller than a predetermined limit because of e.g., the product specifications. In such a case, the semiconductor device A1 can improve the dielectric strength within the thickness limit, compared to the electrical insulation with a single insulating element. This is because the first circuit and the second circuit can be insulated by the insulation layers 1171 between the upper winding 115a and the lower winding 115b of the semiconductor element 11 and by the insulation layers 1271 between the upper winding 125a and the lower winding 125b of the semiconductor element 12. By insulating the first circuit and the second circuit with two semiconductor elements 11 and 12, the number of insulation layers between the first circuit and the second circuit can be greater than when insulated with a single insulation element.

In the semiconductor device A1, the distance d2 between the wire(s) 41 and the semiconductor element 11 is greater than the distance d0 determined by Formula (1). In this embodiment, the distance d2 is the distance in the thickness direction z between the loop portion 413 of the wire 41 and the sealing ring portion 113 of the semiconductor element 11. Each wire 41 is at an intermediate potential between the first circuit and the second circuit, as noted above. On the other hand, the semiconductor element 11 is bonded to the island portion 311 (first lead 31), and thus the seal ring portion 113 may be at the same potential as the island portion 311. Hence, the wire 41 is at a relatively high voltage, whereas the seal ring portion 113 is at a relatively low voltage, thereby generating a potential difference between the wire 41 and the seal ring portion 113. In the semiconductor device A1, since the distance d2 is greater than the distance d0, it is possible to design a desired insulation resistance voltage or dielectric strength between the wire 41 and the sealing ring portion 113 for satisfying actual usage conditions. Since the semiconductor device A1 can ensure an appropriate dielectric strength between the wire 41 and the semiconductor element 11, it is possible to suppress or prevent the occurrence of dielectric breakdown. By the design method for the semiconductor device A1, the distance d2 is designed to be greater than the distance d0 at the second design step S102. This enables the design and manufacture of a semiconductor device A1 in which the occurrence of dielectric breakdown is suppressed.

In the semiconductor device A1, the distance d2′ between the wire(s) 41 and the lead 31 is greater than the distance d0 determined by Formula (1). In this embodiment, the distance d2′ is the distance in the thickness direction z between the loop portion 413 of the wire 41 and the mount surface 311a of the island portion 311 (lead 31). The wire 41 is a component of the third circuit since it conducts to the upper winding 115a of the semiconductor element 11 (functional part 115), while the lead 31 is a component of the first circuit. Thus, the wire 41 is at a relatively high voltage, whereas the lead 31 is at a relatively low voltage, which produces a potential difference between the wire 41 and the lead 31. With the semiconductor device A1, since the distance d2′ is greater than the distance d0, it is possible to design a desired insulation resistance voltage between the wire 41 and the lead 31 for satisfying actual usage conditions. Accordingly, the semiconductor device A1 can ensure an appropriate dielectric strength between the wire 41 and the lead 31, thereby suppressing the occurrence of dielectric breakdown. By the design method of the semiconductor device A1, the distance d2′ is designed to be greater than the distance d0 at the second design step S102. This enables the design and manufacture of a semiconductor device A1 in which the occurrence of dielectric breakdown is suppressed.

In the semiconductor device A1, the distance d3 between the wire(s) 41 and the semiconductor element 12 is greater than the distance d0 determined by Formula (1). In this embodiment, the distance d3 is the distance in the thickness direction z between the loop portion 413 of the wire 41 and the seal ring portion 123 of the semiconductor element 12. Each wire 41 is at an intermediate potential between the first circuit and the second circuit, as noted above. The semiconductor element 12 is bonded to the island portion 321 (lead 32), and thus the seal ring portion 123 may be at the same potential as the island portion 321. Hence, the wire 41 is at a relatively low voltage, whereas the seal ring portion 123 is at a relatively high voltage, which produces a potential difference between the wire 41 and the seal ring portion 123. With the semiconductor device A1, since the distance d3 is greater than the distance d0, it is possible to design a desired insulation resistance voltage between the wire 41 and the sealing ring portion 123 for satisfying actual usage conditions. Hence, the semiconductor device A1 can ensure a desired dielectric strength between the wire 41 and the semiconductor element 12, thereby suppressing the occurrence of dielectric breakdown. By the design method of the semiconductor device A1, the distance d3 is designed to be greater than the distance d0 at the third design step S103. This enables the design and manufacture of a semiconductor device A1 in which the occurrence of dielectric breakdown is suppressed.

In the semiconductor device A1, the distance d3′ between the wire(s) 41 and the lead 32 is greater than the distance d0 determined by Formula (1). In this embodiment, the distance d3′ is the distance in the thickness direction z between the loop portion 413 of the wire 41 and the mount surface 321a of the island portion 321 (lead 32). The wire 41 is a component of the third circuit since it conducts to the upper winding 125a of the semiconductor element 12 (functional part 125), whereas the lead 32 is a component of the second circuit. Hence, the wire 41 is at a relatively low voltage, while the lead 32 is at a relatively high voltage, thereby producing a potential difference between the wire 41 and the lead 32. With the semiconductor device A1, since the distance d3′ is greater than the distance d0, it is possible to design a desired insulation resistance voltage between the wire 41 and the lead 32 for satisfying actual usage conditions. Hence, the semiconductor device A1 can ensure a desired dielectric strength between the wire 41 and the lead 32, thereby suppressing the occurrence of dielectric breakdown. By the design method of the semiconductor device A1, the distance d3′ is designed to be greater than the distance d0 at the third design step S103. This enables the design and manufacture of a semiconductor device A1 in which the occurrence of dielectric breakdown is suppressed.

In the semiconductor device A1, the distance d4 between each wire 41 and each wire 42 is greater than the distance d0 determined by Formula (1). In this embodiment, the distance d4 is the distance in the direction perpendicular to the thickness direction z of the neck portion 411 of each wire 41 and the neck portion 421 of each wire 42. The wire 41 is electrically connected to the upper winding 115a of the semiconductor element 11 (functional part 115) and is therefore a component of the third circuit. On the other hand, the wire 42 is electrically connected to the lower winding 115b of the semiconductor element 11 (functional part 115) and is therefore a component of the first circuit. Therefore, the wire 41 becomes relatively high voltage and the wire 42 becomes relatively low voltage, resulting in a potential difference between the wires 41 and 42. In the semiconductor device A1, since the above distance d4 is greater than the distance d0, it is possible to design an insulation resistance voltage or dielectric strength suitable for actual use between the wires 41 and 42. Since the semiconductor device A1 can ensure an appropriate dielectric strength between the wire 41 and the wire 42, the occurrence of dielectric breakdown can be suppressed. In the design method of the semiconductor device A1, the fourth design step S104 is used to design the distance d4 to be greater than the distance d0. This enables the design and manufacture of a semiconductor device A1 in which the occurrence of dielectric breakdown is suppressed.

In the semiconductor device A1, the distance d5 between each wire 41 and each wire 43 is greater than the distance d0 determined by Formula (1). In this embodiment, the distance d5 is the distance in the direction perpendicular to the thickness direction z of the joint portion 412 of the wire 41 and the neck portion 431 of the wire 43. The wire 41 is electrically connected to the upper winding 125a of the semiconductor element 12 (functional part 125) and is therefore a component of the third circuit. On the other hand, the wire 43 is electrically connected to the lower winding 125b of the semiconductor element 12 (functional part 125) and is therefore a component of the second circuit. Therefore, since the wire 41 is at relatively low potential and the wire 43 is at relatively high potential, a potential difference is generated between the wire 41 and the wire 43. In the semiconductor device A1, since the above distance d5 is greater than the distance d0, it is possible to design an insulation resistance voltage suitable for actual use between the wire 41 and the wire 43. Since the semiconductor device A1 can secure an appropriate dielectric strength between the wire 41 and the wire 43, the occurrence of dielectric breakdown can be suppressed. In the design method of the semiconductor device A1, the above distance d5 is designed to be greater than the distance d0 by the fifth design step S105. This enables the design and manufacture of a semiconductor device A1 in which the occurrence of dielectric breakdown is suppressed.

In the semiconductor element 11 of the semiconductor device A1, the potential of the lower winding 115b of the functional part 115 is approximately the same as the potential of the lead 31. In this embodiment, since the semiconductor element 11 is bonded to the lead 31, the potential of the semiconductor substrate 110 is approximately the same as the potential of the lead 31. Furthermore, in the semiconductor device A1, the potential of the semiconductor substrate 110 and the potential of the lower winding 115b are approximately the same. As a result, in the semiconductor device A1, the number of insulation layers 1171 between the semiconductor substrate 110 and the lower winding 115b can be reduced, thereby suppressing an increase in the thickness of the first semiconductor element 11.

In the semiconductor device A1, the lower winding 115b is connected to the semiconductor element 13 by connecting the wire 42 to the pad 111 which is electrically connected to the lower winding 115b. The semiconductor element 13 is bonded to the lead 31. According to this configuration, the lower winding 115b and the lead 31 become components of the first circuit that includes the semiconductor element 13. Thus, in the semiconductor device A1, the potential of the lower winding 115b can be made approximately the same as the potential of the lead 31.

In the semiconductor device A1, the potential of the lower winding 125b of the functional part 125 in the semiconductor element 12 is approximately the same as the potential of the lead 32. In this embodiment, since the semiconductor element 12 is bonded to the lead 32, the potential of the semiconductor substrate 120 is approximately the same as the potential of the lead 32. As a result, in the semiconductor device A1, the potential of the semiconductor substrate 120 and the potential of the lower winding 125b are approximately the same. Therefore, in the semiconductor device A1, the number of insulation layers 1271 between the semiconductor substrate 120 and the lower winding 125b can be reduced, thereby suppressing an increase in the thickness of the semiconductor element 12.

In the semiconductor device A1, the lower winding 125b is connected to the semiconductor element 14 by connecting the wire 43 to the pad 121, which is electrically connected to the lower winding 125b. The semiconductor element 14 is bonded to the lead 32. According to this configuration, the lower winding 125b and the lead 32 become components of the second circuit that includes g the semiconductor element 14. Thus, in the semiconductor device A1, the potential of the lower winding 125b can be made substantially the same as the potential of the lead 32.

The following describes semiconductor devices according to other embodiments and variations of the first aspect of the present disclosure. Various components in the embodiments and variations of the present disclosure may be combined as appropriate, as long as there are no technical contradictions.

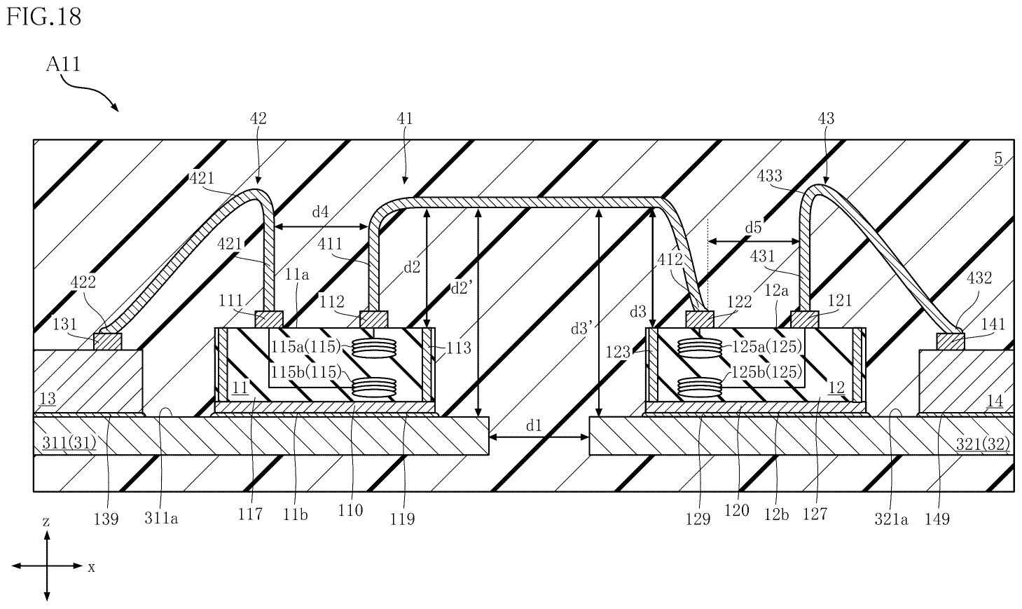

FIG. 18 shows a semiconductor device A11 according to a first variation of the first embodiment of the first aspect. FIG. 18 is an enlarged sectional view of a part of the semiconductor device A11 and corresponds to the sectional view in FIG. 7. The semiconductor device A11 may differ from the semiconductor device A1 in the shape of the wire 41.

As shown in FIG. 18, in each wire 41 of the semiconductor device A11, the loop portion 413 extends from the seal ring portion 113 to the seal ring portion 123 so as to be substantially parallel to the mount surfaces 311a and 321a. By using wires 41 of this shape, the distance d2 and the distance d3 can be made substantially the same. As long as the distance d2 and the distance d3 are approximately the same, the loop portion 413 may be curved upward or downward in the thickness direction z.

The semiconductor device A11 has a configuration common to the semiconductor device A1 and produces the same effect as the semiconductor device A1. In the semiconductor device A11, the distance d3 can be made greater than in the semiconductor device A1. Therefore, the semiconductor device A11 can further suppress the occurrence of dielectric breakdown than the semiconductor device A1.

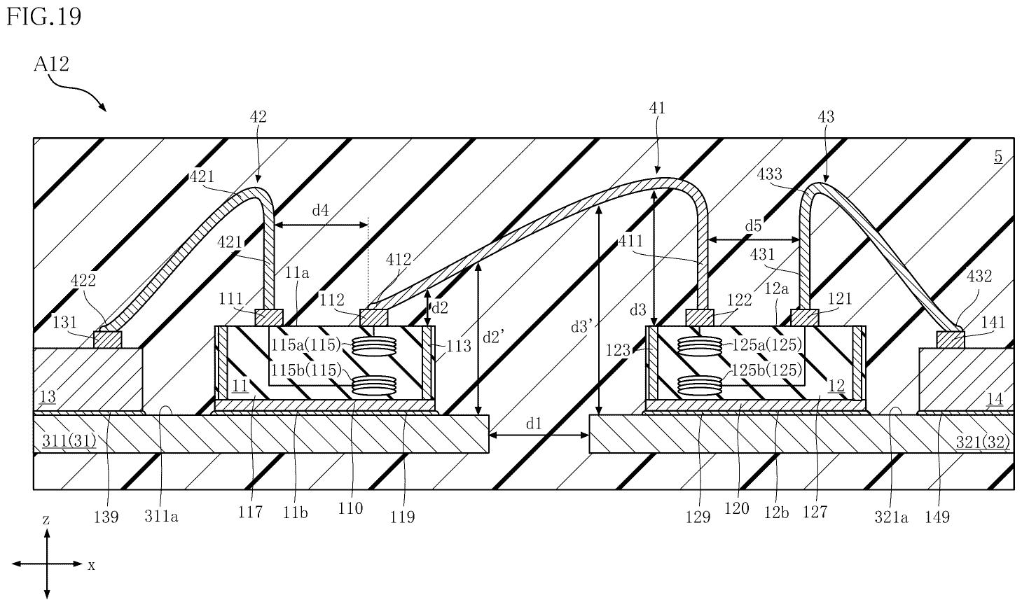

FIG. 19 shows a semiconductor device A12 according to a second variation of the first embodiment of the first aspect. FIG. 19 is an enlarged sectional view of a semiconductor device A12, corresponding to the sectional view in FIG. 7. The semiconductor device A12 may differ from the semiconductor device A1 in that the wire 41 is first-bonded to the pad 122 of the second semiconductor element 12 and second-bonded to the pad 112 of the first semiconductor element 11.

As shown in FIG. 19, in the semiconductor device A12, the neck portion 411 of each wire 41 is bonded to the pad 122 of the semiconductor element 12. In the semiconductor device A12, the distance d5 is the distance between the neck portion 411 of the wire 41 and the neck portion 431 of the wire 43 in a direction perpendicular to the thickness direction z. The joint portion 412 of the wire 41 is bonded to the pad 112 of the semiconductor element 11. In the semiconductor device A12, the distance d4 is the distance in a direction perpendicular to the thickness direction z between the joint portions 412 of the wire 41 and the neck portion 421 of the wire 42.

The semiconductor device A12 can produce the same effect as the semiconductor device A1 due to having the same configuration as the semiconductor device A1. As understood from the example of the semiconductor device A12, according to a semiconductor device of the present disclosure, the bonding target of the first and second bonding of the wire 41 is not limitative.

Unlike the semiconductor device A12 shown in FIG. 19, in the wires 42, 43, the first bonding and the second bonding may be performed in the opposite manner, as in the wire 41. In the semiconductor device of the present disclosure, the bonding target of the first and second bonding of the wires 42, 43 are not limitative.

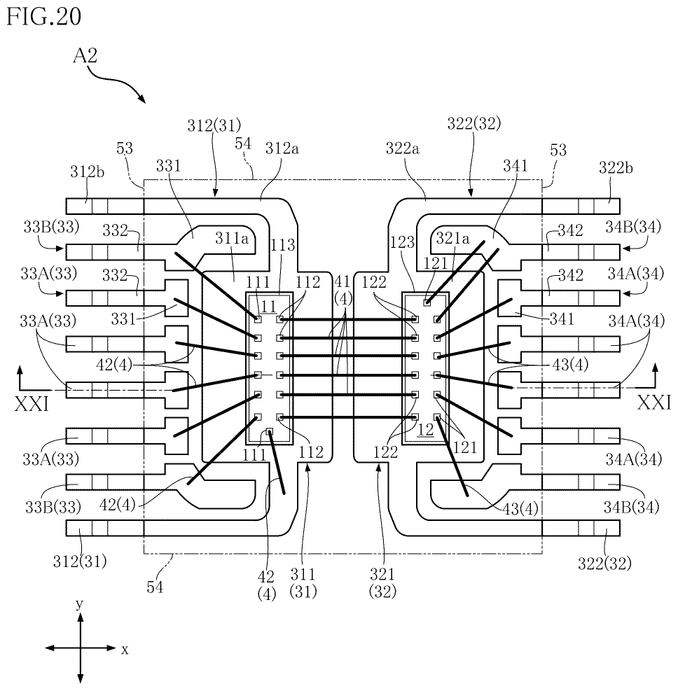

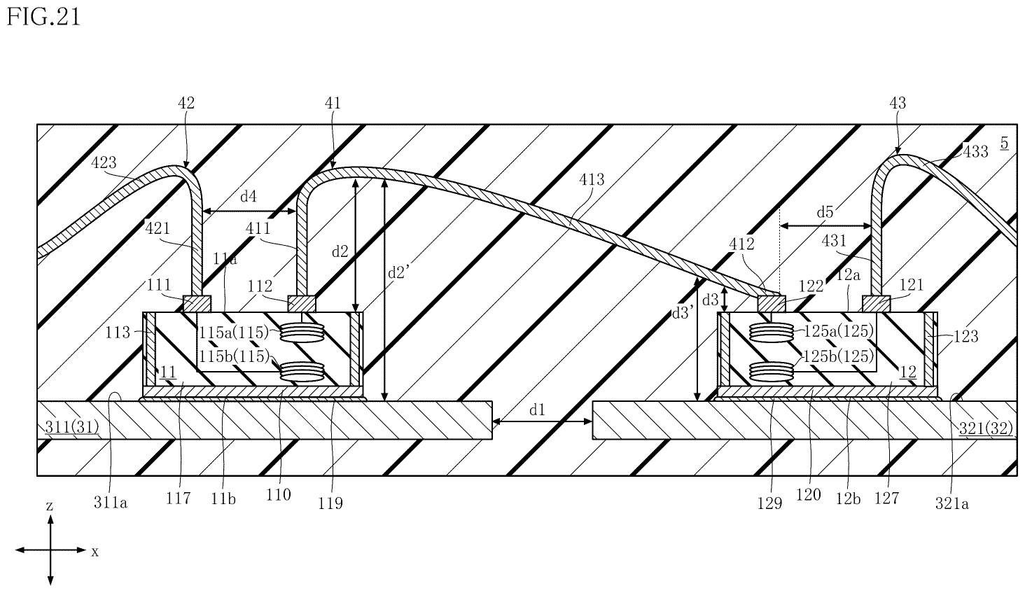

FIGS. 20 and 21 show a semiconductor device A2 according to a second embodiment of the first aspect. The semiconductor device A2 differs from the semiconductor device A1 in that it does not include semiconductor elements 13 and 14. The configuration of connection for the wires 42 and 43 is not limited to the example shown in FIG. 20, but may be varied as appropriate according to the configuration of the semiconductor elements 11 and 12.

In the semiconductor device A2, each wire 42 is electrically connected to one of the pads 111 and also electrically connected to one of the two terminal portions 312 or one of the leads 33. As such, each wire 42 electrically connects the semiconductor element 11 to the lead 31 or one of the leads 33.

In the semiconductor device A2, each wire 43 is electrically connected to one of the pads 121, and to one of the two terminal portions 322 of the lead 32, or to one of the leads 34. Thus, each wire 43 electrically connects the semiconductor element 12 to the lead 32 or one of the leads 34.

For instance, the semiconductor device A2 may be mounted on a wiring board, and the semiconductor element 13 may be disposed on the same wiring board. The semiconductor element 13 may be electrically connected to the semiconductor element 11 via the wiring board and the leads 33. The lead 31 may be electrically connected to, via the wiring board, the ground of the first circuit that includes the semiconductor element 13. Similarly, the semiconductor device A2 may be mounted on a wiring board, and the semiconductor element 14 may be disposed on the wiring board. The semiconductor element 14 may be be electrically connected to the semiconductor element 12 via the wiring board and the leads 34. The lead 32 may be be electrically connected, via the wiring board, to the ground of the second circuit that includes the semiconductor element 14. With such a configuration, the semiconductor device A2 (hence, the semiconductor elements 11, 12) may be used to insulate the first circuit (the circuit including the semiconductor element 13) and the second circuit (the circuit including the semiconductor element 14) from each other.

The manufacturing method of the semiconductor device A2 described above is the same as that of the semiconductor device A1 (see FIG. 10), but may differ in the following points. First, in the element mounting process S13, there is no process for mounting semiconductor elements 13, 14. Second, in the wire bonding process S14, there is no process for providing wires 44, 45, 46 and 47.

As in the semiconductor device A1, in the semiconductor device A2, the distance d1 between the lead 31 and the lead 32 in the first direction x is greater than the distance d0 determined by Formula (1). Therefore, the semiconductor device A2, like the semiconductor device A1, may ensure an appropriate dielectric strength between the lead 31 and the lead 32, thereby suppressing the occurrence of dielectric breakdown. In addition, since the semiconductor device A2 has a configuration common to that of the semiconductor device A1, it has the same effect as the semiconductor device A1. For example, in the semiconductor device A2, since the distance d2 between each wire 41 and the semiconductor element 11 is greater than the distance d0 determined by Formula (1), an appropriate dielectric strength may be ensured between the wire 41 and the semiconductor element 11. In addition, since the distance d3 between each wire 41 and the semiconductor element 12 is greater than the distance d0 determined by Formula (1), an appropriate dielectric strength may be ensured between the wire 41 and the semiconductor element 12. In addition, since the distance d4 between the wire 41 and the wire 42 is greater than the distance d0 determined by Formula (1), an appropriate dielectric strength can be ensured between the wires 41 and 42. In addition, since the distance d5 between the wire 41 and the wire 43 is greater than the distance d0 determined by Formula (1), an appropriate dielectric strength may be ensured between the wires 41 and 43.

In the above example of the second embodiment, the semiconductor device A2 does not include the semiconductor element 13 and 14, but the present disclosure is not limited this, and the semiconductor device A2 may include either one of the above two semiconductor elements.

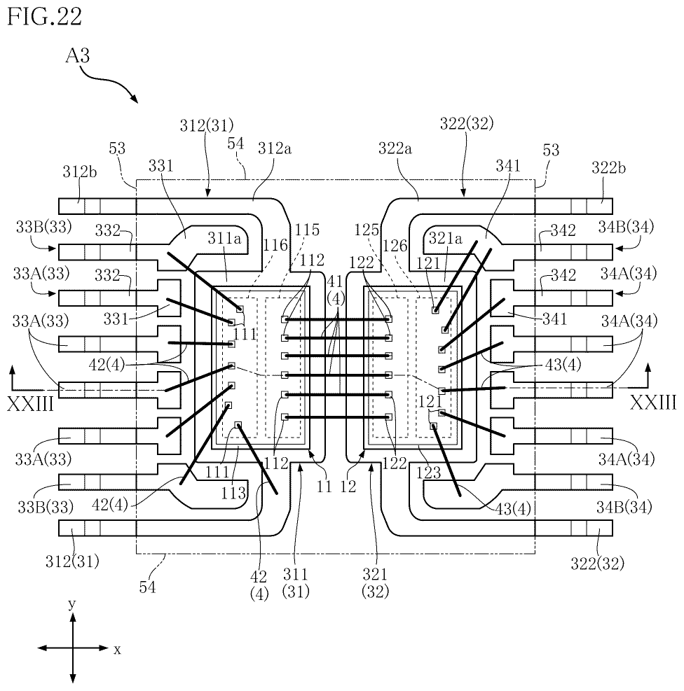

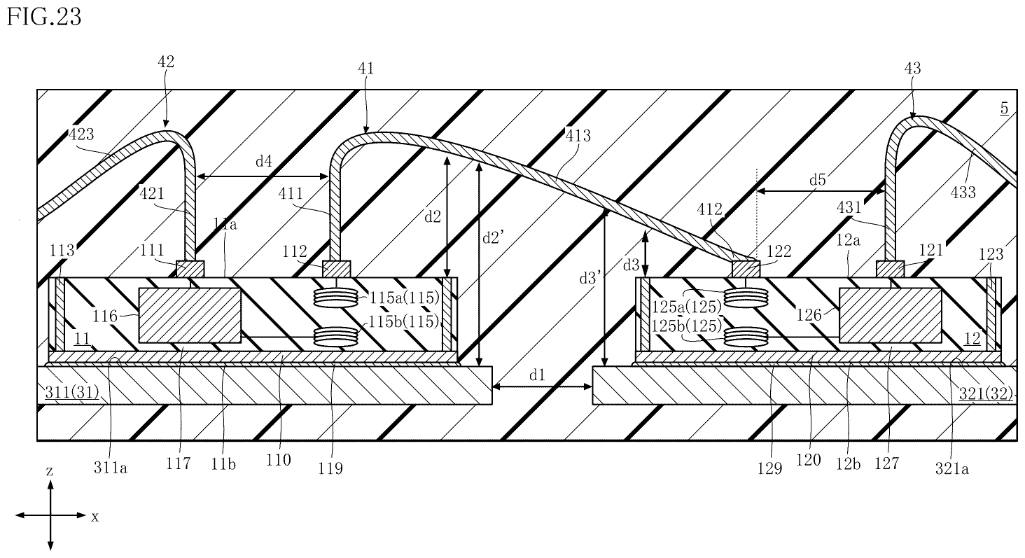

FIGS. 22 and 23 show a semiconductor device A3 according to a third embodiment of the first aspect. The semiconductor device A3 differs from the semiconductor device A2 in the following. First, the semiconductor element 11 of the semiconductor device A3 includes a functional part 116 in addition to the functional part 115. Second, the semiconductor element 12 of the semiconductor device A3 includes a functional part 126 in addition to the functional part 115. Note that the configurations of the wires 42, 43 are not limited to the example shown in FIG. 22, and may be varied as appropriate according to the configurations of the semiconductor elements 11 and 12.

The functional part 116 has the same function as the semiconductor element 13 (i.e., the control element). The functional part 116 may be formed on the semiconductor substrate 110, for example. The functional part 116 is electrically connected to the functional part 115 inside the semiconductor element 11. In the example shown in FIG. 23, the functional part 116 is electrically connected to the lower winding 115b. In this example, the pads 111 are electrically connected to the functional part 116, and the pads 112 are electrically connected to the functional part 115 (upper winding 115a). The semiconductor element 11 of the semiconductor device A3 has a configuration in which a control element and an insulating element are integrated into a single chip.

The functional part 126 has the same function as the semiconductor element 14 (i.e., the drive element). The functional part 126 may be formed on the semiconductor substrate 120, for example. The functional part 126 is electrically connected to the functional part 125 inside the semiconductor element 12. In the example shown in FIG. 23, the functional part 126 is electrically connected to the lower winding 125b. In this example, the pads 121 are electrically connected to the functional part 126, and the pads 122 are electrically connected to the functional part 125 (upper winding 125a). The semiconductor element 12 of the semiconductor device A3 has a configuration in which a driving element and an insulating element are integrated into a single chip.

In the semiconductor device A3 with the above configuration, the first circuit including the functional part 116 of the semiconductor element 11 and the second circuit including the functional part 126 of the semiconductor element 12 are insulated from each other by the functional part 115 of the semiconductor element 11 and the functional part 125 of the semiconductor element 12.

The method of manufacturing the semiconductor device A3 may be the same as the method of manufacturing the semiconductor device A2. Specifically, the method of manufacturing the semiconductor device A3 is the same as the method of manufacturing the semiconductor device A1 (see FIG. 10), except for the following differences. First, in the element mounting process S13, there is no process for mounting semiconductor elements 13, 14. Second, in the wire bonding process S14, there is no process for forming wires 44, 45, 46 and 47.

As in the semiconductor devices A1 and A2, in the semiconductor device A3, the distance d1 between the lead 31 and the lead 32 in the first direction x is greater than the distance d0 determined by Formula (1). Thus, the semiconductor device A3, like the semiconductor devices A1 and A2, may ensure an adequate dielectric strength between the leads 31, 32, thereby suppressing the occurrence of dielectric breakdown. In addition, the semiconductor device A3 has the same effect as the semiconductor devices A1 and A2 since it has the same configuration as the semiconductor devices A1 and A2. For example, in the semiconductor device A3, as in the semiconductor devices A1 and A2, the distance d2 between the wire 41 and the semiconductor element 11 is greater than the distance d0 determined by Formula (1), whereby an appropriate dielectric strength may be ensured between the wire 41 and the semiconductor element 11. Since the distance d3 between the wire 41 and the semiconductor element 12 is greater than the distance d0 determined by Formula (1), an appropriate dielectric strength may be ensured between the wire 41 and the semiconductor element 12. The distance d4 between the wire 41 and the wire 42 is greater than the distance d0 determined by Formula (1), an appropriate dielectric strength may be ensured between the wires 41 and 42. The distance d5 between the wire 41 and the wire 43 is greater than the distance d0 determined by Formula (1), an appropriate dielectric strength may be ensured between the wires 41 and 43.

In the above example of the third embodiment, in the semiconductor device A3, the semiconductor element 11 includes functional parts 115 and 116, and the semiconductor element 12 includes functional parts 125 and 126. Alternatively, the semiconductor element 11 may not include a functional part 116, or the semiconductor element 12 may not include a functional part 126.

In the above first to third embodiments (including variations), the semiconductor elements 11 and 12 equally share the voltage difference between the first circuit and the second circuit for insulation. That is, the insulation ratios of the respective semiconductor elements 11, 12 are the same with respect to the voltage difference between the first and the second circuits. Alternatively, the insulation ratios of the semiconductor elements 11 and 12 may be different. In this case, the number of the insulation layers 1171 between the upper winding 115a and the lower winding 115b, and the number of the insulation layers 1271 between the upper winding 125a and the lower winding 125b may differ according to the insulation ratios. For example, when the insulation ratio of the semiconductor element 11 is greater than the insulation ratio of the semiconductor element 12, the number of the insulation layers 1171 is greater than the number of the insulation layers 1271. As such, in the semiconductor device of the present disclosure, the insulation ratios for the first semiconductor element 11 and the second semiconductor element 12 are not limitative.

The semiconductor device, the design method, and the manufacturing method according to the first aspect of the present disclosure are not limited to the embodiments described above. The specific configuration of each part of the semiconductor device and the specific processing of each step/process of the design method and manufacturing method may be varied in many ways. The first aspect of the present disclosure relating to a semiconductor device, a semiconductor device design method, and a semiconductor device manufacturing method may include the embodiments in the following clauses.
Clause A1.

A semiconductor device comprising:
a conductive support including a first lead and a second lead spaced apart from each other in a first direction perpendicular to a thickness direction;
a first semiconductor element including a first functional part and supported by the first lead;
a second semiconductor element including a second functional part and supported by the second lead;
a sealing resin covering a part of the conductive support, the first semiconductor element, and the second semiconductor element, wherein
each of the first functional part and the second functional part transmits an electrical signal in an insulated state, and
a distance d1 between the first lead and the second lead in the first direction is greater than a distance d0 determined by Formula (1),

$$d 0 = ( ( Y / A ) \hat{} ( 1 / B ) ) \times 0.15 \times ( X ) \qquad ( 1 )$$

where Y is an insulation life [years] required for the semiconductor device, A and B are constants depending on a material of the sealing resin, 0.15 is an offset value for calculating the distance d0 [mm], and X is a voltage [kVrms].
Clause A2.

The semiconductor device according to clause A1, further comprising a first wire connected to the first semiconductor element and the second semiconductor element, wherein the first wire is electrically connected to each of the first functional part and the second functional part.
Clause A3.

The semiconductor device according to clause A2, wherein a distance d2 between the first wire and the first semiconductor element is greater than the distance d0 determined by Formula (1).
Clause A4.

The semiconductor device according to clause A2 or A3, wherein a distance d3 between the first wire and the second semiconductor element is greater than the distance d0 determined by Formula (1).
Clause A5.

The semiconductor device according to any one of clauses A2-A4, further comprising a second wire connected to the first semiconductor element,
wherein a distance d4 between the first wire and the second wire is greater than the distance d0 determined by Formula (1).
Clause A6.

The semiconductor device according to clause A5, further comprising a third semiconductor element covered by the sealing resin and electrically connected to the first semiconductor element on a side opposite from the second semiconductor element, wherein
the third semiconductor element and the first semiconductor element are supported by the first lead,
the second wire is connected to the third semiconductor element.
Clause A6-1.

The semiconductor device according to clause A6, wherein the conductive support includes a third lead spaced apart from the first lead and the second lead,
the third lead is electrically connected to the third semiconductor element.
Clause A7.

The semiconductor device according to clause A5, wherein the first semiconductor element includes a third functional part disposed opposite to the second functional part with respect to the first functional part,
the conductive support includes a third lead spaced apart from the first lead and the second lead,
the second wire electrically conducts to the third functional part and connected to the third lead.
Clause A7-1.

The semiconductor device according to clause A6-1 or A7, wherein the third lead protrudes from the sealing resin in the first direction.
Clause A8.

The semiconductor device according to any one of clauses A2-A7, further comprising a third wire connected to the second semiconductor element,
wherein a distance d5 between the first wire and the third wire is greater than the distance d0 determined by Formula (1).
Clause A9.

The semiconductor device according to clause A8, further comprising a fourth semiconductor element covered by the sealing resin and electrically connected to the second semiconductor element on a side opposite from the first semiconductor element,
the fourth semiconductor element and the second semiconductor element are supported by the second lead,
the third wire is connected to the fourth semiconductor element.
Clause A9-1.

The semiconductor device according to clause A9, wherein the conductive support includes a fourth lead spaced apart from the first lead and the second lead, the fourth lead is electrically connected to the fourth semiconductor element.
Clause A10.

The semiconductor device according to clause A8, wherein the second semiconductor element includes a fourth functional part disposed on an opposite side from the first functional part with respect to the first functional part,
the conductive support includes a fourth lead spaced apart from the first lead and the second lead,
the third wire electrically conducts to the fourth functional part and connected to the fourth lead.
Clause A10-1.

The semiconductor device according to clause A9-1 or A10, wherein the fourth lead protrudes from the sealing resin in the first direction.
Clause A11.

The semiconductor device according to any one of clauses A1-A10, wherein the first functional part includes a first upper winding and a first lower winding spaced apart from each other in the thickness direction,
a potential of the first lower winding is equal to a potential of the first lead.
Clause A12.

The semiconductor device according to clause A11, wherein the first semiconductor element includes a plurality of first insulation layers stacked between the first upper winding and the first lower winding,
the first insulation layers are made up of not less than four layers and not more than six layers.
Clause A13.

The semiconductor device according to clause A11 or A12, wherein a size of the plurality of first insulation layers in the thickness direction is not less than 9.6 μm and not more than 14.4 μm.
Clause A14.

The semiconductor device according to any one of clauses A1-A13, wherein the second functional part includes a second upper winding and a second lower winding spaced apart from each other in the thickness direction,
a potential of the second lower winding is equal to a potential of the second lead.
Clause A15.

The semiconductor device according to clause A14, wherein the second semiconductor element includes a plurality of second insulation layers stacked between the second upper winding and the second lower winding in the thickness direction,
the plurality of second insulation layers are made up of not less than four layers and not more than six layers.
Clause A16.

The semiconductor device according to clause A14 or A15, wherein a size of the plurality of second insulation layers in the thickness direction is not less than 9.6 μm and not more than 14.4 μm.
Clause A17.

The semiconductor device according to any one of clauses A1-A16, wherein a constituting material of the sealing resin contains an epoxy resin.
Clause A18.

A method for designing a semiconductor device that comprises:
a conductive support including a first lead and a second lead spaced apart from each other in a first direction;
a first semiconductor element including a first functional part and supported by the first lead;
a second semiconductor element including a second functional part and supported by the second lead;
a sealing resin covering a part of the conductive support, the first semiconductor element, and the second semiconductor element,
wherein each of the first functional part and the second functional part transmits an electrical signal in an insulated state,
the design method comprising a first design step configured to design that a distance d1 between the first lead and the second lead in the first direction is greater than a distance d0 determined by Formula (1),

$$d 0 = ( ( Y / A ) \hat{} ( 1 / B ) ) \times 0.15 \times ( X ) \qquad ( 1 )$$

where Y is an insulation life [years] required for the semiconductor device, A and B are constants depending on a material of the sealing resin, 0.15 is an offset value for calculating the distance d0 [mm], and X is a voltage [kVrms].
Clause A19.

The method for designing a semiconductor device according to clause A18, wherein the semiconductor device further comprises a first wire connected to the first semiconductor element and the second semiconductor element,
the first wire electrically conducts to the first functional part and the second functional part.
Clause A20.

The method for designing a semiconductor device according to clause A19, further comprising a second design step configured to design that a distance d2 between the first wire and the first semiconductor element is greater than the distance d0 determined by Formula (1).
Clause A21.

The method for designing a semiconductor device according to clause A19 or A20, further comprising a second design step configured to design that a distance d3 between the first wire and the second semiconductor element is greater than the distance d0 determined by Formula (1).
Clause A22.

The method for designing a semiconductor device according to any one of clauses A19-A21, wherein the semiconductor device further comprises a second wire connected to the first semiconductor element,
the design method further comprises a fourth design step configured to design that a distance d4 between the first wire and the second wire is greater than the distance d0 determined by Formula (1).
Clause A22-1.

The method for designing a semiconductor device according to clause A22, wherein the semiconductor device further comprises a third semiconductor element covered by the sealing resin and electrically connected to the first semiconductor element on a side opposite from the semiconductor element,
the third semiconductor element and the first semiconductor element are supported by the first lead,
the second wire is connected to the third semiconductor element.
Clause A22-2.

The method for designing a semiconductor device according to clause A22, wherein the first semiconductor element incudes a third functional part disposed on a side opposite from the second functional part with respect to the first functional part,
the conductive support includes a third lead spaced apart from the first lead and the second lead,
the second wire electrically conducts to the third functional part and connected to the third lead.
Clause A23.

The method for designing a semiconductor device according to any one of clauses A19-A22, wherein the semiconductor device further includes a third wire connected to the second semiconductor element,
the design method comprises a fifth design step configured to design that a distance d5 between the first wire and the third wire is greater than the distance d0 determined by Formula (1).
Clause A23-1.

The method for designing a semiconductor device according to clause A23, wherein the semiconductor device further includes a third wire connected to the second semiconductor element,
the design method comprises a fifth design step configured to design that a distance d5 between the first wire and the third wire is greater than the distance d0 determined by Formula (1).
Clause A23-2.

The method for designing a semiconductor device according to clause A23, wherein the second semiconductor element includes a fourth functional part disposed opposite from the first functional part with respect to the second functional part,
the conductive support includes a fourth lead spaced apart from the first lead and the second lead,
the third wire electrically conducts to the fourth functional part and connected to the fourth lead.
Clause A24.

A method for manufacturing a semiconductor device, comprising the method for designing a semiconductor device according to any one of clauses A18-A23.

### REFERENCE NUMERALS RELATING TO FIRST ASPECT

| | |
|---|---|
| A1, A11, A12, A2, A3: Semiconductor device | |
| 11: Semiconductor element | 11a: Obverse surface |
| 11b: Reverse surface | 110: Semiconductor substrate |
| 111, 112: Pad | 113: Seal ring portion |
| 115: Functional part | 115a: Upper winding |
| 115b: Lower winding | 116: Functional part |
| 117: Stacking structure | 1171: Insulation layer |
| 118: Distributing conductor | 1181: Penetration wiring |
| 1182: Lead-out wiring | 119: Conductive bonding material |
| 12: Semiconductor element | 12a: Obverse surface |
| 12b: Reverse surface | 120: Semiconductor substrate |
| 121, 122: Pad | 123: Seal ring portion |
| 125: Functional part | 125a: Upper winding |
| 125b: Lower winding | 126: Functional part |
| 127: Stacking structure | 1271: Insulation layer |
| 128: Distributing conductor | 1281: Penetration wiring |
| 1282: Lead-out wiring | 129: Conductive bonding material |
| 13: Semiconductor element | 13a: Obverse surface |
| 13b: Reverse surface | 131: Pad |
| 139: Conductive bonding material | 14: Semiconductor element |
| 14a: Obverse surface | 14b: Reverse surface |
| 141: Pad | 149: Conductive bonding material |
| 3: Conductive support | 31: Lead |
| 311: Island portion | 311a: Mount surface |
| 312: Terminal portion | 312a: Covered portion |
| 312b: Exposed portion | 32: Lead |
| 321: Island portion | 321a: Mount surface |
| 322: Terminal portion | 322a: Covered portion |
| 322b: Exposed portion | 33: Lead |
| 33A: Intermediate lead | 33B: Lateral lead |
| 331: Covered portion | 332: Exposed portion |
| 34: Lead | 34A: Intermediate lead |
| 34B: Lateral lead | 341: Covered portion |
| 342: Exposed portion | 4: Connection member |
| 41: Wire | 411: Neck portion |
| 412: Joint portion | 413: Loop portion |
| 42: Wire | 421: Neck portion |
| 422: Joint portion | 423: Loop portion |
| 43: Wire | 431: Neck portion |
| 432: Joint portion | 433: Loop portion |
| 44 to 47: Wire | 5: Sealing resin |
| 51: Top face | 52: Bottom face |
| 53: Side face | 531: Upper portion |
| 532: Lower portion | 533: Middle portion |
| 54: Side face | 541: Upper portion |
| 542: Lower portion | 543: Middle portion |
| 81: Lead frame | 810: Flat portion |
| 811: Lead | 811a: Island |
| 811b: Support lead | 812: Lead |
| 812a: Island | 812b: Support lead |
| 813, 814: Lead | 815: Outer frame |
| 816: Dam bar | 82: Resist |

### <Second Aspect>

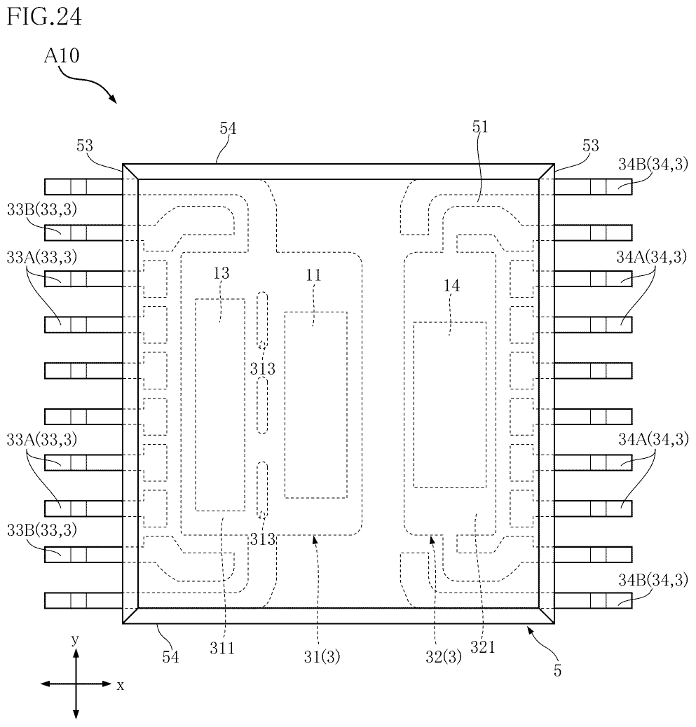

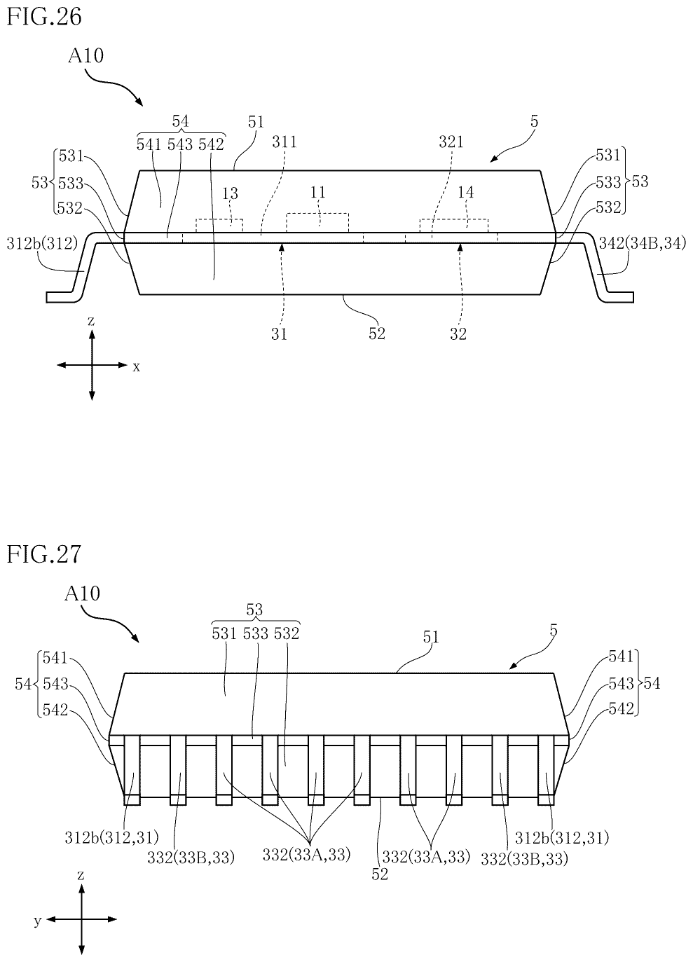

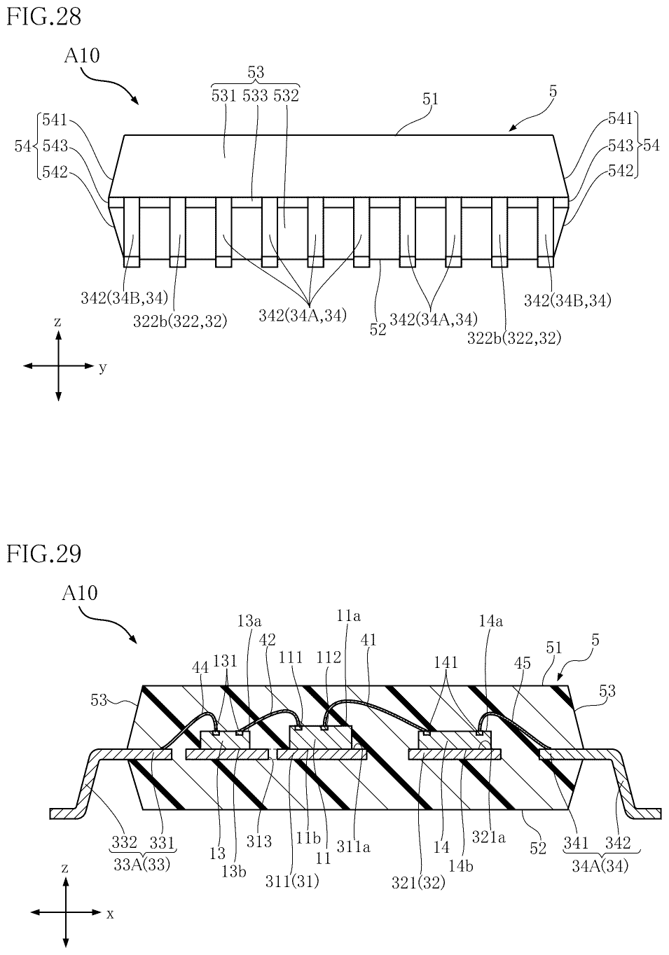

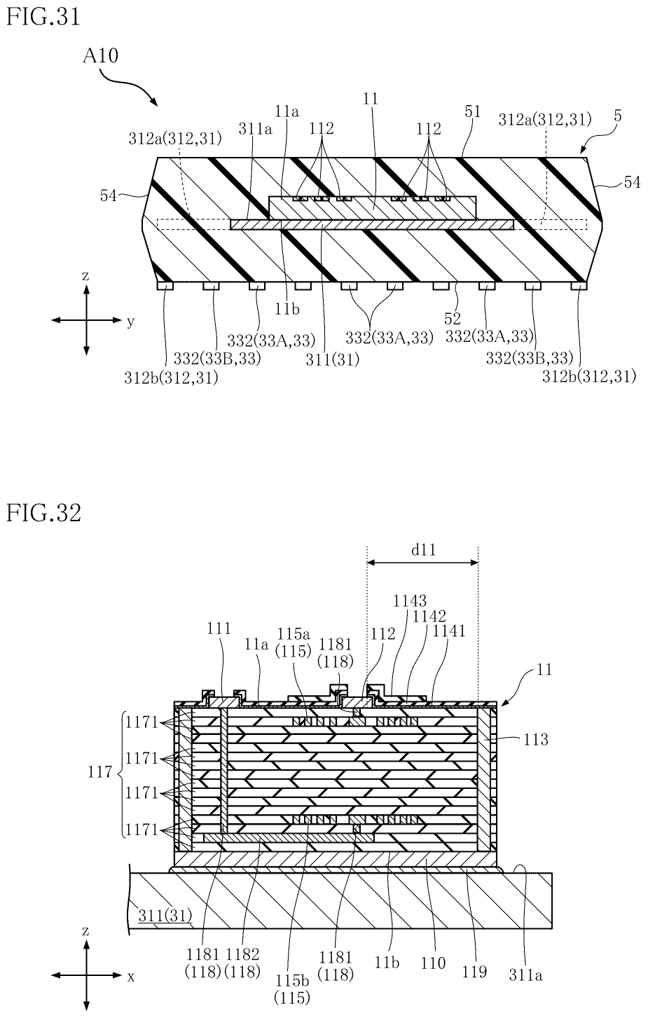

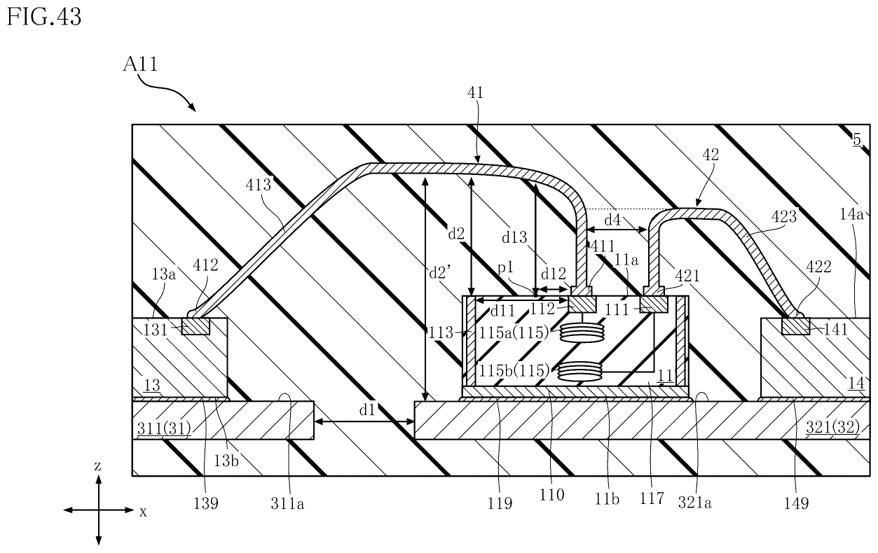

FIGS. 24 to 56 show semiconductor devices, design methods of semiconductor devices, and manufacturing methods of semiconductor devices in accordance with a second aspect of the present disclosure. The semiconductor devices described below with reference to FIGS. 24 to 56 are common in that the semiconductor element 11 includes a seal ring portion 113. In the following description, the components of the semiconductor devices (including variations thereof) that are identical or similar to those of the first aspect may be indicated by the same reference numerals, and redundant descriptions may be omitted.

FIGS. 24 to 32 show a semiconductor device A10 according to a first embodiment of the second aspect. As shown in these figures, the semiconductor device A10 includes a plurality of semiconductor elements 11, 13, 14, a conductive support 3, a plurality of connection members 4, and a sealing resin 5. The conductive support 3 includes a plurality of leads 31-34, and the connection members 4 include a plurality of wires 41, 42 and 44-47.

The Semiconductor elements 11, 13 and 14 are elements that provide the functional core of the semiconductor device A10. The semiconductor elements 11, 13 and 14 are each composed of individual elements. In the first direction x, the semiconductor element 11 is located between the semiconductor elements 13 and 14. In plan view, each semiconductor element 11, 13, 14 is rectangular, having relatively long sides or edges along the second direction y. The plan view shapes of the semiconductor elements 11, 13 and 14 are not limited to the examples shown in the figures.

The semiconductor element 13 has an obverse surface 13a and a reverse surface 13b, as shown in FIG. 29.

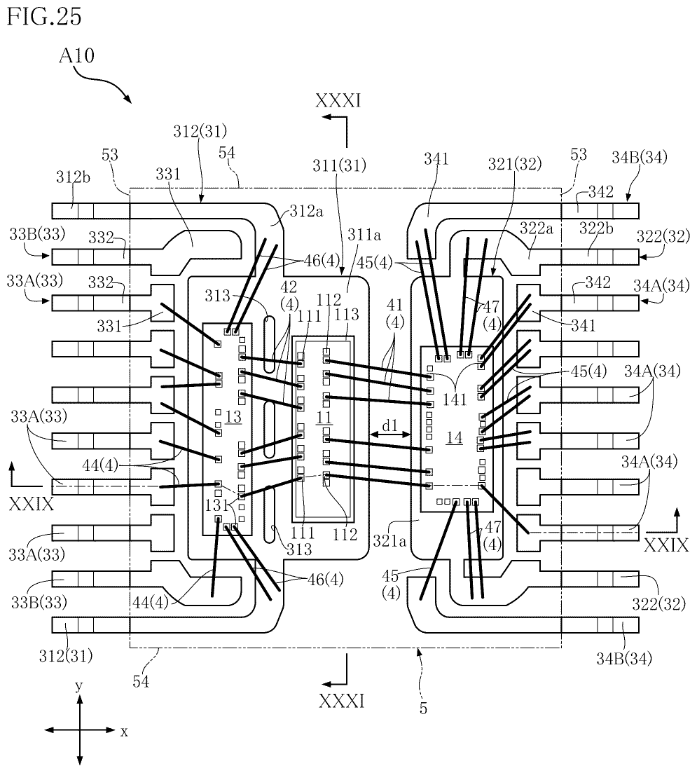

As shown in FIGS. 25 and 29, the semiconductor element 13 is provided with a plurality of pads 131. The pads 131 are disposed on the obverse surface 13a (a surface facing in the same direction as the mount surface 311a of the island portion 311 of the lead 31 described below).

The semiconductor element 14 has an obverse surface 14a and a reverse surface 14b, as shown in FIG. 29.

As shown in FIGS. 25 and 29, the semiconductor element 14 is provided with a plurality of pads 141. The pads 141 are disposed on the obverse surface 14a (a surface facing in the same direction as the mount surface 321a of the island portion 321 of the lead 32 described below).

The semiconductor element 11 has an obverse surface 11a and a reverse surface 11b, as shown in FIGS. 29-32.

The semiconductor element 11 includes a functional part 115. The functional part 115 may include plural pairs of upper windings 115a and lower windings 115b inside of the semiconductor element 11, where each pair may include one upper winding 115a and one lower winding. Accordingly, the semiconductor element 11 may have a plurality of upper windings 115a and a plurality of lower windings 115b.

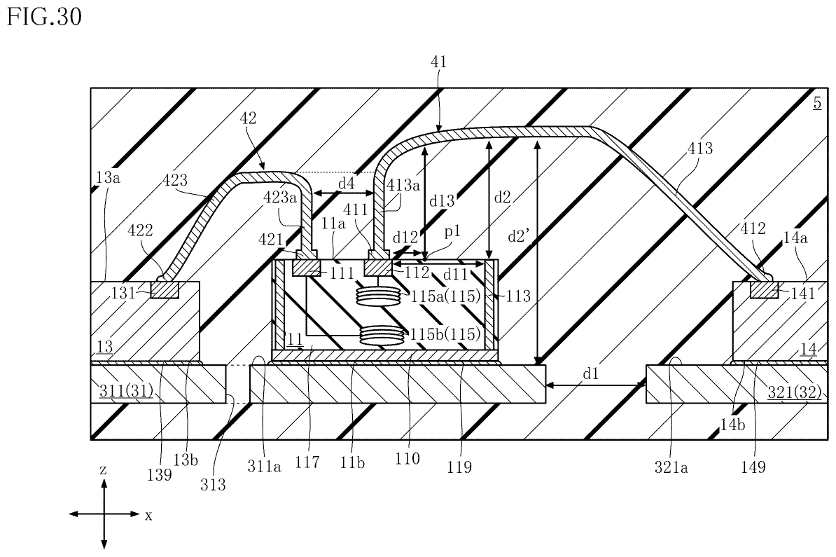

As shown in FIGS. 25, 29 and 30, the semiconductor element 11 has a plurality of pads 111 and 112. The pads 111 and 112 are provided on the obverse surface 13a. As shown in FIG. 30, each pad 111 is electrically connected to one of the lower windings 115b, and each pad 112 is electrically connected to one of the upper windings 115a. As shown in FIGS. 25, 29 and 30, each pad 111 is bonded to one of the wires 42, and each pad 112 is bonded to one of the wires 41.

As shown in FIGS. 25 and 30, the semiconductor element 11 includes a seal ring portion 113. In this embodiment, as shown in FIGS. 30 and 32, the distance d11 in the first direction x (the direction in which the semiconductor element 14 is located with respect to the semiconductor element 11) between each pad 112 and the seal ring portion 113 is, for example, not less than 100 μm and not more than 300 μm, though the present disclosure is not limited to this.

As shown in FIGS. 30 and 32, the semiconductor element 11 of semiconductor device A10 includes a semiconductor substrate 110, a protection film 1141, a passivation film 1142, a coil protection film 1143, a stacking structure 117, and a distributing conductor 118. As shown in FIG. 32, the stacking structure 117 includes a plurality of insulation layers 1171. The insulation layers 1171 as a whole are stacked on the upper surface of the semiconductor substrate 110. Each of the insulation layers 1171 also has a stacking structure made up of a lower etching stopper film and an upper interlayer insulating film, except for the lowest insulation layer 1171 that contacts the upper surface of the semiconductor substrate 110. The lowest insulation layer 1171 comprises only an interlayer insulating film or layer. The thicknesses of the respective insulation layers 1171 may be equal to or different from each other.

The upper and lower windings 115a, 115b are formed on different insulation layers 1171 in the stacking structure 117, thereby facing each other via one or more insulation layers 1171. In the illustrated example, ten insulation layers 1171 are disposed between the upper and lower windings 115a, 115b, where the lower winding 115b is formed on the fourth insulation layer 1171 from the semiconductor substrate 110, and the upper winding 115a is formed on the fifteenth insulation layer 1171. The total number of insulation layers 1171 is not limited to the example shown in the figure and may be changed depending on, for example, the voltage applied to the pads 111 and the pads 112.

The distributing conductor 118 includes a plurality of penetration wirings 1181 and a lead-out wiring 1182. In the example shown in FIG. 32, the penetration wires 1181 include one for connecting a pad 111 to the lead-out wiring 1182, one for connecting the lead-out wiring 1182 to the lower winding 115b, and one for connecting a pad 112 to the upper winding 115a.

The protection film 1141 is formed on the stacking structure 117, as shown in FIG. 32. The passivation film 1142 is formed on the protection film 1141, as shown in FIG. 32. The coil protection film 1143 is formed on the passivation film 1142 and selectively covers the area located directly above the upper winding 115a, as shown in FIG. 32. As understood from FIG. 32, a number of pad openings are formed in the protection film 1141, the passivation film 1142, and the coil protection film 1143 so that the pads 111 and the pads 112 are exposed to the outside. The protection film 1141 contains SiO₂, for example, and has a thickness of about 150 nm. The passivation film 1142 contains, for example, SiN and has a thickness of about 1000 nm. The coil protection film 1143 contains, for example, polyimide and has a thickness of about 4000 nm. The constituting material and thicknesses of the protection film 1141, the passivation film 1142 and the coil protection film 1143 are not limited to the above examples.

The structure of the semiconductor element 11 is not limited to the example described above. Specifically, the upper winding 115a and the lower winding 115b are not limited to being each planarly wound on a single insulation layer 1171, but may be three-dimensionally formed by being wound partly on multiple insulation layers 1171, respectively. In order to suppress the increase in thickness of the semiconductor element 11, however, it may be preferable that the upper winding 115a and the lower winding 115b are each wound planarly on a single insulation layer 1171.

In the semiconductor device A10, the power voltage for the semiconductor element 14 is higher than the power voltage for the semiconductor element 13. Thus, a potential difference is produced between the semiconductor element 13 and the semiconductor element 14. In light of this, a first circuit that includes the semiconductor element 13 as a component and a second circuit that includes the semiconductor element 14 as a component are insulated from each other by the semiconductor element 11. The components of the first circuit include, in addition to the semiconductor element 13, the lead 31, the leads 33, the wires 42, 44 and 46, and some portions of the semiconductor element 11 (such as the pads 111 and the lower windings 115b). The components of the second circuit include, in addition to the semiconductor element 14, the lead 32, the leads 34, the wires 41, 45, 47, and some portions of the semiconductor element 11 (such as the pads 112 and the upper windings 115a). The potentials of the first circuit and the second circuit are different from each other. In the semiconductor device A10, the potential of the second circuit is higher than that of the first circuit. With this condition, the semiconductor element 11 relays signals between the first circuit and the second circuit. In an inverter device of an electric vehicle or a hybrid vehicle, the voltage applied to the ground of the semiconductor element 13 is about 0 V, while the voltage applied to the ground of the semiconductor element 14 may transiently be 600 V or more. Depending on the specifications of the inverter device, the voltage applied to the ground of the semiconductor element 14 may be 3750 V or more.

The conductive support 3 provides a conductive path between the semiconductor elements 11, 13, 14 and the circuit board on which the semiconductor device A10 is mounted. The conductive support 3 includes a lead 31, a lead 32, leads 33 and leads 34.

The lead 31 and the lead 32 are spaced apart from each other in the first direction x, as shown in FIGS. 24 and 25. In the semiconductor device A10, the semiconductor elements 11 and 13 are mounted on the lead 31, and the semiconductor element 14 is mounted on the lead 32.

The lead 31 includes an island portion 311 and two terminal portions 312, as shown in FIG. 25.

The island portion 311 has a mount surface 311a facing one side (upper side) of the thickness direction z, as shown in FIGS. 29 and 30. As shown in FIG. 30, the semiconductor element 11 is bonded to the mount surface 311a via a conductive bonding material 119, and the semiconductor element 13 is also bonded to the mount surface 311a via a conductive bonding material 139. The semiconductor substrate 110 of the semiconductor element 11 is at substantially the same potential as the island portion 311 via the conductive bonding material 119.

As shown in FIGS. 25, 29 and 30, in the semiconductor device A10, a plurality of through-holes 313 are formed in the island portion 311. The through-holes 313 each extend through the island portion 311 in the thickness direction z along the second direction y. In plan view, at least one of the through-holes 313 is located between the semiconductor element 11 and the semiconductor element 13. The through-holes 313 are arranged along the second direction y. Unlike the illustrated example, the island portion 311 may be formed with no through-holes 313.

Each of the two terminal portions 312 includes a covered portion 312a and an exposed portion 312b.

The lead 32 includes an island portion 321 and two terminal portions 322.

As shown in FIGS. 29 and 30, the island portion 321 has a mount surface 321a facing one side (the upper side) of the thickness direction z. As shown in FIG. 30, the semiconductor element 14 is bonded to the mount surface 321a via a conductive bonding material 149.

Each of the two terminal portions 422 includes a covered portion 322a and an exposed portion 322b.

As shown in FIGS. 24 and 25, the leads 33 are opposite from the island portion 321 of the lead 32 with respect to the island portion 311 of the lead 31 in the first direction x. The leads 33 are arranged along the second direction y. At least one of the leads 33 is electrically connected to the semiconductor element 13 via one of the wires 44. The leads 33 include a plurality of intermediate leads 33A (six in the illustrated example) and two lateral leads 33B. The two lateral leads 33B are spaced apart from each other so as to sandwich the intermediate leads 33A in the second direction y. In the second direction y each of the two lateral leads 33B is located between one of the two terminal portions 312 of the lead 31 and the intermediate lead 33A located closest to this one terminal portion 312.

As shown in FIGS. 25 and 29, the leads 33 (intermediate leads 33A and two lateral leads 33B) each have a covered portion 331 and an exposed portion 332.

The shape, arrangement and number of the leads 33 are not limited to the examples shown in the figures. For example, the number of the leads 33 may be less than or greater than the number of the leads shown in the examples (i.e., eight leads). The leads 33 may include an additional lead(s) disposed outwardly of one of the two terminal portions 312 of the lead 31.

As shown in FIGS. 24 and 25, the leads 34 are opposite from the leads 33 with respect to the island portion 311 of the lead 31 in the first direction x. The leads 34 are arranged along the second direction y. At least one of the leads 34 is electrically connected to the semiconductor element 14 via one of the wires 45. The leads 34 include a plurality of intermediate leads 34A (six in the illustrated example) and two lateral leads 34B. The two lateral leads 34B are spaced apart from each other so as to sandwich the intermediate leads 34A in the second direction y. In the second direction y each of the two terminal portions 322 of the lead 32 is located between one of the two lateral leads 34B and the intermediate lead 33A located closest to this one lateral lead 34B.

As shown in FIGS. 25 and 29, the leads 34 (intermediate leads 34A and two lateral leads 34B) each have a covered portion 341 and an exposed portion 342.

The shape, arrangement, and number of leads 34 are not limited to the examples shown in the figures. For example, the number of leads 34 may be less than or greater than the number of the leads shown in the examples (i.e., eight leads). The two lateral leads 34B may each be located, in the second direction y, between one of the two terminal portions 322 of the lead 32 and the intermediate lead 34A located closest to this one terminal portion 322.

As noted above, the connection members 4 include wires 41, 42 and 44-47. The connection members 4 may be bonding ribbons or plate-shaped metal members in place of the wires (bonding wires) 41, 42, 44-47.

The wires 41, 42, 44-47 may be made of a metal material such as copper or a copper alloy (e.g., a palladium-copper alloy), for example. Without limitation, the wires 41, 42, 44-47 may each be made up of a core member (containing copper for example) and a surface member (containing palladium for example) covering the core member. The metal material of the wires 41, 42, 44-47 may contain gold, aluminum or silver in place of copper or a copper alloy.

The wires 41 are each bonded to one of the pads 112 of the semiconductor element 11 and bonded to one of the pads 141 of the semiconductor element 14, as shown in FIGS. 25 and 30. Each wire 41 electrically connects the semiconductor element 11 and the semiconductor element 14. The wires 41 are arranged along the second direction y. In plan view, each wire 41 bridges between the island portion 311 of the lead 31 and the island portion 321 of the lead 32.

As shown in FIG. 30, each wire 41 includes two joint portions 411, 412 and a loop portion 413. In the wire 41, the joint portion 411 is bonded to one of the pads 112, while the joint portion 412 is bonded to one of the pads 141. The loop portion 413 connects the two joint portions 411, 412. The loop portion 413 rises up from the joint portion 411 in the thickness direction, and then curves to extend toward the other joint portion 412. The loop portion 413 has a rise section 413a. The rise section 413a is a part of the loop portion 413 that connects to the joint portion 411 and extends up in the thickness direction z. In the illustrated example (see FIG. 30), the rise section 413a as a whole may extend in parallel to the thickness direction z. Each wire 41 may be provided by using a ball bonding process, where one end of the wire 41 may be first-bonded to one of the pads 112, and the other end may be second-bonded to one of the pads 141. Alternatively, each wire 41 may be provided by other processes such as wedge bonding, for example. When wedge bonding is used for a wire 41, the shapes of the respective joint portions 411 and 412 may be substantially the same.

In the semiconductor device A10, the semiconductor element 11 has points p1 (see FIG. 30) corresponding to the respective pads 112. The points p1 are located between the corresponding pads 112 and the seal ring portions 113 in the first direction x. The distance d12 between the point p1 and the pad 112 (see FIG. 30) is, for example, 50 μm or more and 150 μm or less. As such, the obverse surface 11a of the semiconductor element 11 has a point p1 located at a distance d12 in the first direction x from each pad 112 toward the seal ring portion 113. The distance d13 between the point p1 and the wire 41 (loop portion 413) in the thickness direction z (see FIG. 30) is 85% or more and 95% or less of the distance d2. In other words, the obverse surface 11a of the semiconductor element 11 has a point p1 where the distance d13 in the thickness direction z between the wire 41 (loop portion 413) and the obverse surface 11a is equal to 85% or more and 95% or less of the distance d2, and the distance d12 between the point p1 and the pad 112 in the first direction x is equal to not less than 50 μm and not more than 150 μm. According to the present disclosure, however, the value of the distance d12 and the ratio of the distance d13 to the distance d2 are not limited to the above examples.

As shown in FIGS. 25 and 30, each wire 42 is bonded to one of the pads 111 of the semiconductor element 11 and to one of the pads 131 of the semiconductor element 13. Each wire 42 electrically connects the semiconductor element 11 and the semiconductor element 13. The wires 42 are arranged along the second direction y. As shown in FIG. 30, in this embodiment, the uppermost part of each wire 42 in the direction z is lower than the uppermost part of each wire 41 (in other words, located closer to the obverse surface 11a of the semiconductor element 11 in the thickness direction z).

As shown in FIG. 30, each wire 42 includes two joint portions 421, 422 and a loop portion 423. In each wire 42, the joint portion 421 is bonded to one of the pads 111, and the other joint portion 422 is bonded to one of the pads 131. The loop portion 423 connects the two joint portions 421 and 422. The loop portion 423 rises from the joint portion 421 in the thickness direction z, and then curves to extend toward the joint portion 422. The loop portion 423 has a rise section 423a. The rise section 423a is a part of the loop portion 423 that connects to the joint portion 421 and extends in the thickness direction z. In the illustrated example (see FIG. 30), the rise section 423a extends in parallel to the thickness direction z. Each wire 42 is provided by ball bonding, for example, and is first-bonded to one of the pads 111 and second-bonded to one of the pads 131. Alternatively, each wire 42 may be formed by other methods such as a wedge bonding process. By using wedge bonding, the shape of the joint portion 421 is generally the same as that of the joint portion 422.

In this embodiment, as shown in FIG. 30, the uppermost top of the wire 42 in the thickness direction z is lower than the uppermost top of the wire 41 in the thickness direction z. In other words, the uppermost top of the wire 42 is lower (closer to the island portions 311, 321) in the thickness direction z than the uppermost top of the wire 41. Alternatively, the apexes of the respective wires 41, 42 may be at the same height in the thickness direction z, or the apex of the wire 42 may be higher in the thickness direction z than the apex of the wire 41.

Each wire 44 is bonded to one of the pads 131 of the semiconductor element 13 and one of the covered portions 331 of the leads 33, as shown in FIG. 25. Each wire 44 electrically connects the semiconductor element 14 and one of the leads 33.

Each wire 45 is bonded to one of the pads 141 of the semiconductor element 14 and one of the covered portions 341 of the leads 34, as shown in FIG. 25. Each wire 45 electrically connects the semiconductor element 14 and one of the leads 34.

Each wire 46 is bonded to one of the pads 131 of the semiconductor element 13 and to the covered portion 312a of one of the two terminal portions 312, as shown in FIG. 25. The wires 46 electrically connect the semiconductor element 13 and the leads 31. According to the present disclosure, use may be made of a plurality of wires 46 or a single wire 46.

Each wire 47 is bonded to one of the pads 141 of the semiconductor element 14 and one of the covered portions 322a of the two terminal portions 322, as shown in FIG. 25. Each wire 47 electrically connects the semiconductor element 14 and the lead 32. According to the present disclosure, use may be made of a plurality of wires 47 or a single wire 47.

The sealing resin 5 covers the semiconductor element 11, the semiconductor element 13, the semiconductor element 14, a part of the conductive support 3, and the connection members 4, as shown in FIG. 24. The sealing resin 5 has electrical insulation properties. For instance, the sealing resin 5 insulates predetermined components of the first circuit (e.g., the lead 31) and predetermined components of the second circuit (e.g., the lead 32) from each other.

As shown in FIGS. 25-28, the sealing resin 5 has a top face 51, a bottom face 52, a pair of side faces 53, and a pair of side faces 54. The side faces 53 each include an upper portion 531, a lower portion 532 and a middle portion 533. Likewise, the side faces 54 each include an upper portion 541, a lower portion 542 and a middle portion 543.

Generally, in the motor driver circuit of an inverter device, use may be made of a half-bridge circuit provided with a low-side (low-potential side) switching element and a high-side (high-potential side) switching element. In the following description, without limitation, these switching elements are MOSFETs. In this example, the reference potential of the source of the low-side switching element is ground, and the reference potential of the gate driver for driving the switching element is also ground. On the other hand, the reference potential of the source of the high-side switching element and the reference potential of the gate driver for driving the switching element correspond to the potential at the output node of the half-bridge circuit. When the high-side and low-side switching elements are driven, the potential at the output node may vary in response to the driving of the switching elements, and thus the reference potential of the gate driver for driving the high-side switching element may also vary. When the high-side switching element is on, the reference potential of the gate driver may be equivalent to the voltage applied to the drain of the high-side switching element (e.g., 600 V or more). In the semiconductor device A10, the ground of the semiconductor element 13 is separated from the ground of the semiconductor element 14. Thus, when the semiconductor device A10 is used as a gate driver for driving the high-side switching element, a voltage equivalent to the voltage applied to the drain of the high-side switching element is transiently applied to the ground of the semiconductor element 14.

In the semiconductor device A10, it is arranged that the distance between any two of the certain components provided in the first circuit and the second circuit is greater than the distance do [mm] determined by Formula (1). In Formula (1), the term “Y” is the required length of insulation life [years] for the semiconductor device A10, the terms “A” and “B” are constants depending on the material of the sealing resin 5, and the term “X” is the voltage (effective value) [kVrms] used in the semiconductor device A10. The voltage X is, for example, the difference of voltage applied between two target points or sites. In the semiconductor device A10, AC voltage is generated by the switching elements in operation, and the effective value is used for the voltage X. In an example where the sealing resin 5 is made of an epoxy resin, the constant A is 1000×416 and the constant B is 16. In the formula, the number “0.15” is an offset value for calculating the distance d0 [mm]. The unit of the offset value may be [mm]/(([year]\hat{ }(1/B))×[kVrms]) so that the dimension of the right side of Formula (1) corresponds to the dimension of the left side (i.e., distance d0) of Formula (1). As understood from Formula (1), the distance d0 becomes greater as the voltage is greater, and/or the insulation life year is greater, and it also depends on the material of the sealing resin 5. For instance, the distance d0 calculated by Formula (1) is about 0.0294 [mm] (=29.4 [μm]) when the insulation life year Y is 20 [years], the voltage X is 1 [kVrms], and the constant A is 1000×416 for epoxy resin.

Specifically, the distance d1 (see FIG. 30) in the first direction X between the leads 31 and 32 is greater than the distance d0. In setting the distance d1, the voltage X is, for example, the difference between the voltage applied to the first circuit (the lead 31) and the voltage applied to the second circuit (the lead 32). Alternatively, the voltage X in setting the distance d1 may be greater than the difference of voltage applied between the first and second circuits. In the example shown in FIG. 30, the distance d1 is the shortest distance between the island portions 311 and 321 where the two island portions are closest to each other. The distance d1 is, for example, 10 mm or less, which prevents the semiconductor device A10 from becoming unduly large. In the semiconductor device A10, the distance d1 is about 300 μm, which is greater than the distance d0 (29.4 μm).

The distance d2 (see FIG. 30) between each wire 41 and the semiconductor element 11 is greater than the distance d0. In the example shown in FIG. 30, the distance d2 is the shortest distance in the thickness direction z where the loop portion 413 and the seal ring portion 113 of the semiconductor element 11 are closest to each other. In this embodiment, since the wire 41 is a component of the second circuit, the voltage X used in setting the distance d2 is, for example, the difference between the voltage applied to the second circuit (each wire 41) and the voltage applied to the first circuit (the seal ring portion 113 of the semiconductor element 11). Alternatively, the voltage X in setting the distance d2 may be greater than the voltage difference between the first and second circuits. The distance d2 is, for example, 10 mm or less, which prevents the semiconductor device A10 from becoming unduly large. In the semiconductor device A10, the distance d2 is about 170 μm, which is greater than the distance d0 (29.4 μm).

The distance d2′ (see FIG. 30) between each wire 41 and the lead 31 is greater than the distance d0. In the example shown in FIG. 30, the distance d2′ is the shortest distance in the thickness direction z where the loop portion 413 and the mount surface 311a of the island portion 311 are closest to each other. Similarly to the setting of distance d2, the difference between the voltage applied to the second circuit (the wires 41) and the voltage applied to the first circuit (the lead 31) may be used for the voltage X to be used in setting the distance d2′. Alternatively, the voltage X in setting the distance d2′ may be greater than the voltage difference between the first and second circuits. The distance d2′ is, for example, 10 mm or less, which prevents the semiconductor device A10 from becoming unduly large. In the semiconductor device A10, the distance d2′ is about 470 μm, which is greater than the distance d0 (29.4 μm).

The distance d4 between the wire(s) 41 and the wire(s) 42 (see FIG. 30) is greater than the distance d0. In the example shown in FIG. 30, the distance d4 is the shortest distance in the direction perpendicular to the thickness direction z (in FIG. 7, the first direction x) at the point where the rise section 413a of the loop portion 413 is closest to the rise section 423a of the loop portion 423. In this embodiment, the wire 41 is a component of the second circuit and the wire 42 is a component of the first circuit. Thus, in setting the distance d4, the difference between the voltage applied to the second circuit (each wire 41) and the voltage applied to the first circuit (each wire 42) is used for voltage X, for example. Alternatively, the voltage X to be used in setting the distance d4 may be greater than the voltage difference between the first and second circuits. In the semiconductor device A10, the distance d4 is about 300 μm, which is greater than the distance do (29.4 μm).

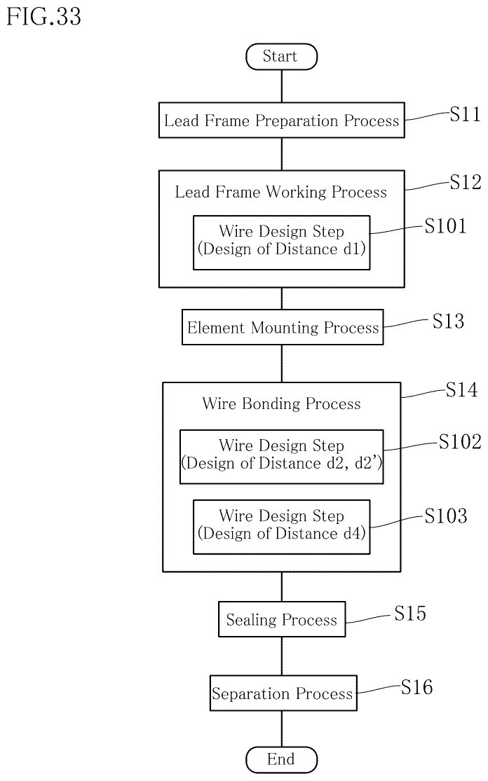

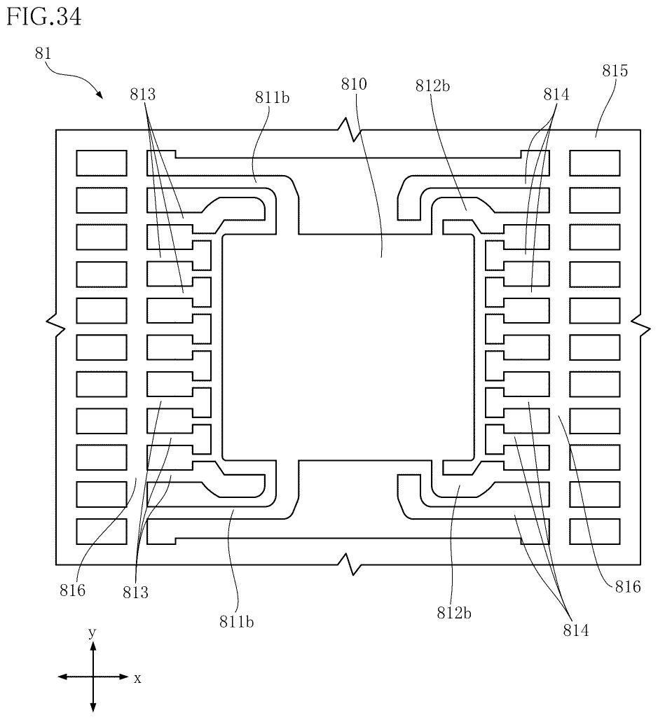

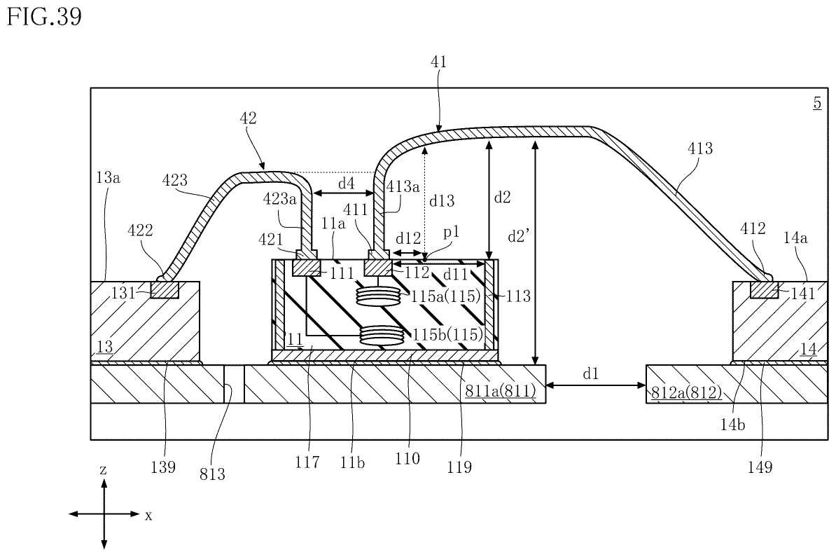

Examples of manufacturing method of the semiconductor device A10 will be described below with reference to FIGS. 33-40. FIG. 33 is a flowchart showing an example of a manufacturing method of the semiconductor device A10. FIGS. 34-38 and 40 are plan views showing processes of the manufacturing method of the semiconductor device A10. FIG. 39 is a cross-sectional view showing a process of the manufacturing method of the semiconductor device A10. The cross-section in FIG. 39 corresponds in location to the cross-section in FIG. 30.

As shown in FIG. 33, the manufacturing method of the semiconductor device A10 may include a lead frame preparation process S11, a lead frame working process S12, an element mounting process S13, a wire bonding process S14, a sealing process S15 and a separation process S16. Further, the manufacturing method for the semiconductor device A1 includes a design method having design steps. Specifically, the design steps may include a wire design step S101, another wire design step S102, and another wire design step S103 as described below.

In the lead frame preparation process S11, a lead frame 81 shown in FIG. 34 is prepared. The lead frame 81 includes a flat portion 810, a plurality of support leads 811b, 812b, a plurality of leads 813, 814, an outer frame 815, and a dam bar 816, as shown in FIG. 34. The lead frame 81 is produced, for example, by punching out a rectangular copper sheet. As shown in FIG. 34, the support leads 811b, 812b are connected to the flat section 810. The support leads 811b, 812b and the leads 813, 814 are connected via the outer frame 815 and the dam bar 816. Of the lead frame 81, the outer frame 815 and the dam bar 816 do not constitute the semiconductor device A10.

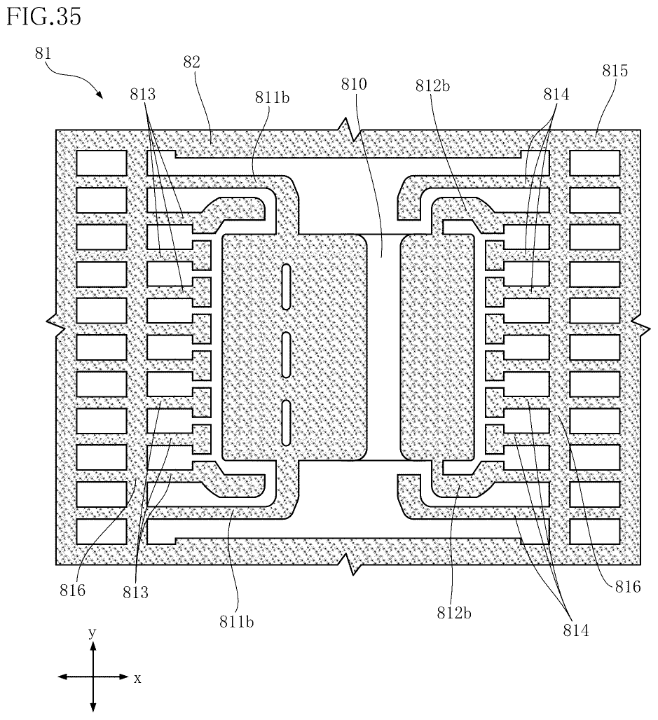

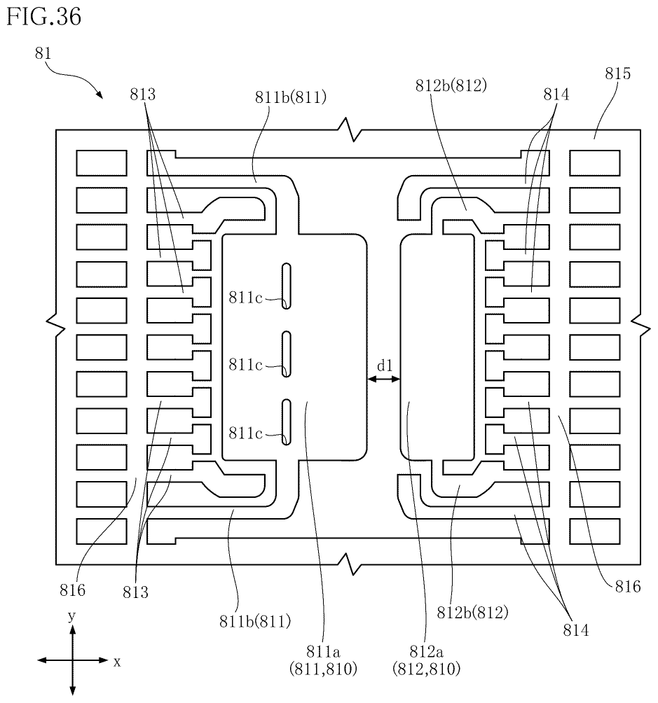

In the lead frame working process S12, the flat portion 810 of the lead frame 81 is divided into two islands 811a and 812a (see FIG. 36). Specifically, in the lead frame working process S12, a resist 82 is formed on the lead frame 81 as shown in FIG. 35. In FIG. 35, the resist 82 is indicated by dots. Then, an etching process is applied to the lead frame 81 with the resist 82 formed thereon. As a result, the portion(s) of the lead frame 81 exposed from the resist 82 is removed, and thus the flat portion 810 is divided into two islands 811a and 812a, as shown in FIG. 36. In addition, a plurality of through-holes 811c are formed in the flat portion 810 (island 811a). Then, by removing the resist 82, the lead frame 81 shown in FIG. 36 is formed. In the lead frame 81 shown in FIG. 36, the support leads 811b are connected to the island 811a, thereby constituting a lead 811 including the island 811a and the support leads 811b. In the lead frame 81 shown in FIG. 36, the support leads 812b are connected to the island 812a, thereby constituting a lead 812 including the island 812a and the support leads 812b.

In the present embodiment, the wire design step S101 is performed during the lead frame working process S12, as shown in FIG. 33.

In the wire design step S101, when dividing the flat portion 810 into two islands 811a and 812a, it is designed that the distance d1 (see FIGS. 35, 36, and 39) in the first direction x between the island 811a (lead 811) and the island 812a (lead 812) will be greater than the distance d0, which is determined by Formula (1). As explained in detail below, the island 811a (lead 811) becomes the island portion 311 (lead 31), and the island 812a (lead 812) becomes the island portion 321 (lead 32). Thus, in the process of designing the distance d1 in the wire design step S101, it is designed that the distance d1 between the leads 31 and 32 in the first direction x will be greater than the distance d0. By designing the distance d1 to be greater than the distance d0 and also be mm or less in the wire design step S101, it is preferable to prevent the resulting semiconductor device A10 from becoming unduly large.

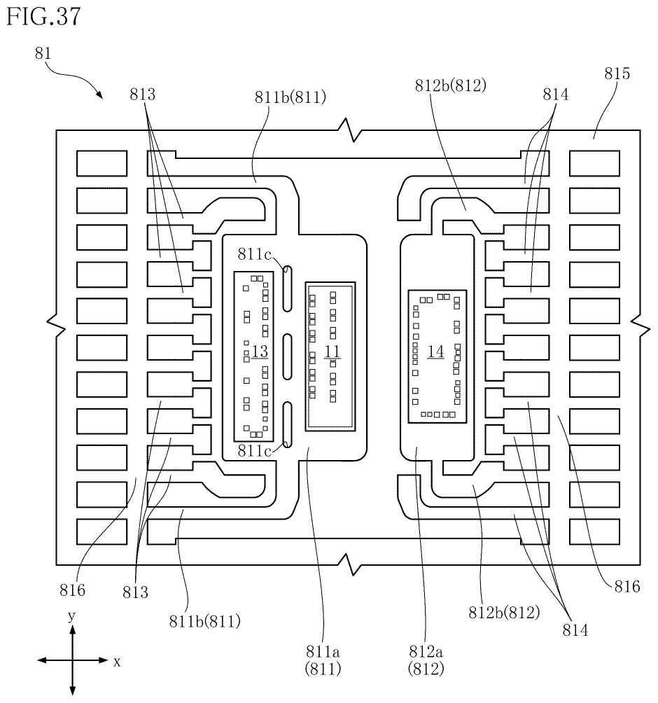

In the element mounting process S13, three semiconductor elements 11, 13 and 14 are prepared and mounted on the lead frame 81, as shown in FIG. 37. Specifically, the two semiconductor elements 11, 13 are bonded to the island 811a by a conductive bonding material not shown in the figure, and the semiconductor element 14 is bonded to the island 812a by a conductive bonding material not shown. Here, in the semiconductor element 11 to be prepared, the distance d11 (see FIG. 30) along the first direction x between the pad(s) 112 and the seal ring portion 113 is not less than 100 μm and not more than 300 μm.

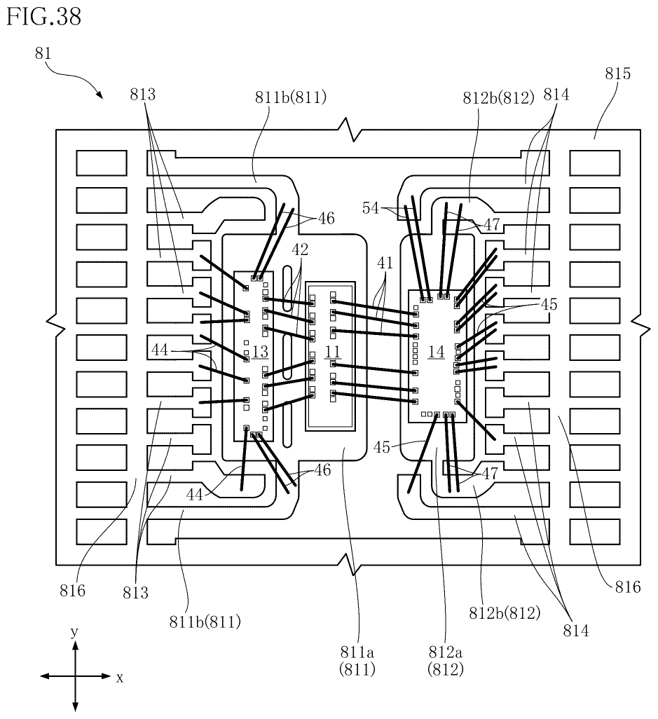

In the wire bonding process S14, the wires 41, 42, 44, 45, 46 and 47 are provided, as shown in FIGS. 38 and 39. The providing of the wires 41, 42 and 44-47 may be done using a well-known wire bonder. The order of provision of the wires 41, 42 and 44-47 is not limitative.

In the present embodiment, as shown in FIG. 33, the wire design step S102 and the wire design step S103 are performed during the wire bonding process S14.

In the wire design step S102, it is designed in providing each wire 41 that the distance d2 in the thickness direction z between the wire 41 and the semiconductor element 11 is greater than the distance d0, as shown in FIG. 39, and also that the distance d2′ in the thickness direction z between the wire 41 and the lead 811 is greater than the distance d0. To this end, the bonding of the wire 41 is performed such that the loop portion 413 of the wire 41 is spaced apart from the seal ring portion 113 and the island 811a of the semiconductor element 11 by more than the distance do. As understood below, the lead 811 becomes the lead 31. Thus, in the process of designing the distance d2′ in the wire design step S102, it is designed that the distance d2′ in the thickness direction z between the wire 41 and the lead 31 will be greater than the distance d0. In the wire design step S102, it is preferable that the distance d2 is to be greater than the distance d0 but less than or equal to 10 mm, for example, thereby preventing the resulting semiconductor device A10 from becoming unduly large. Likewise, in the wire design step S102, it is desirable that the distance d2′ is to be greater than the distance d0 but less than or equal to 10 mm, for example, thereby preventing the resulting semiconductor device A10 from becoming unduly large.

In the wire design step S103, each wire 41, 42 is designed so that the distance d4 between the wire 41 and the wire 42 is greater than the distance d0, as shown in FIG. 39. For example, when the wire 41 is bonded before the wire 42, the wire 42 is bonded so that the rise section 423a of the loop portion 423 of the wire 42 is spaced apart from the rise section 413a of the loop portion 413 of the wire 41 by more than the distance d0. Conversely, when the wire 42 is bonded before the wire 41, the wire 41 is bonded so that the rise section 413a of the loop portion 413 of the wire 41 is spaced apart from the rise section 423a of the loop portion 423 of the wire 42 by more than the distance d0. In the wire design step S103, it is preferable to design the distance d4 to be greater than the distance d0 but less than 10 mm, for example, thereby preventing the resulting semiconductor device A10 from becoming unduly large.

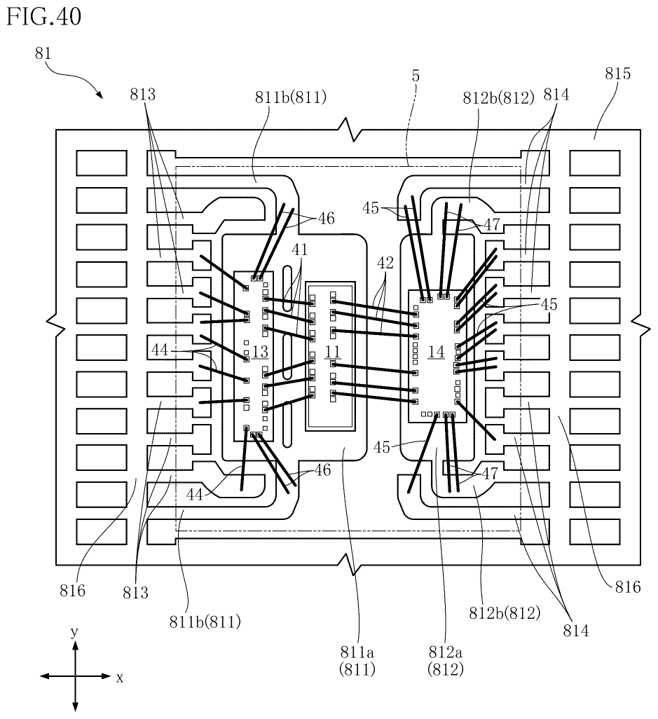

In the sealing process S15, as shown in FIG. 40, the sealing resin 5 is formed. In FIG. 40, the sealing resin 5 is indicated by imaginary lines (double-dotted lines). The sealing resin 5 may be formed by transfer molding, for example. The sealing resin 5 may be made of an epoxy resin, for example.

Subsequently, in the separation process S16, dicing is performed to divide the product assembly into individual pieces, whereby the leads 811, 812, 813 and 814 connected to each other via the outer frame 815 and the dam bar 816 are separated. Thus, after the separation, the lead 811 provides the lead 31. Specifically, the island 811a provides the island portion 311, and the supporting leads 811b provide the respective terminal portions 312. Likewise, the lead 812 provides the lead 32. Specifically, the island 812a provides the island portion 321, and the supporting leads 812b provide the respective terminal portions 322. Further, the leads 813 provide the respective leads 33, and the leads 814 provide the respective leads 34. The leads 33 (or leads 813) and the leads 34 (or leads 814) may be subjected to the required bending during the separation process S16 or during the punching process in the lead frame preparation process S11.

Through the above processes, the semiconductor device A10 is manufactured. The manufacturing method of the semiconductor device A10 is not limited to the above example. For instance, by forming two islands 811a, 812a by the punching process in the lead frame preparation process S11, the lead frame working process S12 may be eliminated. In this case, the wire design step S101 is performed during the lead frame preparation process S11. It should be noted that the formation of the two islands 811a, 812a may be more precise by the etching process in the lead frame fabrication process S12 than by the punching process in the lead frame preparation process S11, whereby the distance d1 can reliably be greater than the distance d0. As another manufacturing method, a rectangular copper plate may be prepared in the lead frame preparation process S11, and the formation of resist 82 and etching treatment may be performed on the copper plate in the lead frame working process S12. In this manner, a plurality of members such as the leads 811 (island 811a and supporting leads 811b), the leads 812 (island 812a and supporting leads 812b), the leads 813, 814, the outer frame 815, and the dam bar 816 may be formed collectively from the prepared copper plate.

The following describes the workings and advantages of the semiconductor device A10, the method of designing the semiconductor device A10, and the method of manufacturing the semiconductor device A10.

In the semiconductor device A10, the distance d2 is greater than the distance d0 determined by Formula (1). The distance d2 is the distance in the thickness direction z between the loop portion 413 of the wire 41 and the seal ring portion 113 of the semiconductor element 11. Since the semiconductor element 11 is bonded to the island portion 311 (lead 31), the seal ring portion 113 has the same potential as the island portion 311 and can be regarded as a component of the first circuit. Likewise, since the wire 41 is electrically connected to the semiconductor element 14, it has the same potential as the semiconductor element 14 and can be regarded as a component of the second circuit. Since the seal ring portion 113 has a relatively low potential and the wire 41 has a relatively high voltage, a potential difference is generated between the seal ring portion 113 and the wire 41. In the semiconductor device A10, by making the above distance d2 greater than the distance d0, it is possible to design the dielectric strength, or insulation resistance voltage, which is suitable for actual use between the seal ring portion 113 and the wire 41. Since the semiconductor device A10 may ensure an adequate dielectric strength between the seal ring portion 113 and the wire 41, the occurrence of dielectric breakdown can be suppressed. In the design method of the semiconductor device A10, the wire design step S102 is designed so that the above distance d2 is to be greater than the distance d0. This enables the design and manufacture of the semiconductor device A10 in which the occurrence of dielectric breakdown is suppressed. In the semiconductor device A10, the leads 31 and 32 are examples of the “first lead” and “second lead” described in Clause B, respectively. The semiconductor element 11 and the semiconductor element 14 are examples of the “first semiconductor element” and the “second semiconductor element” described in Clause B, respectively. The wire 41 is an example of a “first wire” as described in Clause B. The pad 112 is an example of a “first pad” as described in Clause B. The seal ring portion 113 is an example of a “seal ring portion” as described in Clause B. The distance d2 is an example of the “first distance” as described in Clause B.

In the semiconductor device A10, the distance d2 is greater than the distance d0, and the distance d11 in the first direction x between the pad 112 and the seal ring portion 113 is greater than 100 μm or more. In the semiconductor device A10, the wire 41 is a copper wire containing copper. The copper wire 41 is less bendable than a gold wire (a wire that contains gold in its composition). Therefore, if the copper wire 41 is subjected to the same wire bonding process (looping) as the gold wire, cracks may occur in the wire 41 and excessive stress may be applied to the semiconductor element 11 (pad 112), damaging the pad 112. Therefore, when the wire 41 is made of copper, looping may need to be performed so that it has a gently rising form. In the semiconductor device A10, since the above distance d11 is 100 μm or more, the distance d2 can be made greater than the distance d0 even when the rise of the wire 41 is gradual. In the case where the wire 41 is a copper wire, the semiconductor device A10 can suppress the occurrence of wire cracks and damage to the semiconductor element 11 while making the distance d2 greater than the distance d0. However, if the distance d11 is too great, the dimension of the semiconductor element 11 in the first direction x increases, causing the semiconductor device A10 to become unduly large. Therefore, by setting the distance d11 to between 100 μm and 300 μm, that is, not less than 100 μm and not greater than 300 μm, the generation of wire cracks and damage to the semiconductor element 11 can be suppressed, while also preventing the semiconductor device A10 from becoming unduly large. In the semiconductor device A10, the distance d11 is an example of the “second distance” described in Clause B.

In the semiconductor device A10, the distance d11 is greater than the distance d2. With this configuration, the distance d2 can be made greater than the distance d0 even when the looping is performed such that the rise section 413a of the wire 41 has a gradual rise. As such, the distance d11 being greater than the distance d2 is desirable to ensure an appropriate dielectric strength and to suppress the occurrence of dielectric breakdown.

In the semiconductor device A10, the distance d12 is 50 μm or more and 150 μm or less. The distance d12 is the separation distance between each pad 112 and a point p1 (see FIG. 30) corresponding to the pad 112, where the point p1 is a point on the obverse surface 11a where the distance d13 in the thickness direction z between the obverse surface 11a and the wire 41 is in a range of 85% to 95% of the distance d2. With this configuration, it is easy to make the distance d2 greater than the distance d0. As such, the distance d12 being 50 μm or more and 100 μm or less is desirable to ensure an appropriate dielectric strength and to suppress the occurrence of dielectric breakdown. In the semiconductor device A10, the point p1 is an example of a “point” as described in Clause B, the distance d12 is an example of a “third distance” as described in Clause B, and the distance d13 is an example of a “fourth distance” as described in Clause B.

In the semiconductor device A10, as in the semiconductor device A1, the distance d1 in the first direction x between the leads 31 and 32 is greater than the distance d0 determined by Formula (1). Therefore, as with the semiconductor device A1, the semiconductor device A10 may ensure an appropriate dielectric strength between the two leads 31, 32, and thus suppress the occurrence of dielectric breakdown. In the design method of the semiconductor device A10, it is designed by the wire design step S101 that the distance d1 is to be greater than the distance d0. This enables the design and manufacture of the semiconductor device A10 in which the occurrence of dielectric breakdowns is suppressed.

In the semiconductor device A10, the distance d2′ between each wire 41 and the lead 31 is greater than the distance d0 determined by Formula (1). In this embodiment, the distance d2′ is the distance in the thickness direction z between the loop portion 413 of the wire 41 and the mount surface 311a of the island portion 311 (lead 31). The wire(s) 41 is electrically connected to the upper winding 115a of the semiconductor element 11 (functional part 115) and therefore a component of the second circuit. The lead 31, on the other hand, is a component of the first circuit. Since the wire 41 is a relatively high voltage and the lead 31 is a relatively low voltage, a potential difference is generated between the wire 41 and the lead 31. In the semiconductor device A10, since the distance d2′ is greater than the distance d, it is possible to design an insulation resistance voltage suitable for actual use between the wire 41 and the lead 31. Therefore, the semiconductor device A10 may ensure adequate dielectric strength between the wire 41 and the lead 31, thereby suppressing the occurrence of dielectric breakdown. In the design method of the semiconductor device A10, it is designed by the wire design step S102 that the distance d2′ is to be greater than the distance d0. This enables the design and manufacture of the semiconductor device A10 in which the occurrence of dielectric breakdowns is suppressed.

In the semiconductor device A10, the distance d4 between the wire(s) 41 and the wire(s) 42 is greater than the distance d0 determined by Formula (1). In this embodiment, the distance d4 is the distance in the direction perpendicular to the thickness direction z between the rise section 413a of the loop portion 413 of the wire 41 and the rise section 423a of the loop portion 423 of the wire 42. The wire 41 is electrically connected to the semiconductor element 14 and is therefore a component of the second circuit. On the other hand, the wire 42 is electrically connected to the semiconductor element 13 and is therefore a component of the first circuit. Since the wire 41 is a relatively high voltage and the wire 42 is a relatively low voltage, a potential difference is generated between the wire 41 and the wire 42. In the semiconductor device A10, since the distance d4 is greater than the distance d0, it is possible to design a insulation resistance voltage suitable for actual use between the wire 41 and the wire 42. Therefore, the semiconductor device A10 may ensure an appropriate dielectric strength between the wires 41 and 42, thereby suppressing the occurrence of dielectric breakdown. In the design method of the semiconductor device A10, it is designed by the wire design process S103 that the distance d4 is to be greater than the distance d0. This enables the design and manufacture of the semiconductor device A10 in which the occurrence of dielectric breakdowns is suppressed.

In the semiconductor device A10, as in the semiconductor device A1, in the semiconductor element 11, the potential of the lower winding 115b of the functional part 115 is approximately the same as the potential of the lead 31. Therefore, in the semiconductor device A10, as in the semiconductor device A1, the number of the insulation layers 1171 between the semiconductor substrate 110 and the lower winding 115b can be reduced, thereby preventing the thickness of the semiconductor element 11 from becoming unduly large.

In the semiconductor device A10, the lower winding 115b is electrically connected to the semiconductor element 13 by connecting the wire 42 to the pad 111, which is electrically connected to the lower winding 115b. The semiconductor element 13 is bonded to the lead 31. With this configuration, the lower winding 115b and the lead 31 are components of the first circuit including the semiconductor element 13. Hence, in the semiconductor device A10, the potential of the lower winding 115b can be approximately the same as that of the lead 31.

Other embodiments and variations of the semiconductor device according to the second aspect of the present disclosure are described below. The configurations of parts in these embodiments and variations may be combined with each other in various ways to the extent that no technical contradiction arises.

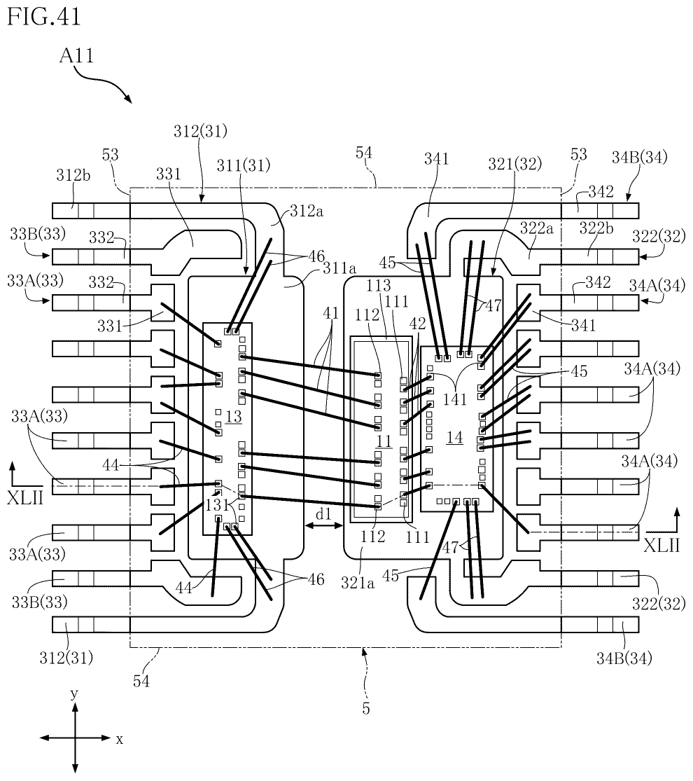

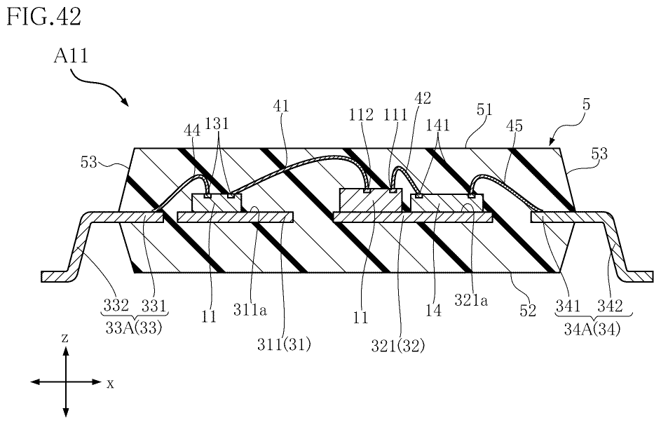

FIGS. 41-43 show a semiconductor device A11 according to a first variation of the first embodiment in the second aspect. The semiconductor device A11 described below is different from the semiconductor device A11 shown in FIG. 18, which is provided according to the first aspect of the present disclosure. The semiconductor device A11 of the second aspect may differ from the semiconductor device A10 of the second aspect in that the semiconductor device A11 has a semiconductor element 11 mounted on a lead 32 (island portion 321), not on a lead 31 (island portion 311).

In the semiconductor device A11, the semiconductor element 11 is electrically connected to the island portion 321 by a conductive bonding material 119, as shown in FIGS. 41-43. With this configuration, regarding the semiconductor element 11, the semiconductor substrate 110 and the seal ring portion 113 are at the same potential as the lead 32. Thus, the seal ring portion 113 is at the same potential as the second circuit.

In the semiconductor device A11, as shown in FIGS. 41-43, each wire 41 electrically connects the semiconductor element 11 to the semiconductor element 13. The joint portion 411 of each wire 41 is bonded to one of the pads 112 of the semiconductor element 11, and the joint portion 412 of each wire 41 is bonded to one of the pads 131 of the semiconductor element 13. In semiconductor device A11, as shown in FIGS. 41-43, each wire 42 electrically connects the semiconductor element 11 to the semiconductor element 14. The joint portion 421 of each wire 42 is bonded to one of the pads 111 of the semiconductor element 11, and the joint portion 422 of each wire 42 is bonded to one of the pads 141 of the semiconductor element 14. As shown in FIGS. 41-43, in the semiconductor device A11, in plan view, the pads 112 are closer to the semiconductor element 13 with respect to the pads 111, while the pads 111 are closer to the semiconductor element 14 with respect to the pads 112.

In the semiconductor device A11, the distance d2′ is the shortest distance in the thickness direction z where the wire 41 (loop portion 413) and the island portion 321 (mount surface 321a) of the lead 32 are closest to each other.

The manufacturing method of the semiconductor device A11 may be conducted in the same manner as that of the semiconductor device A10 in accordance with the flowchart for the semiconductor device A10 (see FIG. 33). It should be noted, however, that in the wire design step S102 by the manufacturing method of the semiconductor device A11, it is designed, for forming each wire 41, that the distance d2 in the thickness direction z between the wire 41 and the semiconductor element 11 is to be greater than the distance d0, and also that the distance d2′ in the thickness direction z between the wire 41 and the lead 812 is to be greater than the distance d0. The other processes (and specific steps) may be the same or similar.

In the semiconductor device A11, as in the semiconductor device A10, since the distance d2 is greater than the distance d0, it is possible to design an insulation resistance voltage suitable for actual use between the wire 41 and the seal ring portion 113. Therefore, in the semiconductor device A11, an appropriate dielectric strength may be ensured between the wire 41 and the seal ring portion 113 (semiconductor element 11), whereby the occurrence of dielectric breakdown may be suppressed. However, in the semiconductor device A11, unlike the semiconductor device A10, the semiconductor element 11 is bonded to the island portion 321 (lead 32), and the seal ring portion 113 is at the same potential as the island portion 321 and thus becomes a component of the second circuit. On the other hand, the wire 41 is electrically connected to the semiconductor element 13, it has the same potential as the semiconductor element 13 and becomes a component of the first circuit. The seal ring portion 113 is a relatively high voltage and the wire 41 is a relatively low voltage, and thus a potential difference is generated between the seal ring portion 113 and the wire 41. In the semiconductor device A11, the leads 32 and 31 are examples of the “first lead” and “second lead” described in Clause B1, respectively. The semiconductor elements 11 and 13 are examples of the “first semiconductor element” and “second semiconductor element” described in Clause B1, respectively. The wire 41 is an example of the “first wire” described in Clause B1, the pad 112 is an example of the “first pad” described in Clause B1, the seal ring portion 113 is an example of the “seal ring portion” described in Clause B1, and the distance d2 is an example of the “first distance” described in Clause B1.

The semiconductor device A11 may have configurations common to those of the semiconductor device A10, whereby it provides the same effects as the semiconductor device A10. For example, in the semiconductor device A11, as in the semiconductor device A10, the distance d2 is greater than the distance d0, and the distance d11 in the first direction x between the pad 112 and the seal ring portion 113 is 100 μm or more and 300 μm or less. Therefore, in the semiconductor device A11, like the semiconductor device A10, it is possible to make the rise of the wire 41 gentle, while making the distance d2 greater than the distance d0. Thus, when the wire 41 is a copper wire, it is possible to suppress the occurrence of wire cracks and damage to semiconductor element 11 while rendering the distance d2 greater than the distance d0.

As understood from the above variation, in the semiconductor device of the present disclosure, the semiconductor element 11 may be mounted on (bonded to) the lead 31 and electrically connected to the semiconductor element 14 by the wire 42, or the semiconductor element 11 may be mounted on (bonded to) the lead 32 and electrically connected to the semiconductor element 13 by the wire 41.

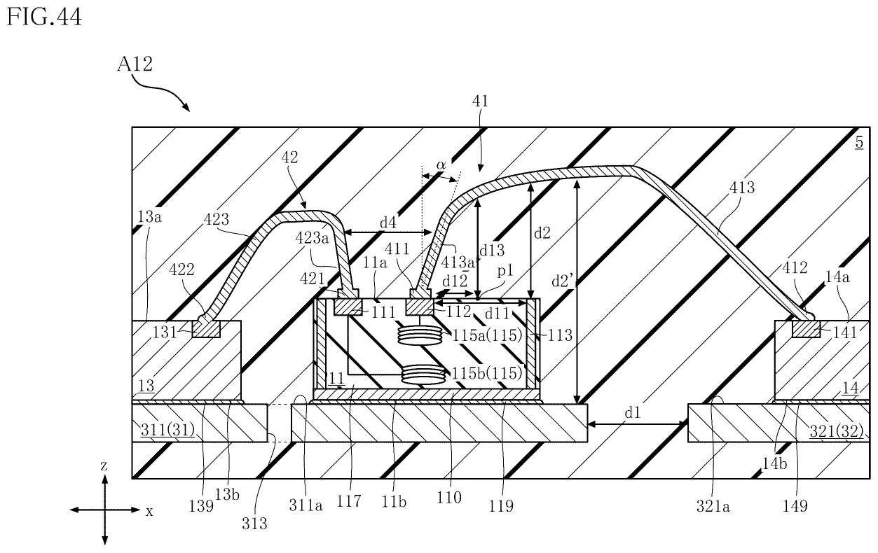

FIG. 44 shows a semiconductor device A12 according to a second variation of the first embodiment of the second aspect. The semiconductor device A12 of this variation described below is different from the semiconductor device A12 of the first aspect shown in FIG. 19. The semiconductor device A12 of this variation may differ from the semiconductor device A10 in that the rise section 413a of the loop portion 413 of each wire 41 is inclined with respect to the thickness direction z. Likewise, in the illustrated variation, the rise section 423a of the loop portion 423 of each wire 42 is inclined with respect to the thickness direction z. Alternatively, the rise section 423a of the wire 42 may not be inclined with respect to the thickness direction z.

In the semiconductor device A12, the rise section 413a of the loop portion 413 of each wire 41 is inclined at an inclination angle α with respect to the thickness direction z. The inclination angle α is, for example, not less than 80° and not more than 100°.

The semiconductor device A12 may have the configurations common to those of the semiconductor device A10, thereby producing the same effects as the semiconductor device A10. In the semiconductor device A12, the distance d4 can be made greater than in the semiconductor device A10, which is advantageous to further suppressing the occurrence of dielectric breakdown.

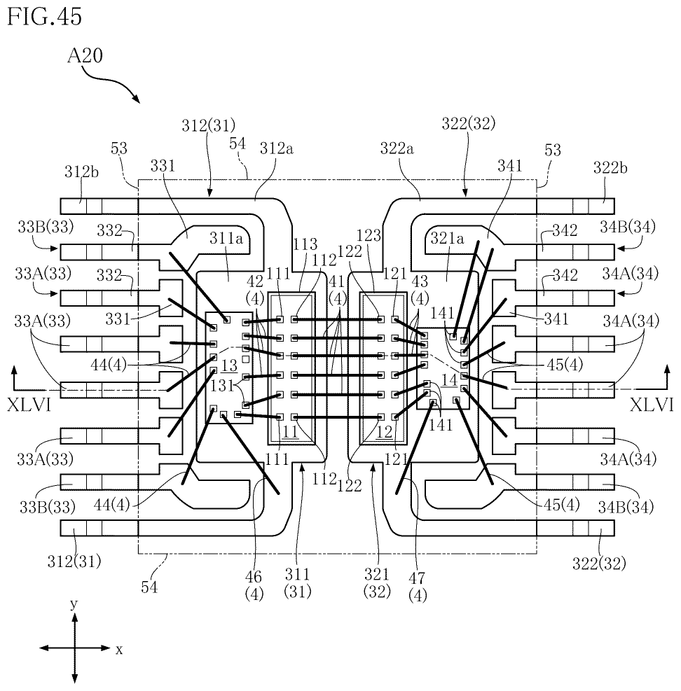

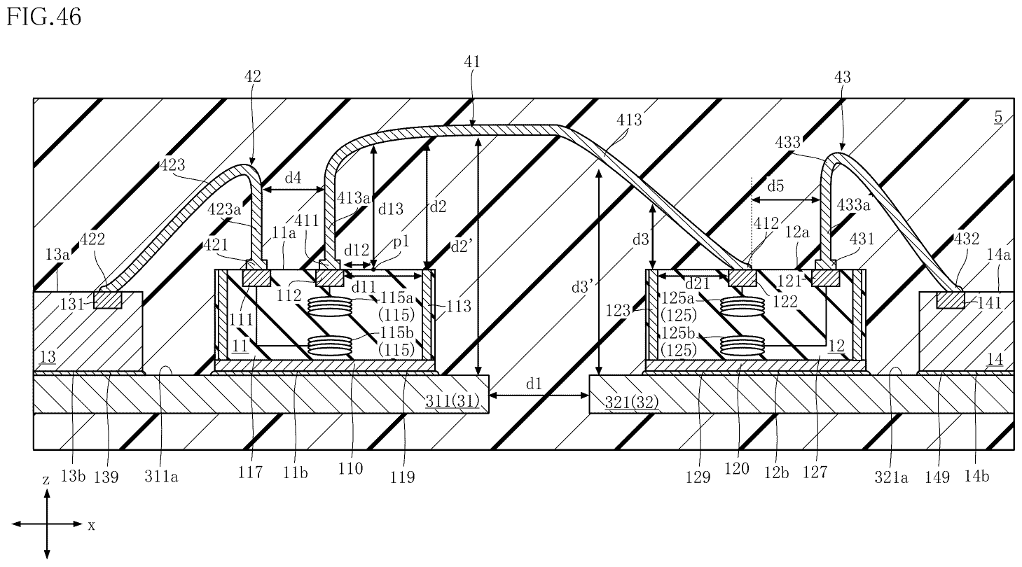

FIGS. 45-47 show a semiconductor device A20 according to a second embodiment of the second aspect. The semiconductor device A20 differs from the semiconductor device A10 in that the former further includes a semiconductor element 12. The plan view of the semiconductor device A20 shown in FIG. 45 is equivalent to the plan view of the semiconductor device A1 shown in FIG. 2. The cross-sectional view of the semiconductor device A20 shown in FIG. 46 corresponds to the cross-sectional view of the semiconductor device A1 shown in FIG. 7.

The semiconductor element 12, like the semiconductor element 11, is an element (insulating element) configured to transmit PWM control signals or other electrical signals in an insulated state. The semiconductor element 12 is rectangular in plan view, with longer sides or edges extending along the second direction y, though the present disclosure is not limited to this. The semiconductor element 12 is electrically connected to the semiconductor element 11 and to the semiconductor element 14. In the first direction x, the semiconductor element 12 is disposed between the semiconductor element 11 and the semiconductor element 14. In the semiconductor device A20, the first circuit including the semiconductor element 13 and the second circuit including the semiconductor element 14 are electrically isolated from each other by the semiconductor element 11 and the semiconductor element 12.

The semiconductor element 12, together with the semiconductor element 14, is mounted on the island portion 321 (lead 32). The semiconductor element 12 is bonded to the mount surface 321a of the island portion 321 via a conductive bonding material 129. Thus, the semiconductor substrate 120 of the semiconductor element 12 is at substantially the same potential as the island portion 321 via the conductive bonding material 129.

The semiconductor element 12 has an obverse surface 12a and a reverse surface 12b, as shown in FIG. 46.

The semiconductor element 12 includes a functional part 125. The functional part 125 is internally provided with a plurality of sets of upper windings 125a and lower windings 125b, where each set consists of one upper winding 125a and one lower winding 125b. Thus, the semiconductor element 12 includes more than one upper winding 125a and more than one lower winding 125b. FIG. 46 shows one set of the upper winding 125a and the lower winding 125b.

As shown in FIGS. 45-47, the semiconductor element 12 includes a plurality of pads 121 and 122. The pads 121 and 122 are provided on the obverse surface 12a. As shown in FIG. 46, each pad 121 is electrically connected to one of the lower windings 125b, and each pad 122 is electrically connected to one of the upper windings 125a. As shown in FIGS. 45 and 46, each pad 121 is connected with one of the wires 43, and each pad 122 is connected with one of the wires 41.

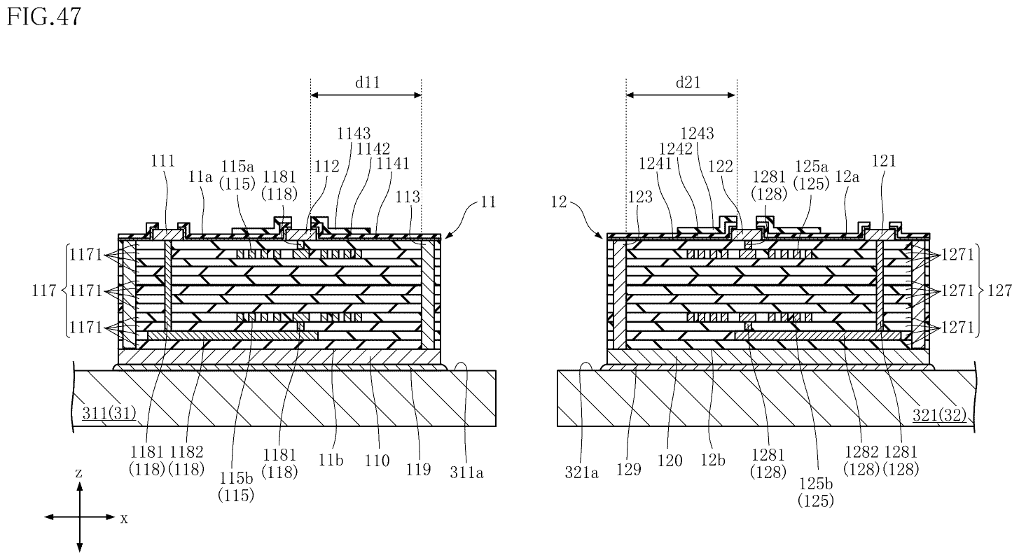

As shown in FIGS. 45-47, the semiconductor element 12 includes a seal ring portion 123. In this embodiment, as shown in FIGS. 46 and 47, the distance d21 between each pad 122 and the seal ring portion 123 in the first direction x (the direction in which the semiconductor element 11 is offset with respect to the semiconductor element 12) is, for example, not less than 100 μm and not more than 300 μm, though the present disclosure is not limited to this.

As shown in FIGS. 46 and 47, the semiconductor element 12 of the semiconductor device A20 includes a semiconductor substrate 120, a protection film 1241, a passivation film 1242, a coil protection film 1243, a stacking structure 127, and a distributing conductor 128.

The stacking structure 127 is formed on the semiconductor substrate 120. As shown in FIG. 47, the stacking structure 127 includes a plurality of insulation layers 1271. The insulation layers 1271 are stacked on the upper surface of the semiconductor substrate 120. The insulation layers 1271 include the lowest insulation layer 1271 held in contact with the upper surface of the semiconductor substrate 120. Except for the lowest insulation layer, each insulation layer has a laminated structure made up of a lower etching stopper film and an upper interlayer insulating film. The lowest insulation layer 1271 may consist only of an interlayer insulation layer. The thicknesses of the respective insulation layers 1271 may be the same or mutually different.

The upper winding 125a and the lower winding 125b are formed on different insulation layers 1271 in the stacking structure 127 and arranged to face each other through one or more insulation layers 1271. In the illustrated example, the lower winding 125b is formed on the fourth insulation layer 1271 from the semiconductor substrate 120, and the upper winding 125a is formed on the eleventh insulation layer 1271, whereby six insulation layers 1271 are sandwiched between the upper winding 125a and the lower winding 125b. The number of insulation layers 1271 is not limited to the example shown in the figure, but may be adjusted as appropriate, for example, depending on the voltage applied to the pads 121 and 122. In the present embodiment, due to the relationship between the dielectric strength of the semiconductor element 12 and the thickness (preferably reduced thickness) of the semiconductor element 12, it is desirable that the number of insulation layers 1271 between the upper winding 125a and the lower winding 125b be not less than four layers and not more than six layers. The dimension z in the thickness direction of the plurality of insulation layers 1271 between the upper winding 125a and the lower winding 125b (i.e., the distance of separation along the thickness direction z between the upper winding 125a and the lower winding 125b) is not limited, but is, for example, not less than 9.6 μm and not more than 14.4 μm. This example of dimension (not less than 9.6 μm and not more than 14.4 μm) may correspond to the case, for example, where the thickness of each insulation layer 1271 intervening between the upper winding 125a and the lower winding 125b is 2.4 μm, and the number of the intervening insulation layers 1271 is not less than four (4) and not more than six (6).

In this embodiment, the number of the insulation layers 1171 in the semiconductor element 11 is equal to the number of the insulation layers 1271 in the semiconductor element 12. Specifically, the lower winding 115b is formed on the fourth insulation layer 1171 from the semiconductor substrate 110, and the upper winding 115a is formed on the eleventh insulation layer 1171, with six insulation layers 1171 interposed between the lower winding 115b and the upper winding 115a. Thus, the number of the insulation layers 1171 between the upper winding 115a and the lower winding 115b in the semiconductor device A20 is less than the number of the insulation layers 1171 between the upper winding 115a and the lower winding 115b in the semiconductor device A10. In the present embodiment, in view of the relationship between the dielectric strength of the semiconductor element 11 and the thickness of the semiconductor element 11 (suppression of increase), it is desirable that the number of the insulation layers 1171 between the upper winding 115a and the lower winding 115b be not less than four and not more than six. The dimension z in the thickness direction of the insulation layers 1171 between the upper winding 115a and the lower winding 115b (i.e., the separation distance along the thickness direction z of the upper winding 115a and the lower winding 115b) is not limitative, but is, for example, not less than 9.6 μm and not more than 14.4 μm. This dimension example (not less than 9.6 μm and not more than 14.4 μm) corresponds to a case where the dimension z in the thickness direction of each insulation layer 1171 between the upper winding 115a and the lower winding 115b is 2.4 μm and the number of the insulation layers 1171 between the upper winding 115a and the lower winding 115b is not less than four (4) and not more than six (6).

The distributing conductor 128 includes a plurality of penetration wirings 1281 and a lead-out wiring 1282. In the example shown in FIG. 47, the penetration wirings 1281 include wirings for connecting the pads 121 to the lead-out wiring 1282, a wiring for connecting the lead-out wiring 1282 to the lower winding 125b, and wirings for connecting the pads 122 to the upper winding 125a.

The protection film 1241 is stacked on the stacking structure 127 as shown in FIG. 47. The passivation film 1242 is stacked on the protection film 1241 as shown in FIG. 47. The coil protection film 1243 is stacked on the passivation film 1242 as shown in FIG. 47, and arranged to selectively cover the region located directly above the upper winding 125a. As understood from FIG. 47, a number of pad openings are formed in the protection film 1241, the passivation film 1242 and the coil protection film 1243 for exposing the pads 121, 122. The protection film 1241 contains, for example, SiO₂ and has a thickness of about 150 nm. The passivation film 1242 contains, for example, SiN and has a thickness of about 1000 nm. The coil protection film 1243 contains, for example, polyimide and has a thickness of about 4000 nm. The constituent materials and thicknesses of the protection film 1241, the passivation film 1242 and the coil protection film 1243 are not limited to the above examples.

The structure of the semiconductor element 12 is not limited to the above example. For instance, the upper winding 125a and the lower winding 125b are not limited to being flatly wound on a single insulation layer 1271, but may be three-dimensionally wound on two or more insulation layers 1271. However, in order to suppress an increase in the thickness of the semiconductor element 12, it is preferable that the upper winding 125a and the lower winding 125b are each wound in a plane of a single insulation layer 1271.

In the semiconductor device A20, as shown in FIGS. 45 and 46, each of the wires 41 is bonded to one of the pads 112 of the semiconductor element 11 and also to one of the pads 122 of the semiconductor element 12. The joint portion 411 of each wire 41 is bonded to one of the pads 112 of the semiconductor element 11, while the other joint portion 412 of the wire 41 is bonded to one of the pads 122 of the semiconductor element 12.

In the semiconductor device A20, the connection members 4 include a plurality of wires 43. Each of the wires 43 is bonded to one of the pads 121 of the semiconductor element 12 and also to one of the pads 141 of the semiconductor element 14, as shown in FIGS. 45 and 46. The wires 43 electrically connect the semiconductor element 12 and the semiconductor element 14.

As shown in FIG. 46, the wires 43 each include two joint portions 431, 432 and a loop portion 433. In each wire 43, the joint portion 431 is bonded to one of the pads 121, and the other joint portion 432 is bonded to one of the pads 141. The loop portion 433 connects the two joint portions 431 and 432. The loop portion 433 rises from the joint portion 431 in the thickness direction z, and then curves to extend toward the joint portion 432. The loop portion 433 has a rise section 433a. The rise section 433a is a part of the loop portion 433 that is connected to the joint portion 431 and rises in the thickness direction z. Each wire 43 is formed, for example, by a ball bonding process, and is first-bonded to one of the pads 121 and second-bonded to one of the pads 141. Alternatively, each wire 43 may be formed by other methods such as wedge bonding. When each wire 43 is formed by wedge bonding, the shape of the joint portion 431 is substantially the same as that of the other joint portion 432.

The conductive support 3 of the semiconductor device A20 differs from the conductive support 3 of the semiconductor device A10 in the following. First, use is made of six leads 33 and six leads 34. Second, all the leads 34 are disposed between the two terminal portions 322 of the lead 32 in the second direction y. On the other hand, the shape, size and arrangement of the conductive support 3 of the semiconductor device A20 are not limited to the examples shown in the figures. For instance, the island portion 321 may be formed with through-holes penetrating in the thickness direction z, as in the island portion 311 of the semiconductor device A10. Such through-holes may be disposed, for example, between the semiconductor element 12 and the semiconductor element 14.

In the semiconductor device A20, the first circuit and the second circuit are electrically insulated by two intervening semiconductor elements 11 and 12 (two insulating elements), providing a third circuit whose potential is intermediate between the potential of the first circuit and the potential of the second circuit. As such, the semiconductor device A20 can be considered as including a third circuit, in addition to the first circuit and the second circuit. In this embodiment, the third circuit may be made up of some parts of the semiconductor element 11 (such as the upper windings 115a and the pads 112), some parts of the semiconductor element 12 (such as the upper windings 125a and the pads 122), and the wires 41. When the potential of the second circuit is higher than that of the first circuit, the potential of the third circuit is higher than that of the first circuit and lower than that of the second circuit. In this embodiment, supposing that the semiconductor elements 11 and 12 have the same configurations, the voltage difference between the first circuit and the second circuit is equally divided for insulation by the two semiconductor insulating elements. Thus, the potential of the third circuit corresponds to half the potential difference between the first circuit and the second circuit. Alternatively, it may be arranged that the potential of the third circuit is offset toward either the potential of the first circuit or the second circuit, with respect to half the potential difference between the first circuit and the second circuit.

In the semiconductor device A20, it is configured that the distance between any two constituents selected from a constituent of the first circuit, a constituent of the second circuit and a constituent of the third circuit is greater than the distance d0 [mm] determined by the following formula (1).

Specifically, the distance d1 in the first direction x between the leads 31 and 32 (see FIG. 46) is greater than the distance d0. In setting the distance d1, the difference between the voltage applied to the first circuit (lead 31) and the voltage applied to the second circuit (lead 32) may be used for the voltage X. In the example shown in FIG. 46, the distance d1 is the shortest distance between the two island portions 311 and 321 where they are closest to each other. The distance d1 is, for example, not more than 10 mm, which is advantageous to preventing the semiconductor device A20 from becoming unduly large. In the semiconductor device A20, the distance d1 is about 300 μm, which is greater than the distance d0 (29.4 μm).

The distance d2 (see FIG. 46) between each wire 41 and the semiconductor element 11 is greater than the distance d0. In the example shown in FIG. 46, the distance d2 is the shortest distance in the thickness direction z where the loop portion 413 and the seal ring portion 113 of the semiconductor element 11 are closest to each other. In this embodiment, the wire(s) 41 is a component of the third circuit, which has an intermediate potential between the first circuit and the second circuit. Thus, in setting the distance d2, the difference between the voltage applied to the third circuit (the wire 41) and the voltage applied to the first circuit (the seal ring portion 113 of the semiconductor element 11) may be used for the voltage X. As such, the voltage X for setting the distance d2 may be smaller than the voltage X for setting the distance d1. Alternatively, the voltage X for setting the distance d2 may be greater than the voltage difference between the third circuit and the first circuit. In this case, the voltage X for setting the distance d2 may be the same as the voltage X for setting the distance d1. The distance d2 is, for example, not more than 10 mm, which is advantageous to preventing the semiconductor device A20 from becoming unduly large. In the semiconductor device A20, the distance d2 is about 170 μm, which is greater than the distance d0 (29.4 μm).

The distance d2′ (see FIG. 46) between each wire 41 and the lead 31 is greater than the distance d0. In the example shown in FIG. 46, the distance d2′ is the shortest distance in the thickness direction z where the loop portion 413 and the mount surface 311a of the island portion 311 are closest to each other. The voltage X used for setting the distance d2′ may be the same as that for setting the distance d2, which is the difference between the voltage applied to the third circuit (each wire 41) and the voltage applied to the first circuit (lead 31). Alternatively, the voltage X for setting the distance d2′ may be greater than the voltage difference between the third circuit and the first circuit. For example, it may be the same as the voltage X used for setting the distance d1. The distance d2′ is, for example, not more than 10 mm, which is advantageous to preventing the semiconductor device A20 from becoming unduly large. In the semiconductor device A20, the distance d2′ is about 470 μm, which is greater than the distance d0 (29.4 μm).

The distance d3 (see FIG. 46) between each wire 41 and the semiconductor element 12 is greater than the distance d0. In the example shown in FIG. 46, the distance d3 is the shortest distance in the thickness direction z where each loop portion 413 and the seal ring portion 123 of the semiconductor element 12 are closest to each other. In this embodiment, since the wire(s) 41 is a component of the third circuit, which is at an intermediate potential between the first circuit and the second circuit, the voltage X used for setting the distance d3 is the difference between the voltage applied to the third circuit (each wire 41) and the voltage applied to the second circuit (the seal ring portion 123 of the semiconductor element 12). As such, the voltage X for setting the distance d3 may be smaller than the voltage X for setting the distance d1. Alternatively, the voltage X for setting the distance d3 may be greater than the voltage difference between the third circuit and the second circuit. For example, it may be the same as the voltage X for setting the distance d1. The distance d3 is, for example, not more than 10 mm, which is advantageous to preventing the semiconductor device A20 from becoming unduly large. In the semiconductor device A20, the distance d3 is about 170 μm, which is greater than the distance d0 (29.4 μm).

The distance d3′ (see FIG. 46) between each wire 41 and the lead 32 is greater than the distance d0. In the example shown in FIG. 46, the distance d3′ is the shortest distance in the thickness direction z where each loop portion 413 and the island portion 321 are closest to each other. The voltage X used for setting the distance d3′ is, as in setting the distance d3, the difference between the voltage applied to the third circuit (each wire 41) and the voltage applied to the second circuit (lead 32). Alternatively, the voltage X used for setting the distance d3′ may be greater than the voltage difference between the third circuit and the second circuit. For example, it may be the same as the voltage X used for setting the distance d1. The distance d3′ is, for example, not more than 10 mm, which is advantageous to preventing the semiconductor device A20 becoming unduly large. In the semiconductor device A20, the distance d3′ is about 470 μm, which is greater than the distance d0 (29.4 μm).

The distance d4 between the wire(s) 41 and the wire(s) 42 (see FIG. 46) is greater than the distance d0. In the example shown in FIG. 46, the distance d4 is the shortest distance in the direction perpendicular to the thickness direction z (the first direction x in FIG. 7) where the rise section 413a of the loop portion 413 of the wire 41 and the rise section 423a of the loop portion 423 of the wire 42 are closest to each other. In this embodiment, the wire 41 is a component of the third circuit, which has an intermediate potential between the first circuit and the second circuit. Hence, the voltage X used for setting the distance d4 is the difference between the voltage applied to the third circuit (each wire 41) and the voltage applied to the first circuit (each wire 42). As such, the voltage X used for setting the distance d4 may be smaller than the voltage X used for setting the distance d1. Alternatively, the voltage X for setting the distance d4 may be greater than the voltage difference between the third circuit and the first circuit. For example, it may be the same as the voltage X for setting the distance d1. In the semiconductor device A20, the distance d4 is about 300 μm, which is greater than the distance d0 (29.4 μm).

The distance d5 between the wire(s) 41 and the wire(s) 43 (see FIG. 46) is greater than the distance d0. In the example shown in FIG. 46, the distance d5 is the shortest distance in the direction perpendicular to the thickness direction z (the first direction x in FIG. 46) where the joint portion 412 of the wire 41 and the rise section 433 of the loop portion 433 of the wire 43 are closest to each other. In this embodiment, the wire(s) 41 is a component of the third circuit, which has an intermediate potential between the first circuit and the second circuit. Thus, the voltage X used for setting the distance d5 is, for example, the difference between the voltage applied to the third circuit (each wire 41) and the voltage applied to the second circuit (each wire 43). As such, the voltage X used for setting the distance d5 may be smaller than the voltage X used for setting the distance d1. Alternatively, the voltage X for setting the distance d5 may be greater than the voltage difference between the third circuit and the second circuit. For example, it may be the same as the voltage X for setting the distance d1. In the semiconductor device A20, the distance d5 is about 300 μm, which is greater than the distance d0 (29.4 μm).

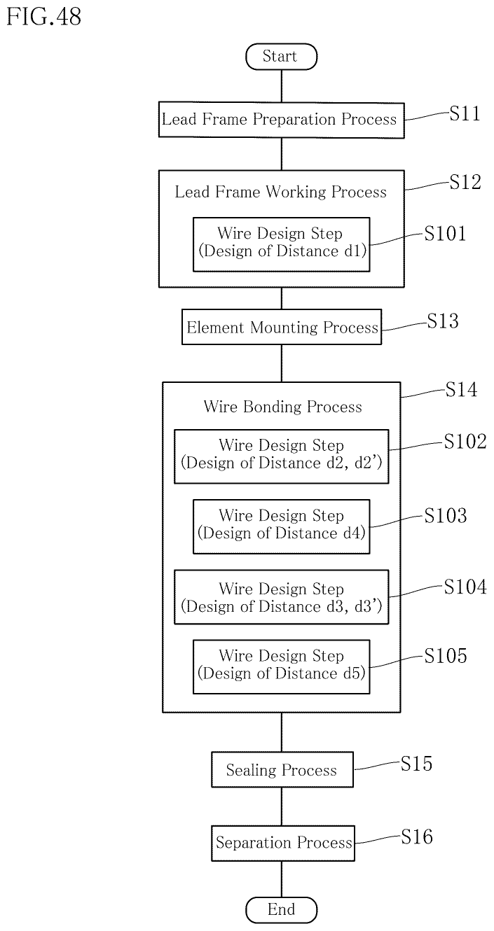

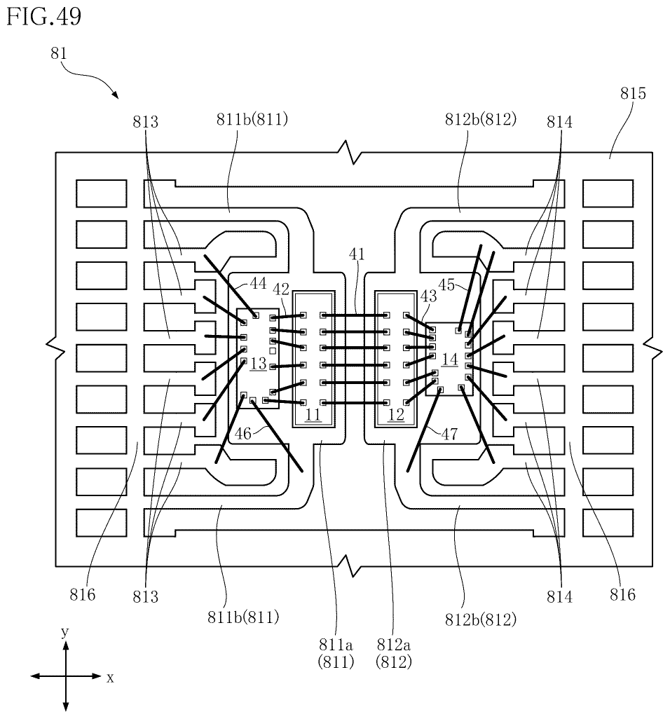

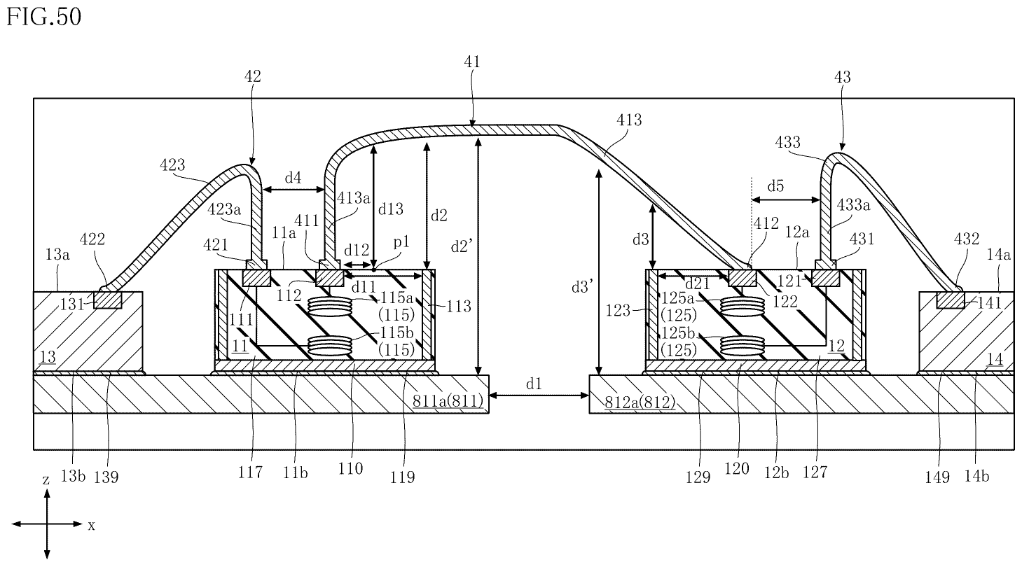

Next, an example of a method of manufacturing the semiconductor device A20 will be described with reference to FIGS. 48 to 50. FIG. 48 is a flowchart showing an example of the method for manufacturing the semiconductor device A20. FIG. 49 is a plan view illustrating a process of the method for manufacturing a semiconductor device A20. FIG. 50 is a cross-sectional view illustrating a process of the method for manufacturing a semiconductor device A20. The cross-section in FIG. 50 corresponds to the cross-section in FIG. 46.

As shown in FIG. 48, the manufacturing method of the semiconductor device A20 of the present embodiment includes a lead frame preparation process S11, a lead frame working process S12, an element mounting process S13, a wire bonding process S14, a sealing process S15, and a separation process S16, which are the same as those in the manufacturing method of the semiconductor device A10 (see FIG. 33). The manufacturing method of the semiconductor device A20 may differ from that of the semiconductor device A10 in the following. First, the element mounting process S13 additionally includes the semiconductor elements 12. Second, in the wire bonding process S14, wire design steps S104 and S105 may be performed in addition to the wire design steps S102 and S103. Thus, the design steps used in the manufacturing method of the semiconductor device A20 may further include the wire design step S104 and the wire design step S105. Except for the above two steps, the manufacturing method of the semiconductor device A20 is the same as the manufacturing method of the semiconductor device A10 (see FIG. 33).

In the element mounting process S13, the semiconductor element 12 is prepared together with the semiconductor elements 11, 13, 14, and then as shown in FIGS. 49-50, the semiconductor elements 11 and 13 are bonded to the island 811a, and the semiconductor elements 12 and 14 are bonded to the other island 812a. The semiconductor element 12 to be prepared has a distance d21 (see FIG. 50) along the first direction x between each pad 122 and the seal ring portion 123, which is not less than 100 μm and not more than 300 μm.

In the wire design step S104, for forming each wire 41, as shown in FIG. 50, it is designed that the distance d3 in the thickness direction z between each wire 41 and the semiconductor element 12 is to be greater than the distance d0, and that the distance d3′ in the thickness direction z between each wire 41 and the lead 812 is to be greater than the distance d0. To this end, in bonding each wire 41, it is arranged that the loop portion 413 of each wire 41 is spaced apart from the seal ring portion 123 of the semiconductor element 12 by more than the distance d0, and also that the same loop portion 413 is spaced apart from the island 812a by more than the distance d0. Since the lead 812 is to be the lead 32, it is designed, in the wire design step S104, that the distance d3′ between each wire 41 and the lead 32 in the thickness direction z is to be greater than the distance d0. In the wire design step S104, the distance d2 may be designed to be greater than the distance d0 and not more than 10 mm, for example, which is advantageous to preventing the semiconductor device A20 from becoming unduly large. Likewise, in the wire design step S104, the distance d3′ may be designed to be greater than the distance d0 and not more than 10 mm, for example, which is advantageous to preventing the semiconductor device A20 from becoming unduly large.

In the wire design step S105, in forming the wire(s) 41 and the wire(s) 43, it is designed that the distance d5 between the wire 41 and the wire 43 is to be greater than the distance d0, as shown in FIG. 50. For example, when the wire 41 is bonded before the wire 43, the bonding of the wire 43 is performed such that the rise section 433a of the loop portion 433 of the wire 43 is to be spaced apart from the joint portion 412 of the wire 41 by more than the distance d0. Conversely, when the wire 43 is bonded before the wire 41, the bonding of the wire 41 is performed such that the joint portion 412 of the wire 41 is to be spaced apart from the rise section 433a of the loop portion 433 of the wire 43 by more than the distance d0. In the wire design step S105, it may be designed that the distance d5 is to be greater than the distance d0 and not more than 10 mm, for example, which is advantageous to preventing the semiconductor device A20 from becoming unduly large.

The workings and advantages of the semiconductor device A20, the design method of the semiconductor device A20 and the manufacturing method of the semiconductor device A20 are as follows.

In the semiconductor device A20, the distance d2 is greater than the distance d0 determined by formula (1). The distance d2 is the distance in the thickness direction z between the loop portion 413 of the wire 41 and the seal ring portion 113 of the semiconductor element 11. The potential of the first circuit is the potential at the seal ring portion 113, and the potential of the third circuit, which is the intermediate potential between the first circuit and the second circuit, is the potential at the wire 41. As such, the seal ring portion 113 becomes a relatively low voltage and the wire 41 becomes a relatively high voltage, whereby a potential difference is generated between the seal ring portion 113 and the wire 41. In the semiconductor device A20, by making the distance d2 greater than the distance d0, it is possible to design an insulation resistance voltage suitable for actual use between the seal ring portion 113 and the wire 41. Therefore, the semiconductor device A20, like the semiconductor device A10, can ensure an appropriate dielectric strength between the seal ring portion 113 and the wire 41, thereby suppressing the occurrence of dielectric breakdown. In the design method of the semiconductor device A20, the wire design step S102 is performed such that the distance d2 is designed to be greater than the distance d0. This enables the design and manufacture of the semiconductor device A20 in which the occurrence of dielectric breakdown is suppressed. In the semiconductor device A20, the leads 31 and 32 are examples of the “first lead” and “second lead” described in Clause B, respectively. The semiconductor elements 11 and 12 are examples of the “first semiconductor element” and “second semiconductor element” described in Clause B, respectively. The wire 41 is an example of the “first wire” described in Clause B, the pad 112 is an example of the “first pad” described in Clause B, the seal ring portion 113 is an example of the “seal ring portion” described in Clause B, and the distance d2 is an example of the “first distance” described in Clause B.

In the semiconductor device A20, as in the semiconductor device A10, the distance d2 is greater than the distance d0, and the distance d11 in the first direction x between the pad 112 and the seal ring portion 113 is not less than 100 μm and not more than 300 μm. Therefore, the semiconductor device A20, like semiconductor device A10, can render the rise of wire 41 gentle while rendering the distance d2 greater than the distance d0. Therefore, when the wire 41 is a copper wire, it is possible to suppress the occurrence of wire cracks and damage to the semiconductor element 11 while rendering the distance d2 greater than the distance d0. In this semiconductor device A20, the distance d11 is an example of the “second distance” described in Clause B.

In the semiconductor device A20, the distance d21 in the first direction x between the pad 122 and the seal ring portion 123 is not less than 100 μm and not more than 300 μm. AS the distance d21 becomes greater, the distance d3 tends to be greater than the distance d0, thereby ensuring an appropriate dielectric strength between the wire 41 and the seal ring portion 123. On the other hand, if the distance d21 is too large, the dimension of the semiconductor element 12 in the first direction x increases, resulting in a larger semiconductor device A20. As seen from this, the distance d21 being not less than 100 μm and not more than 300 μm is advantageous to suppressing the occurrence of dielectric breakdown while also preventing the semiconductor device A20 from becoming unduly large.

In the semiconductor device A20, the semiconductor elements 13 and 14 are electrically insulated by the semiconductor elements 11 and 12. In the other configuration of the semiconductor device A10, the semiconductor elements 13 and 14 are electrically insulated by a single semiconductor element 11 (insulating element), whereby the voltage difference between the first circuit and the second circuit is applied on the single insulating element (semiconductor element 11). In contrast, with the semiconductor device A20, the voltage difference between the first circuit and the second circuit is shared by the two insulating elements (the semiconductor elements 11, 12). Thus, the voltage difference generated in each semiconductor element 11, 12 can be reduced. Accordingly, the semiconductor device A20 can have more improved dielectric strength between the lead 31 (island portion 311) and the semiconductor element 11, compared to the semiconductor device A10. Likewise, the dielectric strength between the lead 32 (island portion 321) and the semiconductor element 12 can also be improved.

Since the voltage difference generated in the semiconductor element 11 is relatively small, the number of the insulation layers 1171 needed between the upper winding 115a and the lower winding 115b can be reduced. This makes it possible to reduce the thickness (dimension in the thickness direction z) of the semiconductor element 11, thereby achieving a thinner semiconductor device A20. Similarly, since the voltage difference generated in the semiconductor element 12 is relatively small, the number of insulation layers 1271 needed between the upper winding 125a and the lower winding 125b can be reduced. This also makes it possible to reduce the thickness (dimension in the thickness direction z) of the semiconductor element 12, thereby thinning the semiconductor device A20. As such, the semiconductor device A20 can be made thinner than the semiconductor device A10 while maintaining the same dielectric strength. Even when a thickness limitation is incurred on the semiconductor device A20 due to e.g., product specifications or other requirements, the dielectric strength of the semiconductor device A20 can be relatively great within the thickness limitation of the semiconductor device A20 as compared to the semiconductor device A10. This may be attributable to the fact that the first circuit and the second circuit can be insulated from each other by the insulation layers 1171 between the upper winding 115a and the lower winding 115b of the semiconductor element 11 as well as by the insulation layers 1271 between the upper winding 125a and the lower winding 125b of the semiconductor element 12. In other words, when the first circuit and the second circuit are insulated by the two semiconductor elements 11, 12, the number of insulation layers disposed between the first circuit and the second circuit can be increased compared to when they are insulated by a single insulating element (semiconductor element 11).

In the semiconductor device A20, as in the semiconductor device A1, the distance d3 between each wire 41 and the semiconductor element 12 is greater than the distance d0 determined by Formula (1). Therefore, the semiconductor device A20, as in the semiconductor device A1, may ensure an appropriate dielectric strength between each wire 41 and the semiconductor element 12, thereby suppressing the occurrence of dielectric breakdown. In the design method of the semiconductor device A20, the distance d3 is designed to be greater than the distance d0 by the wire design step S104, which is advantageous to enabling the design and manufacture of the semiconductor device A20 in which the occurrence of dielectric breakdown is suppressed.

In the semiconductor device A20, as in the semiconductor device A1, the distance d3′ between each wire 41 and the lead 32 is greater than the distance d0 determined by Formula (1). Therefore, the semiconductor device A20, as in the semiconductor device A1, may ensure an appropriate dielectric strength between the wires 41 and leads 32, thereby suppressing the occurrence of dielectric breakdown. In the design method of the semiconductor device A20, the distance d3′ is designed to be greater than the distance d0 by the wire design step S104. This enables the design and manufacture of the semiconductor device A20 in which the occurrence of dielectric breakdown is suppressed.

In the semiconductor device A20, the distance d5 between the wire(s) 41 and the wire(s) 43 is greater than the distance d0 determined by Formula (1). In this embodiment, the distance d5 is the distance in a direction perpendicular to the thickness direction z between the joint portion 412 of the wire 41 and the rise section 433a of the loop portion 433 of the wire 43. The wire 41 is a component of the third circuit as it is electrically connected to the upper winding 125a of the semiconductor element 12 (functional part 125). On the other hand, the wire 43 is a component of the second circuit as it is electrically connected to the lower winding 125b of the semiconductor element 12 (functional part 125). Thus, the wire 41 has a relatively low voltage and the wire 43 has a relatively high voltage, whereby a potential difference is generated between the wire 41 and the wire 43. In the semiconductor device A20, since the distance d5 is greater than distance d0, it is possible to design an insulation resistance voltage suitable for actual use between the wire 41 and the wire 43. Accordingly, the semiconductor device A20 may ensure an appropriate dielectric strength between the wire 41 and the wire 43, thereby suppressing the occurrence of dielectric breakdown. In the design method of the semiconductor device A20, the distance d5 is designed to be greater than the distance d0 by the wire design step S105, which is advantageous to enabling the design and manufacture of the semiconductor device A20 in which the occurrence of dielectric breakdown is suppressed.

As in the semiconductor device A1, in the semiconductor element 12 of the semiconductor device A20, the potential of the lower winding 125b of the functional part 125 is approximately the same as the potential of the lead 32. Thus, with the semiconductor device A20, the number of the insulation layers 1271 needed between the semiconductor substrate 120 and the lower winding 125b can be reduced, thereby preventing the thickness of the semiconductor element 12 from becoming unduly large.

In the semiconductor device A20, the lower winding 125b is electrically connected to the semiconductor element 14 by connecting the wire(s) 43 to the pad(s) 121, which is electrically connected to the lower winding 125b. The semiconductor element 14 is bonded to the lead 32.

With this configuration, the lower winding 125b and the lead 32 are components of a second circuit including the semiconductor element 14. Thus, in the semiconductor device A20, the potential of the lower winding 125b is approximately the same as the potential of the lead 32.

Further, the semiconductor device A20 can achieve the same effects as those of the semiconductor device A10 by having configurations common to those of the semiconductor device A10. As understood from the example of the semiconductor device A20, the semiconductor device of the present disclosure is not limited to a configuration in which the first circuit and the second circuit are insulated by a single insulating element (semiconductor element 11), but may have a configuration in which the two circuits are insulated by using two intervening insulating elements (semiconductor elements 11 and 12).

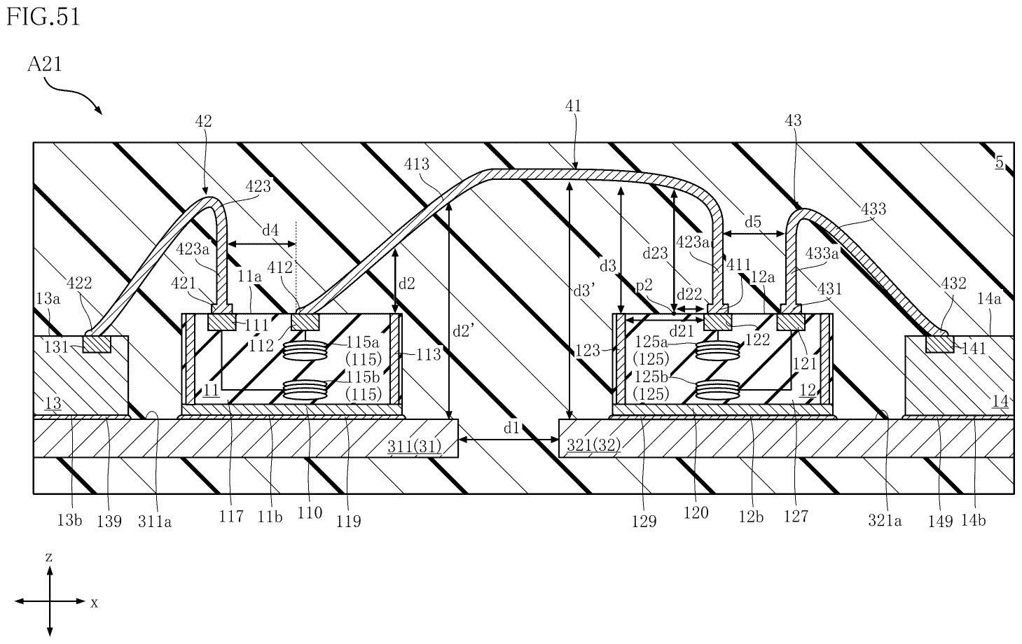

FIG. 51 shows a semiconductor device A21 according to a variation of the second embodiment of the second aspect. The semiconductor device A21 may differ from the semiconductor device A20 in that the wire(s) 41 is first-bonded to the pad(s) 122 of the semiconductor element 12 and second-bonded to the pad(s) 112 of the semiconductor element 11.

As shown in FIG. 51, in the semiconductor device A21, the joint portion 411 of the wire(s) 41 is bonded to the pad(s) 122 of the semiconductor element 12. Thus, in the semiconductor device A21, the distance d5 is the distance in a direction perpendicular to the thickness direction z between the rise section 413a of the loop portion 413 of the wire 41 and the rise section 433a of the loop portion 433 of the wire 43. The joint portion 412 of the wire(s) 41 is bonded to the pad(s) 112 of the semiconductor element 11. Thus, in the semiconductor device A21, the distance d4 is the distance in a direction perpendicular to the thickness direction z between the joint portion 412 of the wire 41 and the rise section 423a of the loop portion 423 of the wire 42.

In the semiconductor device A21, the semiconductor element 12 has points p2 (see FIG. 51) corresponding to the respective pads 122. Each point p2 is located between the corresponding pad 122 and the seal ring portion 123 in the first direction x. The distance d22 (see FIG. 51) between the point p2 and the pad 122 corresponding to that point p2 is, for example, not less than 50 μm and not more than 150 μm. As such, the semiconductor element 12 has points p2 on the obverse surface 12a at a distance d22 in the first direction x from the pads 122 toward the seal ring portion 123. The distance d23 in the thickness direction z between the point(s) p2 and the wire 41 (loop portion 413) (see FIG. 51) is not less than 85% and not more than 95% of the distance d3. In other words, the obverse surface 12a of the semiconductor element 12 has a point(s) p2 where the distance d23 in the thickness direction z between the wire 41 (loop portion 413) and the obverse surface 12a is not less than 85% and not more than 95% of the distance d3, and the distance d22 in the first direction x between the point p2 and the pad 122 is not less than 50 μm and not more than 150 μm. The distance d22 and the ratio of the distance d22 to the distance d3 are not limited to the above examples.

In the semiconductor device A21, the distance d3 between the wire(s) 41 and the semiconductor element 12 is greater than the distance d0 determined by Formula (1). As mentioned above, the wire 41 is at an intermediate potential between the first circuit and the second circuit. On the other hand, since the semiconductor element 12 is bonded to the island portion 321 (lead 32), the seal ring portion 123 may be at the same potential as the island portion 321. As such, the wire 41 is a relatively low voltage and the seal ring portion 123 is a relatively high voltage, whereby a potential difference is generated between the wire 41 and the seal ring portion 123. In the semiconductor device A21, the distance d3 is greater than the distance d0, it is possible to design an insulation resistance voltage suitable for actual use between the wire 41 and the seal ring portion 123. Thus, the semiconductor device A21 can ensure an appropriate dielectric strength between the wire 41 and the semiconductor element 12, thereby suppressing the occurrence of dielectric breakdown. In the design method of the semiconductor device A21, the wire design step S104 is performed such that the distance d3 is to be greater than the distance d0. This enables the design and manufacture of the semiconductor device A21 in which the occurrence of dielectric breakdown is suppressed. In the semiconductor device A21, the leads 32 and 31 are examples of the “first lead” and “second lead” described in Clause B, respectively. The semiconductor elements 12 and 11 are examples of the “first semiconductor element” and “second semiconductor element” described in Clause B, respectively. The wire 41 is an example of the “first wire” described in Clause B. The pad 122 is an example of the “first pad” described in Clause B. The seal ring portion 123 is an example of the “seal ring portion” described in Clause B. The distance d3 is an example of the “first distance” described in Clause B.

In the semiconductor device A21, the distance d3 is greater than the distance d0, and the distance d21 in the first direction x between the pad 122 and the seal ring portion 123 is not less than 100 μm and not more than 300 μm. The wire 41 is a copper wire (containing copper). With this configuration, the distance d3 can be made greater than the distance d0 while making the rising of the wire 41 gentle. Therefore, when the wire 41 is a copper wire, the semiconductor device A21 can suppress the occurrence of wire cracks and damage to the semiconductor element 12 while making the distance d2 greater than the distance d0. In this semiconductor device A21, the distance d21 is an example of the “second distance” described in Clause B.

In the semiconductor device A21, the distance d11 in the first direction x between the pad 112 and the seal ring portion 113 is not less than 100 μm and not more than 300 μm. As the distance d11 becomes greater, the distance d2 tends to become greater than the distance d0, thereby ensuring an appropriate dielectric strength between the wire 41 and the seal ring portion 113. On the other hand, if the distance d11 is too large, the dimension of the semiconductor element 11 in the first direction x becomes unduly large, resulting in a larger semiconductor device A21. As seen from this, the distance d11 being not less than 100 μm and not more than 300 μm is advantageous to suppressing the occurrence of dielectric breakdown while also preventing the semiconductor device A21 from becoming unduly large.

In the semiconductor device A21, the distance d22 is not less than 50 μm and not more than 150 μm. The distance d22 is the separation distance between each pad 122 and the point p2 corresponding to this pad 122 (see FIG. 51), where the point p2 is a point in the obverse surface 12a at which the distance d23 in the thickness direction z between this point and the wire 41 is in a range of not less than 85% and not more than 95% of the distance d3. With this configuration, it is easy to make the distance d3 greater than the distance d0. As such, it is desirable that the distance d22 be 50 μm or more and 150 μm or less in order to secure an appropriate dielectric strength and suppress the occurrence of dielectric breakdown. In the semiconductor device A21, the point p2 is an example of the “point” described in Clause B, the distance d22 is an example of the “third distance” described in Clause B, and the distance d23 is an example of the “fourth distance” described in Clause B.

Further, the semiconductor device A21 can achieve the same effects as the semiconductor device A20 by being provided with configurations common to those of the semiconductor device A20. As understood from the semiconductor device A21, in a semiconductor device of the present disclosure, the bonding targets of the first bonding and/or second bonding of each wire 41 are not limitative.

Differing from the semiconductor device A21 shown in FIG. 51, the first bonding and the second bonding may be performed the other way around regarding the respective wires 42, 43 as with the wires 41. That is, in the semiconductor device of the present disclosure, the bonding targets of the first bonding and the second bonding of the wires 42, 43 are not limitative.

In the second embodiment (including the variations), two semiconductor elements 13 and 14 are insulated by two insulating elements (two semiconductor elements 11 and 12), though the present disclosure is not limited to this, and use may be made of three or more insulating elements for desired insulation.

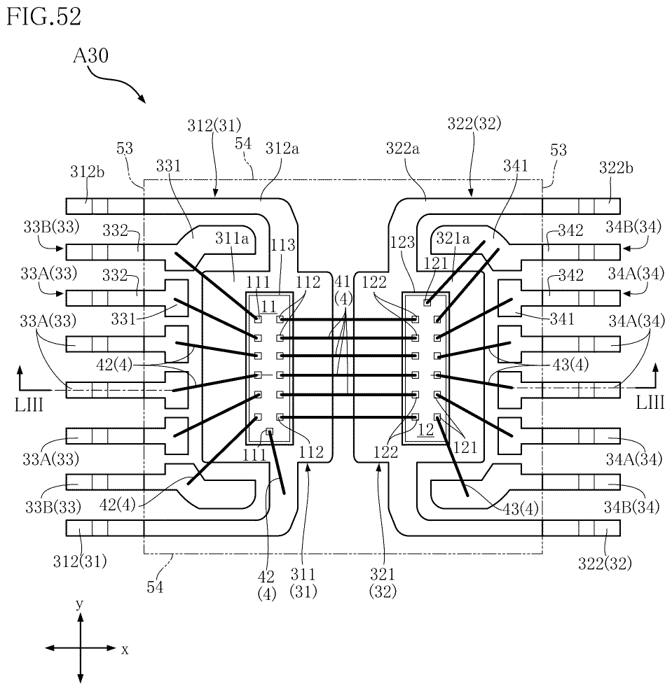

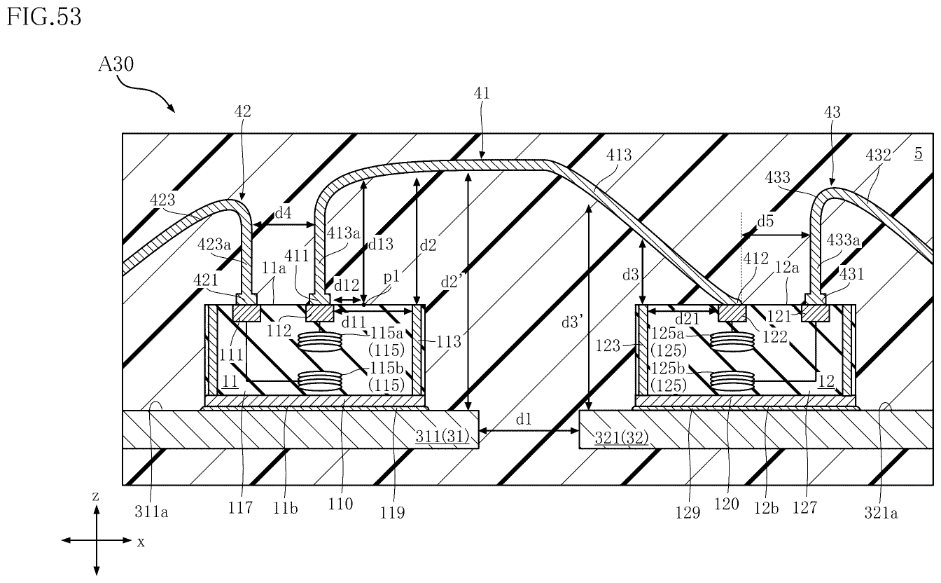

FIGS. 52 and 53 show a semiconductor device A30 according to a third embodiment of the second aspect. The semiconductor device A30 may differ from the semiconductor device A20 in that the semiconductor device A30 does not include semiconductor elements 13 and 14. The connection arrangement of the wires 42 and 43 is not limited to the example shown in FIG. 52, but may be varied as appropriate depending on the configurations of the semiconductor elements 11 and 12.

In the semiconductor device A30, each wire 42 is bonded to one of the pads 111 and also to one of the two terminal portions 312 (covered portion 312a) of the lead 31 or one of the leads 33 for electrical connection thereof. As such, the wires 42 electrically connect the semiconductor element 11 to the lead 31 or to the leads 33.

In the semiconductor device A30, each wire 43 is bonded to one of the pads 121 and also to one of the two terminal portions 322 (covered portion 322a) of the lead 32 or one of the leads 34 for electrical connection thereof. As such, the wires 43 electrically connect the semiconductor element 12 to the lead 32 or to the leads 34.

As an example, the semiconductor device A30 may be mounted on a wiring board, and the semiconductor element 13 is also arranged on the same wiring board, where the semiconductor element 13 may be electrically connected to the semiconductor element 11 via the wiring board and the leads 33. The lead 31 may be electrically connected to the ground of the first circuit including the semiconductor element 13 via the wiring board. Likewise, the semiconductor element 14 may be arranged on the above wiring board, whereby the semiconductor element 14 may be electrically connected to the semiconductor element 12 via the wiring board and the leads 34. The lead 32 may be electrically connected to the ground of the second circuit including the semiconductor element 14 via the wiring board. In this configuration, the semiconductor device A30 (semiconductor elements 11 and 12) may be used to insulate the first circuit (the circuit including the semiconductor element 13) from the second circuit (the circuit including the semiconductor element 14).

The manufacturing method of the above described semiconductor device A30 may be substantially the same as that of the semiconductor device A20 (see FIG. 48), except for the following. First, the element mounting process S13 does not include a process for mounting the semiconductor elements 13 and 14. Second, the wire bonding process S14 does not include a process for providing/forming the wires 44-47.

The workings and advantages of the semiconductor device A30 of the second aspect, the design method of the semiconductor device A30 and the manufacturing method of the semiconductor device A30 are as follows.

In the semiconductor device A30, as in the semiconductor device A20, the distance d2 is greater than distance d0, and it is possible to design an insulation resistance voltage suitable for actual use between the wires 41 and the seal ring portion 113. Therefore, the semiconductor device A30 may ensure an appropriate dielectric strength between the wires 41 and the seal ring portion 113 (semiconductor element 11), whereby the occurrence of dielectric breakdown may be suppressed. In the design method of the semiconductor device A30, as in the design method of the semiconductor device A20, the distance d2 is designed to be greater than the distance d0 by the wire design step S102. This makes it possible to design and manufacture the semiconductor device A30 in which the occurrence of dielectric breakdown is suppressed. In the semiconductor device A30, the leads 31 and 32 are examples of the “first lead” and “second lead” described in Clause B, respectively. The semiconductor elements 11 and 12 are examples of the “first semiconductor element” and “second semiconductor element” described in Clause B, respectively. The wire(s) 41 is an example of the “first wire” described in Clause B, the pad(s) 112 is an example of the “first pad” described in Clause B, the seal ring portion 113 is an example of the “seal ring portion” described in Clause B, and the distance d2 is an example of the “first distance” described in Clause B.

In the semiconductor device A30, as in the semiconductor devices A10, A20, the distance d2 is greater than the distance d0, and the distance d11 in the first direction x between the pad(s) 112 and the seal ring portion 113 is not less than 100 μm and not more than 300 μm. Thus, the semiconductor device A30, like the semiconductor devices A10, A20, can make the rising of the wire 41 gentle while making distance d2 greater than the distance d0. As such, when the wire 41 is a copper wire, it is possible to suppress the occurrence of wire cracks and damage to the semiconductor element 11 while making distance d2 greater than the distance d0.

In the semiconductor device A30, as in the semiconductor device A20, the distance d21 is not less than 100 μm and not more than 300 μm, which is advantageous to suppressing the occurrence of dielectric breakdown while preventing the semiconductor device A30 from becoming unduly large.

Further, the semiconductor device A30 (and the design method and the manufacturing method) may have configurations common to those of the semiconductor devices A10 and A20 (and the design method and the manufacturing method), thereby producing the same effects as those of the semiconductor devices A10 and A20 (and the design method and the manufacturing method). As understood from the semiconductor device A30, a semiconductor device of the present disclosure may not include neither of the two semiconductor elements 13 and 14.

Instead of the above configuration that does not include neither of the semiconductor elements 13, 14, the semiconductor device A30 may include either one of the two semiconductor elements. As such, the semiconductor device of the present disclosure may include one of the semiconductor elements 13, 14 or none of them.

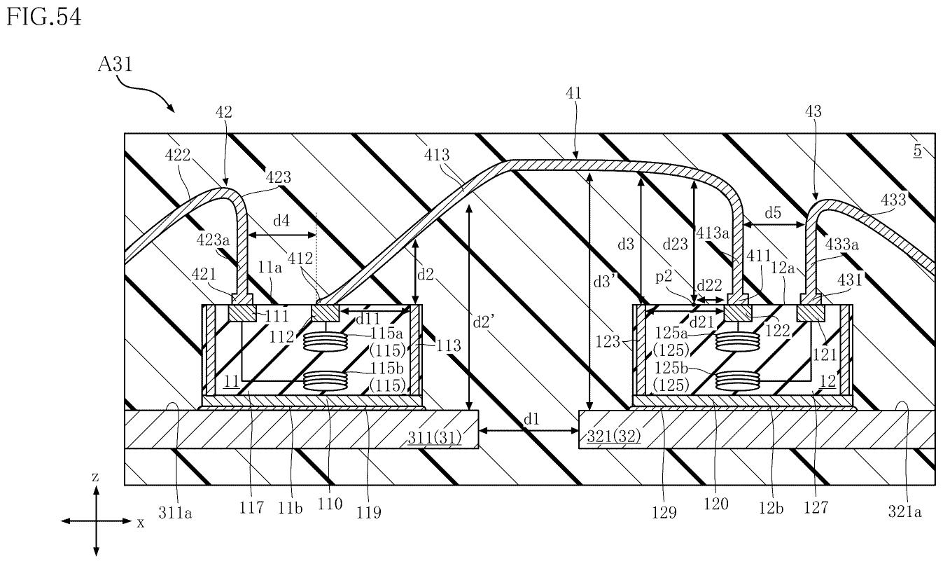

FIG. 54 shows a semiconductor device A31 according to a variation of the third embodiment of the second aspect. FIG. 54 is an enlarged sectional view of the semiconductor device A31, corresponding to the sectional view of FIG. 53. The semiconductor device A31 may differ from the semiconductor device A30 in that the wire(s) 41 is first-bonded to the pad(s) 122 of the semiconductor element 12 and second-bonded to the pad(s) 112 of the semiconductor element 11.

As shown in FIG. 54, in the semiconductor device A31, the rise section 413a of the loop portion 413 of the wire(s) 41 is bonded to the pad(s) 122 of the semiconductor element 12. In the semiconductor device A31, the distance d5 is the distance in the direction perpendicular to the thickness direction z between the rise section 413a of the loop portion 413 of the wire 41 and the rise section 433a of the loop portion 433 of the wire 43. The joint portion 412 of the wire(s) 41 is bonded to the pad(s) 112 of the semiconductor element 11. In the semiconductor device A31, the distance d4 is the distance in the direction perpendicular to the thickness direction z between the joint portion 412 of the wire 41 and the rise section 423a of the loop portion 423 of the wire 42.

In the semiconductor device A31, the distance d3 between the wire(s) 41 and the semiconductor element 12 is greater than the distance d0 determined by formula (1). As mentioned above, the wire 41 is at an intermediate potential between the first circuit and the second circuit. The semiconductor element 12 is bonded to the island portion 321 (lead 32), and thus the seal ring portion 123 may be at the same potential as the island portion 321. As such, the wire 41 is a relatively low voltage and the seal ring portion 123 is a relatively high voltage, whereby a potential difference is generated between the wire 41 and the seal ring portion 123. Since the distance d3 is greater than the distance d0, it is possible to design that the semiconductor device A31 ensures an insulation resistance voltage suitable for actual use between the wire 41 and the seal ring portion 123. Thus, the semiconductor device A31 can ensure an appropriate dielectric strength between the wire 41 and the semiconductor element 12, thereby suppressing the occurrence of dielectric breakdown. In the design method of the semiconductor device A31, the distance d3 is designed to be greater than the distance d0 by the wire design step S104. This makes it possible to design and manufacture a semiconductor device A31 in which the occurrence of dielectric breakdown is suppressed. In this semiconductor device A31, the leads 32 and 31 are examples of the “first lead” and “second lead” described in Clause B, respectively. The semiconductor elements 12 and 11 are examples of the “first semiconductor element” and “second semiconductor element” described in Clause B, respectively. The wire(s) 41 is an example of the “first wire” described in Clause B, and the pad(s) 122 is an example of the “first pad” described in Clause B, the seal ring portion 123 is an example of the “seal ring portion” described in Clause B, and the distance d3 is an example of the “first distance” described in Clause B.

In the semiconductor device A31, the distance d3 is greater than the distance d0, and the distance d21 is not less than 100 μm and not more than 300 μm. The wire(s) 41 is a copper wire (containing copper). With this configuration, the distance d3 can be made greater than the distance do while making the rising of the wire 41 gentle. Thus, when the wire 41 is a copper wire, the semiconductor device A31 can suppress the occurrence of wire cracks and damage to the semiconductor element 11 while making the distance d3 greater than the distance d0. In the semiconductor device A31, the distance d21 is an example of the “second distance” described in Clause B.

In the semiconductor device A31, as in the semiconductor device A21, the distance d22 is not less than 50 μm and not more than 150 μm. Thus, in the semiconductor device A31, as in the semiconductor device A21, the distance d3 can be made greater than the distance d0. As such, in the semiconductor device A31, it is desirable that the distance d22 be 50 μm or more and 150 μm or less in order to secure an appropriate dielectric strength and suppress the occurrence of dielectric breakdown. In the semiconductor device A31, the point p2 is an example of the “point” described in Clause B, the distance d22 is an example of the “third distance” described in Clause B, and the distance d23 is an example of the “fourth distance” described in Clause B.

Further, the semiconductor device A31 may have the configurations common to those of the semiconductor device A30, thereby having the same effects as those of the semiconductor device A30. As understood from the semiconductor device A31, in a semiconductor device of the present disclosure, the bonding targets of the first bonding and second bonding of the wires 41 are not limitative.

Differing from the semiconductor device A31 shown in FIG. 54, in the wires 42, 43, as in the wires 41, the first bonding and the second bonding may be performed the other way around. As such, in a semiconductor device of the present disclosure, the bonding targets of the first bonding and the second bonding of the wires 42, 43 are not limitative.

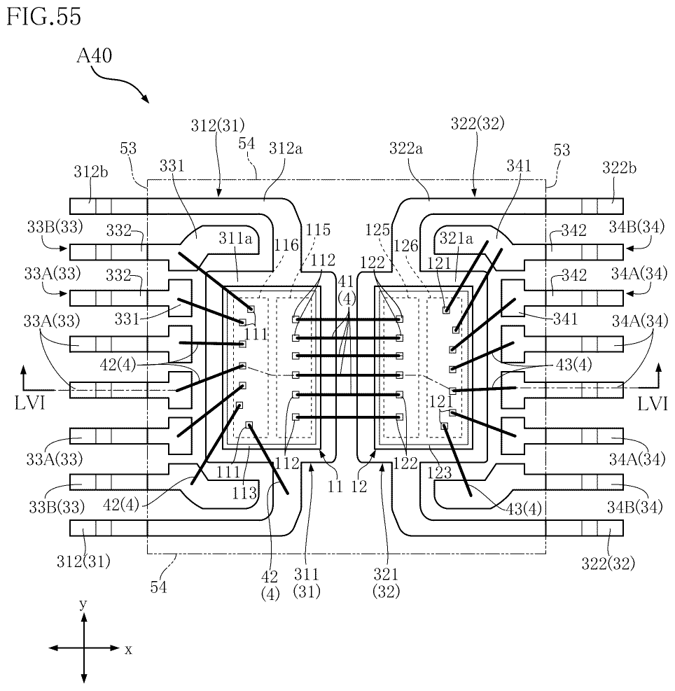

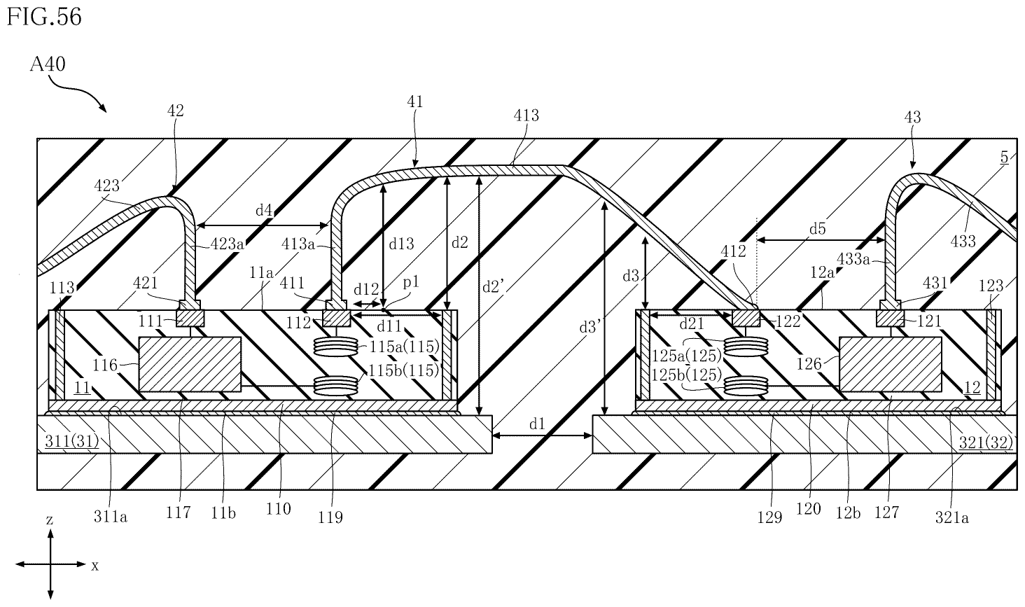

FIGS. 55 and 56 show a semiconductor device A40 according to a fourth embodiment of the second aspect. The semiconductor device A40 may differ from the semiconductor device A30 in the following. First, the semiconductor element 11 of the semiconductor device A40 includes a functional part 116 in addition to the functional part 115. Second, the semiconductor element 12 of the semiconductor device A40 includes a functional part 126 in addition to the functional part 115. The connection configurations of the wires 42 and 43 are not limited to the example shown in FIG. 55, but may be varied as appropriate depending on the configurations of the semiconductor element 11 and the semiconductor element 12.

The functional part 116 functions as the semiconductor element 13 (i.e., control element) described above. The functional part 116 may be formed on the semiconductor substrate 110, for example. The functional part 116 is electrically connected to the functional part 115 inside the semiconductor element 11. In the example shown in FIG. 56, the functional part 116 is electrically connected to the lower winding 115b. In this example, the pads 111 are electrically connected to the functional part 116, and the pads 112 are electrically connected to the functional part 115 (upper winding 115a). The semiconductor element 11 of the semiconductor device A40 has a configuration in which the control element and the insulating element are integrated into a single chip.

The functional part 126 functions as the semiconductor element 14 (i.e., the driving element) described above. The functional part 126 may be formed on the semiconductor substrate 120, for example. The functional part 126 is electrically connected to the functional part 125 inside the semiconductor element 12. In the example shown in FIG. 56, the functional part 126 is electrically connected to the lower winding 125b. In this example, the pads 121 are electrically connected to the functional part 126, and the pads 122 are electrically connected to the functional part 125 (upper winding 125a). The semiconductor element 12 of the semiconductor device A40 has a configuration in which the drive element and the insulating element are integrated into a single chip.

In the semiconductor device A40 with the above-noted configurations, the first circuit including the functional part 116 of the semiconductor element 11 and the second circuit including the functional part 126 of the semiconductor element 12 are insulated from each other by the functional part 115 of the semiconductor element 11 and the functional part 125 of the semiconductor element 12.

The manufacturing method of the semiconductor device A40 is the same as the manufacturing method of the semiconductor device A30. In other words, the manufacturing method of the semiconductor device A40 is the same as the manufacturing method of the semiconductor device A20 (see FIG. 48), except for the following. First, the element mounting process S13 does not include a process for mounting the semiconductor elements 13 and 14. Second, the wire bonding process S14 does not include a process for providing the wires 44-47.

The workings and advantages of the semiconductor device A40 of the second aspect, the design method of the semiconductor device A40 and the manufacturing method of the semiconductor device A40 are as follows.

In the semiconductor device A40, as in the semiconductor device A30, the distance d2 is greater than distance d0, whereby it is possible to design an insulation resistance voltage suitable for actual use between the wire(s) 41 and the seal ring portion 113. Thus, in the semiconductor device A40, an appropriate dielectric strength may be ensured between the wire 41 and the seal ring portion 113 (semiconductor element 11), which is advantageous to suppressing the occurrence of dielectric breakdown. In the design method of the semiconductor device A40, as in the design method of the semiconductor device A30, the wire design step S102 is performed such that the distance d2 is to be greater than the distance d. This makes it possible to design and manufacture of a semiconductor device A40 in which the occurrence of dielectric breakdown is suppressed. In the semiconductor device A40, the leads 31, 32 are examples of the “first lead” and “second lead” described in Clause B, respectively. The semiconductor elements 11, 12 are examples of the “first semiconductor element” and “second semiconductor element” described in Clause B, respectively. The wire(s) 41 is an example of the “first wire” described in Clause B, the pad(s) 112 is an example of the “first pad” described in Clause B, the seal ring portion 113 is an example of the “seal ring portion” described in Clause B, and the distance d2 is an example of the “first distance” described in Clause B.

In the semiconductor device A40, as in the semiconductor devices A10, A20 and A30, the distance d2 is greater than the distance d0, and the distance d11 in the first direction x between the pad(s) 112 and the seal ring portion 113 (see FIG. 56) is not less than 100 μm and not more than 300 μm. Thus, the semiconductor device A40, like the semiconductor devices A10, A20 and A30, can make the rising of the wire 41 gentle while making the distance d2 greater than the distance d0. Thus, when the wire 41 is a copper wire, the occurrence of wire cracks and damage to the semiconductor element 11 can be suppressed while making the distance d2 greater than the distance d0. In the semiconductor device A40, the distance d11 is an example of the “second distance” described in Clause B.

In the semiconductor device A40, as in the semiconductor devices A20 and A30, the distance d21 in the first direction x between the pad(s) 122 and the seal ring portion 123 (see FIG. 56) is not less than 100 μm and not more than 300 μm. Thus, the semiconductor device A40 can suppress the occurrence of dielectric breakdown while preventing the semiconductor device A40 from becoming unduly large, as in the semiconductor devices A20 and A30.

The semiconductor device A40 (the design method and the manufacturing method) may have the same configurations as those of the semiconductor devices A10, A20 and A30 (the design method and the manufacturing method), thereby having the same effects as those of the semiconductor devices A10, A20 and A30 (the design method and the manufacturing method). As understood from the semiconductor device A40, a semiconductor device of the present disclosure may be configured such that the semiconductor element 11 (insulating element) and the semiconductor element 13 (control element) are integrated into a single chip or provided in mutually separate chips. Likewise, a semiconductor device of the present disclosure may be configured such that the semiconductor element 12 (insulating element) and the semiconductor element 14 (driving element) are integrated into a single chip or provided in mutually separate chips.

By the above-described example of the semiconductor device A40 of the fourth embodiment, the semiconductor element 11 includes two functional parts 115, 116, and the semiconductor element 12 includes two functional parts 125, 126. Alternatively, the semiconductor element 11 may not include the functional part 116, and/or the semiconductor element 12 may not include the functional part 126.

In the above-described examples of the second to fourth embodiments (including variations), the semiconductor elements 11 and 12 are used to equally divide the voltage difference between the first circuit and the second circuit for insulation. As such, the insulation ratios for the semiconductor elements 11 and 12 are the same with respect to the voltage difference between the first circuit and the second circuit. Alternatively, the insulation ratios for the semiconductor elements 11 and 12 may be different from each other with respect to the voltage difference between the first circuit and the second circuit. In this case, depending on the insulation ratios for the semiconductor elements 11 and 12, the number of the insulation layers 1171 disposed between the upper winding 115a and the lower winding 115b may be different from the number of the insulation layers 1271 disposed between the upper winding 125a and the lower winding 125b. For instance, when the insulation ratio for the semiconductor element 11 is greater than the insulation ratio for the semiconductor element 12, the number of the insulation layers 1171 is greater than the number of the insulation layers 1271. As seen from this, in a semiconductor device of the present disclosure, the insulation ratios for the semiconductor elements 11 and 12 are not limitative.

The semiconductor device of the second aspect of the present disclosure, the design method of the semiconductor device, and the manufacturing method of the semiconductor device are not limited to the above-described specific examples. The configuration of each part of the semiconductor device, and the configuration of each process or step of the semiconductor device design method, and the configuration of each process or step of the semiconductor device manufacturing method may be varied in many ways. The present disclosure includes the embodiments described in the following clauses.
Clause B1.

A semiconductor device (A10, A20, A30, A40) comprising:
a conductive support (3) including a first lead (31) and a second lead (32) spaced apart from each other in a first direction (x) perpendicular to a thickness direction (z);
a first semiconductor element (11) mounted on the first lead (31);
a second semiconductor element (12, 14) mounted on the second lead (32);
a first wire (41) electrically connecting the first semiconductor element (11) and the second semiconductor element (12, 14); and
a sealing resin (5) covering a part of the conductive support (3), the first semiconductor element (11), the second semiconductor element (12, 14) and the first wire (41),
wherein the first semiconductor element (11) includes an obverse surface (11a) facing one side of the thickness direction (z), a first pad (112) disposed on the obverse surface (11a), and a seal ring portion (113) having a potential different from that of the first pad (112),
the first wire (41) contains copper and is bonded to the first pad (112),
a first distance (d2) in the thickness direction (z) between the first wire (41) and the seal ring portion (113) is greater than a distance d0 determined by Formula (1),
a second distance (d11) in the first direction (x) between the first pad (112) and the seal ring portion (113) is not less than 100 μm and not more than 300 μm,

d0=((Y/A)\hat{ }(1/B))×0.15×(X) (1)
where Y is an insulation life [years] required for the semiconductor device (A10, A20, A30, A40), A and B are constants depending on a material of the sealing resin (5), 0.15 is an offset value for calculating the distance d0 [mm], and X is a voltage [kVrms].
Clause B1-1.

The semiconductor device (A10, A20, A30, A40) according to clause B1, wherein the first wire (41) includes a first joint portion (411) bonded to the first pad (112) and a loop portion (413) connected to the first joint portion (411).
Clause B1-2.

The semiconductor device (A10, A20, A30, A40) according to clause B1-1, wherein the loop portion (413) has a rise section (413a) extending toward the one side of the thickness direction (z).
Clause B2.

The semiconductor device (A10, A20, A30, A40) according to clause B1, wherein the first semiconductor element (11) has, on the obverse surface (11a), a point (p1) spaced apart from the first pad (112) by a third distance (d12) in the first direction (x) toward the seal ring portion (113),
the third distance (d12) is not less than 50 μm and not more than 150 μm,
a fourth distance (d13) between the first wire (41) and the point (p1) in the thickness direction (z) is not less than 85% and not more than 95% of the first distance (d2).
Clause B3.

The semiconductor device (A10, A20, A30, A40) according to clause B2, wherein the second distance (d11) is greater than the first distance (d2).
Clause B4

The semiconductor device (A10, A20, A30, A40) according to any of clauses B1-B3, wherein the first semiconductor element (11) includes a second pad (111) disposed on the obverse surface (11a),
a potential of the second pad (111) is different from the potential of the first pad (112).
Clause B5.

The semiconductor device (A10, A20, A30, A40) according to clause B4, wherein the first semiconductor element (11) includes an upper winding (115a) and a lower winding (115b) spaced apart from each other in the thickness direction (z),
the upper winding (115a) is electrically connected to the first pad (112),
the lower winding (115b) is electrically connected to the second pad (111).
Clause B6.

The semiconductor device (A10, A20, A30, A40) according to clause B5, wherein the first semiconductor element (11) includes a semiconductor substrate (110) having a same potential as the first lead (31),
the upper winding (115a) and the lower winding (115b) are located opposite from the first lead (31) with respect to the semiconductor substrate (110) in the thickness direction (z).
Clause B7.

The semiconductor device (A10, A20, A30, A40) according to clause B6, wherein the lower winding (115b) is at a same potential as the semiconductor substrate (110).
Clause B7-1.

The semiconductor device (A10, A20, A30, A40) according to clause B7, wherein the lower winding (115b) is located closer to the semiconductor substrate (110) than is the upper winding (115a) in the thickness direction (z).
Clause B8.

The semiconductor device (A10, A20, A30, A40) according to clause B6 or B7, wherein the seal ring portion (113) is located on a same side as the upper winding (115a) and the lower winding (115b) with respect to the semiconductor substrate (110) in the thickness direction (z) and is disposed on the semiconductor substrate (110).
Clause B9.

The semiconductor device (A10, A20, A30, A40) according to any of clauses B4-B8, further comprising a second wire (42) bonded to the second pad (111).
Clause B10.

The semiconductor device (A10, A20, A30, A40) according to clause B9, wherein a topmost part of the second wire (42) in the thickness direction (z) is lower than a topmost part of the first wire (41) in the thickness direction (z).
Clause B11.

The semiconductor device (A10) according to clause B9 or B10, further comprising a third semiconductor element (13) supported by the conductive support (3) and electrically connected to the first semiconductor element (11) via the second wire (42),
wherein the first semiconductor element (11) is an insulating element configured to transmit electrical signals between the second semiconductor element (14) and the third semiconductor element (13) in an insulated state.
Clause B12.

The semiconductor device (A10) according to clause B11, wherein the third semiconductor element (13) is mounted on the first lead (31).
Clause B13.

The semiconductor device (A20, A30, A40) according to any of clauses B1-B10, wherein the first semiconductor element (11) and the second semiconductor element (12) are each an insulating element configured to transmit electrical signals in an insulated state.
Clause B13-1.

The semiconductor device (A20, A30, A40) according to clause B13, wherein the second semiconductor element (12) includes a second obverse surface (12a) facing one side of the thickness direction (z) and a third pad (122) disposed on the second obverse surface (12a),
the first wire (41) is bonded to the third pad (122).
Clause B13-2.

The semiconductor device (A20, A30, A40) according to clause B13-1, wherein the second semiconductor element (12) includes a second upper winding (125a) and a second lower winding (125b) spaced apart from each other in the thickness direction (z),
the second upper winding (125a) is electrically connected to the third pad (122).
Clause B13-3.

The semiconductor device (A20, A30, A40) according to clause B13-2, wherein the second semiconductor element (12) includes a second semiconductor substrate (120) having a same potential as the second lead (32),
the second upper winding (125a) and the second lower winding (125b) are located opposite from the second lead (32) with respect to the second semiconductor substrate (120) in the thickness direction (z).
Clause B13-4.

The semiconductor device (A20, A30, A40) according to any of clauses B13-1 to B13-3, wherein the second semiconductor element (12) includes a second seal ring portion (123) having a different potential from that of the third pad (112),
a fifth distance (d21) in the first direction (x) between the third pad (122) and the second seal ring portion (123) is not less than 100 μm and not more than 300 μm.
Clause B14.

The semiconductor device (A10. A20, A30, A40) according to any of clauses B1-B13, wherein the seal ring portion (113) is annular along side faces of the first semiconductor element (11) as viewed in the thickness direction (z).
Clause B15.

The semiconductor device (A10. A20, A30, A40) according to any of clauses B1-B14, wherein a constituent material of the sealing resin (5) includes an epoxy.
Clause B15-1.

A method for designing a semiconductor device (A10, A20, A30, A40), the semiconductor device comprising:
a conductive support (3) including a first lead (31) and a second lead (32) spaced apart from each other in a first direction (x) perpendicular to a thickness direction (z);
a first semiconductor element (11) mounted on the first lead (31);
a second semiconductor element (12, 14) mounted on the second lead (32);
a first wire (41) electrically connecting the first semiconductor element (11) and the second semiconductor element (12, 14); and
a sealing resin (5) covering a part of the conductive support (3), the first semiconductor element (11), the second semiconductor element (12, 14) and the first wire (41),
wherein the first semiconductor element (11) includes an obverse surface (11a) facing one side of the thickness direction (z), a first pad (112) disposed on the obverse surface (11a), and a seal ring portion (113) having a potential different from that of the first pad (112),
the first wire (41) contains copper and is bonded to the first pad (112),
a second distance (d11) in the first direction (x) between the first pad (112) and the seal ring portion (113) is not less than 100 μm and not more than 300 μm,
wherein the method for designing the semiconductor device comprises a design process including a first design step (wire design step S102) configured such that a first distance (d2) between the first wire (41) and the seal ring portion (113) in the thickness direction (z) is designed to be greater than the distance d0 determined by Formula (1),

$$d 0 = ( ( Y / A ) \hat{} ( 1 / B ) ) \times 0.15 \times ( X ) \qquad ( 1 )$$

where Y is an insulation life [years] required for the semiconductor device (A10, A20, A30, A40), A and B are constants depending on a material of the sealing resin (5), 0.15 is an offset value for calculating the distance d0 [mm], and X is a voltage [kVrms].
Clause B15-2.

A method for manufacturing a semiconductor device, including the method for designing the semiconductor device (A10, A20, A30, A40) according to clause B15-1.

### REFERENCE NUMERALS RELATING TO SECOND ASPECT

| | |
|---|---|
| A10, A11, A12, A20, A21, A30, A31, A40: Semiconductor device | |
| 11, 12: Semiconductor element | 11a, 12a: Obverse surface |
| 11b, 12b: Reverse surface | 110, 120: Semiconductor substrate |
| 111, 112, 121, 122: Pads | 113, 123: Seal ring portion |
| 1141, 1241: Protection film | 1142, 1242: Passivation film |
| 1143, 1243: Coil protection film | 115, 125: Functional part |
| 115a, 125a: Upper winding | 115b, 125b: Lower winding |
| 116, 126: Functional part | 117, 127: Stacking structure |
| 1171, 1271: Insulation layer | 118, 128: Distributing conductor |
| 1181, 1281: Penetration wiring | 1182, 1282: Lead-out wiring |
| 119, 129: Conductive bonding material | |
| 13, 14: Semiconductor element | |
| 13a, 14a: Obverse surface | 13b, 14b: Reverse surface |
| 131, 141: Pad | 139, 149: Conductive bonding material |
| 3: Conductive support | 31: Lead |
| 311: Island portion | 311a: Mount surface |
| 312: Terminal portion | 312a: Covered portion |
| 312b: Exposed portion | 313: Through-hole |
| 32: Lead | 321: Island portion |
| 321a: Mount surface | 322: Terminal portion |
| 322a: Covered portion | 322b: Exposed portion |
| 33: Lead | 33A: Intermediate lead |
| 33B: Lateral lead | 331: Covered portion |
| 332: Exposed portion | 34: Lead |
| 34A: Intermediate lead | 34B: Lateral lead |
| 341: Covered portion | 342: Exposed portion |
| 4: Connection member | 41 to 47: Wire |
| 411, 421, 431: Joint portion | 412, 422, 432: Joint portion |
| 413, 423, 433: Loop portion | |
| 413a, 423a, 433a: Rise section | 5: Sealing resin |
| 51: Top face | 52: Bottom face |
| 53: Side face | 531: Upper portion |
| 532: Lower portion | 533: Middle portion |
| 54: Side face | 541: Upper portion |
| 542: Lower portion | 543: Middle portion |
| 81: Lead frame | 810: Flat portion |
| 811, 812, 813, 814: Lead | 811a, 812a: Island |
| 811b, 812b: Support lead | 811c: Through-holes |
| 815: Outer frame | 816: Dam bar |
| 82: Resist | S11: Lead frame preparation process |
| S12: Lead frame working process | S101: Lead design step |
| S13: Element mounting process | S14: Wire bonding process |
| S102, S103, S104, S105: Wire design step | |
| S15: Sealing process | S16: Separation process |

1. A semiconductor device comprising:
a conductive support including a first lead and a second lead spaced apart from each other in a first direction perpendicular to a thickness direction;
a first semiconductor element including a first functional part and supported by the first lead;
a second semiconductor element including a second functional part and supported by the second lead;
a sealing resin covering a part of the conductive support, the first semiconductor element, and the second semiconductor element, wherein
each of the first functional part and the second functional part transmits an electrical signal in an insulated state, and
a distance d1 between the first lead and the second lead in the first direction is greater than a distance d0 determined by Formula (1),
d0=((Y/A)\hat{ }(1/B))×0.15×(X) (1)
where Y is an insulation life [years] required for the semiconductor device, A and B are constants depending on a material of the sealing resin, 0.15 is an offset value for calculating the distance d0 [mm], and X is a voltage [kVrms].

2. The semiconductor device according to claim 1, further comprising a first wire connected to the first semiconductor element and the second semiconductor element,
wherein the first wire is electrically connected to each of the first functional part and the second functional part.

3. The semiconductor device according to claim 2, wherein a distance d2 between the first wire and the first semiconductor element is greater than the distance d0 determined by Formula (1).

4. The semiconductor device according to claim 2, wherein a distance d3 between the first wire and the second semiconductor element is greater than the distance d0 determined by Formula (1).

5. The semiconductor device according to claim 2, further comprising a second wire connected to the first semiconductor element,
wherein a distance d4 between the first wire and the second wire is greater than the distance d0 determined by Formula (1).

6. The semiconductor device according to claim 5, further comprising a third semiconductor element covered by the sealing resin and electrically connected to the first semiconductor element on a side opposite from the second semiconductor element, wherein
the third semiconductor element and the first semiconductor element are supported by the first lead,
the second wire is connected to the third semiconductor element.

7. The semiconductor device according to claim 5, wherein the first semiconductor element includes an electrically connected third functional part disposed opposite to the second functional part with respect to the first functional part,
the conductive support includes a third lead spaced apart from the first lead and the second lead,
the second wire electrically conducts to the third functional part and connected to the third lead.

8. The semiconductor device according to claim 2, further comprising a third wire connected to the second semiconductor element,
wherein a distance d5 between the first wire and the third wire is greater than the distance d0 determined by Formula (1).

9. The semiconductor device according to claim 8, further comprising a fourth semiconductor element covered by the sealing resin and electrically connected to the second semiconductor element on a side opposite from the first semiconductor element,
the fourth semiconductor element and the second semiconductor element are supported by the second lead,
the third wire is connected to the fourth semiconductor element.

10. The semiconductor device according to claim 8, wherein the second semiconductor element includes an electrically connected fourth functional part disposed on an opposite side from the first functional part with respect to the first functional part,
the conductive support includes a fourth lead spaced apart from the first lead and the second lead,
the third wire electrically conducts to the fourth functional part and connected to the fourth lead.

11. The semiconductor device according to claim 1, wherein the first functional part includes a first upper winding and a first lower winding spaced apart from each other in the thickness direction,
a potential of the first lower winding is equal to a potential of the first lead.

12. The semiconductor device according to claim 11, wherein the first semiconductor element includes a plurality of first insulation layers stacked between the first upper winding and the first lower winding,
the first insulation layers are made up of not less than four layers and not more than six layers.

13. The semiconductor device according to claim 11, wherein a size of the plurality of first insulation layers in the thickness direction is not less than 9.6 μm and not more than 14.4 μm.

14. The semiconductor device according to claim 11, wherein the second functional part includes a second upper winding and a second lower winding spaced apart from each other in the thickness direction,
a potential of the second lower winding is equal to a potential of the second lead.

15. The semiconductor device according to claim 14, wherein the second semiconductor element includes a plurality of second insulation layers stacked between the second upper winding and the second lower winding in the thickness direction,
the plurality of second insulation layers are made up of not less than four layers and not more than six layers.

16. The semiconductor device according to claim 14, wherein a size of the plurality of second insulation layers in the thickness direction is not less than 9.6 μm and not more than 14.4 μm.

17. The semiconductor device according to claim 1, wherein a constituting material of the sealing resin contains an epoxy resin.

18. A method for designing a semiconductor device that comprises:
a conductive support including a first lead and a second lead spaced apart from each other in a first direction;
a first semiconductor element including a first functional part and supported by the first lead;
a second semiconductor element including a second functional part and supported by the second lead;
a sealing resin covering a part of the conductive support, the first semiconductor element, and the second semiconductor element,
wherein each of the first functional part and the second functional part transmits an electrical signal in an insulated state,
the method for designing the semiconductor device comprises a first design step configured to design that a distance d1 between the first lead and the second lead in the first direction is greater than a distance d0 determined by Formula (1),
$$d 0 = ( ( Y / A ) \hat{} ( 1 / B ) ) \times 0.15 \times ( X ) \qquad ( 1 )$$
where Y is an insulation life [years] required for the semiconductor device, A and B are constants depending on a material of the sealing resin, 0.15 is an offset value for calculating the distance d0 [mm], and X is a voltage [kVrms].

19. The method for designing a semiconductor device according to claim 18, wherein the semiconductor device further comprises a first wire connected to the first semiconductor element and the second semiconductor element,
the first wire electrically conducts to the first functional part and the second functional part.

20. The method for designing a semiconductor device according to claim 19, further comprising a second design step configured to design that a distance d2 between the first wire and the first semiconductor element is greater than the distance d0 determined by Formula (1).
